(19) United States
(12) Patent Application Publication
(10) Pub. No.: US 2026/0231513 A1
(43) Pub. Date: Aug. 6, 2026

(54) SEMICONDUCTOR DEVICE

(71) Applicant: ROHM CO., LTD., Kyoto-shi (JP)

(72) Inventors: Nobutaka OI, Kyoto-shi (JP); Kohei MURASAKI, Kyoto-shi (JP)

(73) Assignee: ROHM CO., LTD., Kyoto-shi (JP)

(21) Appl. No.: 19/578,941

(22) Filed: Mar. 26, 2026

Related U.S. Application Data
(63) Continuation of application No. PCT/JP2024/033666, filed on Sep. 20, 2024.

(30) Foreign Application Priority Data
Sep. 28, 2023 (JP) 2023-168423

(51) Int. Cl. H10D 84/00; H10D 12/00; H10D 62/10; H10D 62/832; H10D 64/23; H10W 40/50

(52) U.S. Cl. CPC H10D 84/161; H10D 12/481; H10D 62/127; H10D 62/8325; H10D 64/232; H10W 40/50

(57) ABSTRACT

A semiconductor device includes a chip that has a main surface, a pad region that is provided in the main surface, a first electrode that is arranged on the main surface in the pad region, and to which a first potential is to be applied, a side wall dielectric film that covers a side wall of the first electrode in the pad region, and a second electrode that is arranged on the main surface so as to form a capacitive coupling with the first electrode via the side wall dielectric film in the pad region, and to which a second potential different from the first potential is to be applied.

### CROSS-REFERENCE TO RELATED APPLICATIONS

The present application is a bypass continuation of International Patent Application No. PCT/JP2024/033666 filed on Sep. 20, 2024, which claims priority to Japanese Patent Application No. 2023-168423 filed on Sep. 28, 2023 in the Japan Patent Office, and the entire contents of those applications are hereby incorporated herein by reference.

### BACKGROUND

### 1. Field of the Disclosure

The present disclosure relates to a semiconductor device.

### 2. Description of the Related Art

US2023/0106733A1 discloses a semiconductor device including a semiconductor substrate, a trench gate structure, an interlayer insulating film, a source electrode, a separation insulating film, and a gate pad. The trench gate structure is formed in the semiconductor substrate. The interlayer insulating film is formed on the trench gate structure. The source electrode is formed on the interlayer insulating film. The separation insulating film is formed on the source electrode. The gate pad is arranged on the source electrode across the separation insulating film.

### BRIEF DESCRIPTION OF THE DRAWINGS

FIG. 1 is a circuit diagram showing an example of an electrical configuration of a semiconductor device according to a first embodiment.

FIG. 2 is a plan view of the semiconductor device shown in FIG. 1.

FIG. 3 is a plan view showing a layout example of a first main surface.

FIG. 4 is an enlarged plan view showing a main portion of an active region.

FIG. 5 is an enlarged plan view showing a main portion of the active region.

FIG. 6 is a cross-sectional view taken along line VI-VI shown in FIG. 4.

FIG. 7 is a cross-sectional view taken along line VII-VII shown in FIG. 4.

FIG. 8 is a cross-sectional view taken along line VIII-VIII shown in FIG. 5.

FIG. 9 is an enlarged plan view showing a main portion of a monitor region.

FIG. 10 is a cross-sectional view taken along line X-X shown in FIG. 9.

FIG. 11 is a cross-sectional view taken along line XI-XI shown in FIG. 9.

FIG. 12 is an enlarged plan view showing a temperature detection region.

FIG. 13 is a cross-sectional view taken along line XIII-XIII shown in FIG. 12.

FIG. 14 is an enlarged plan view showing a configuration in a pad region together with a pad structure according to the first layout example.

FIG. 15 is an enlarged plan view showing a main portion of the pad region.

FIG. 16 is a cross-sectional view taken along line XVI-XVI shown in FIG. 15.

FIG. 17 is a cross-sectional view taken along line XVII-XVII shown in FIG. 15.

FIG. 18 is a cross-sectional view taken along line XVIII-XVIII shown in FIG. 15.

FIG. 19 is an enlarged plan view showing a main portion shown in FIG. 16.

FIG. 20A is a plan view showing a pad structure according to a second layout example.

FIG. 20B is a plan view showing a pad structure according to a third layout example.

FIG. 20C is a plan view showing a pad structure according to a fourth layout example.

FIG. 20D is a plan view showing a pad structure according to a fifth layout example.

FIG. 20E is a plan view showing a pad structure according to a sixth layout example.

FIG. 20F is a plan view showing a pad structure according to a seventh layout example.

FIG. 20G is a plan view showing a pad structure according to an eighth layout example.

FIG. 20H is a plan view showing a pad structure according to a ninth layout example.

FIG. 20I is a plan view showing a pad structure according to a tenth layout example.

FIG. 20J is a plan view showing a pad structure according to an eleventh layout example.

FIG. 20K is a plan view showing a pad structure according to a twelfth layout example.

FIG. 20L is a plan view showing a pad structure according to a thirteenth layout example.

FIG. 20M is a plan view showing a pad structure according to a fourteenth layout example.

FIG. 21 is a plan view for describing an electric test on a gate pad electrode side.

FIG. 22 is a plan view for describing an electric test on a monitor pad electrode side.

FIG. 23 is a plan view for describing an electric test on an anode pad electrode side.

FIG. 24 is a plan view for describing an electric test on a cathode pad electrode side.

FIG. 25 is a cross-sectional view showing a main portion of a semiconductor device according to a second embodiment.

FIG. 26 is a cross-sectional view showing a main portion of a semiconductor device according to a third embodiment.

FIG. 27 is a cross-sectional view showing a main portion of a semiconductor device according to a fourth embodiment.

FIG. 28 is a cross-sectional view showing a main portion of a semiconductor device according to a fifth embodiment.

FIG. 29 is a cross-sectional view showing a main portion of a semiconductor device according to a sixth embodiment.

FIG. 30 is a cross-sectional view showing a main portion of a semiconductor device according to a seventh embodiment.

FIG. 31 is a cross-sectional view showing a main portion of a semiconductor device according to an eighth embodiment.

FIG. 32 is an enlarged plan view showing a main portion of an active region of the semiconductor device shown in FIG. 31.

FIG. 33 is a cross-sectional view taken along line XXXIII-XXXIII shown in FIG. 32.

FIG. 34 is a cross-sectional view showing a main portion of a semiconductor device according to a ninth embodiment.

FIG. 35 is a cross-sectional view showing a main portion of a semiconductor device according to a tenth embodiment.

FIG. 36 is a cross-sectional view showing a main portion of a semiconductor device according to an eleventh embodiment.

FIG. 37 is a plan view showing a first modification example of the semiconductor device according to any one of the first to eleventh embodiments.

FIG. 38 is a plan view showing a second modification example of the semiconductor device according to any one of the first to eleventh embodiments.

FIG. 39 is a plan view showing a third modification example of the semiconductor device according to any one of the first to eleventh embodiments.

FIG. 40 is a plan view showing a fourth modification example of the semiconductor device according to any one of the first to eleventh embodiments.

### DETAILED DESCRIPTION OF THE PREFERRED EMBODIMENTS

Hereinafter, specific embodiments shall be described in detail with reference to attached drawings. The attached drawings are all schematic views and are not strictly shown, and relative positional relationships, scales, proportions, angles and the like thereof do not necessarily coincide. Identical reference signs will be given to corresponding structures among the attached drawings, and duplicate descriptions thereof shall be omitted or simplified. For the structures of which description has been omitted or simplified, the description given before the omission or simplification shall apply.

When the term “substantially” is used in this specification, the term includes a numerical value (shape) equal to a numerical value (shape) of a comparison target and also includes numerical errors (shape errors) in a range of ±10% based on the numerical value (shape) of the comparison target. Although the terms “first,” “second,” “third,” and the like, are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “p-type” may be referred to as a “first conductivity type” and the “n-type” may be referred to as a “second conductivity type.” As a matter of course, the “n-type” may be referred to as the “first conductivity type” and the “p-type” may be referred to as the “second conductivity type” instead.

The “p-type” is a conductivity type due to a trivalent element and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

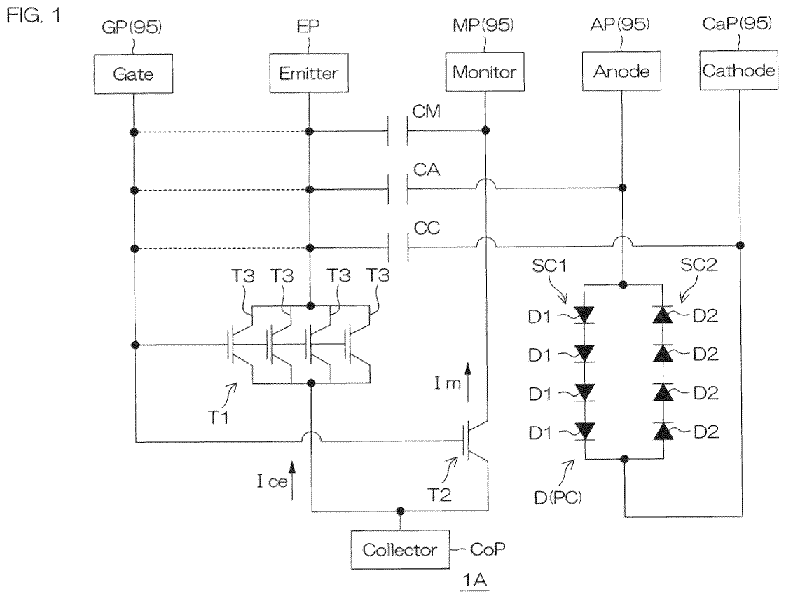

FIG. 1 is a circuit diagram showing an example of an electrical configuration of a semiconductor device 1A according to a first embodiment. The semiconductor device 1A includes a gate pad GP, an emitter pad EP, a monitor pad MP, a collector pad CoP, an anode pad AP, a cathode pad CaP, an insulated gate type main transistor structure T1, an insulated gate type monitor transistor structure T2, and a temperature-sensitive diode structure D. That is, the semiconductor device 1A is a semiconductor switching device.

The main transistor structure T1 includes one or a plurality of transistor structures T3. In this embodiment, the main transistor structure T1 includes a parallel circuit configured by a plurality of (four in this embodiment) transistor structures T3.

The transistor structure T3 includes one or both of a MISFET structure and an IGBT structure. In this embodiment, the transistor structure T3 has a trench gate vertical type IGBT structure.

The main transistor structure T1 (transistor structure T3) includes a gate electrically connected to the gate pad GP, an emitter electrically connected to the emitter pad EP, and a collector electrically connected to the collector pad CoP.

The main transistor structure T1 is on/off controlled in response to the gate potential applied from the gate pad GP, and generates an output current Ice between the emitter pad EP and the collector pad CoP. The output current Ice is an emitter collector current of the main transistor structure T1.

In this embodiment, the monitor transistor structure T2 is connected in parallel to the main transistor structure T1. In this embodiment, the monitor transistor structure T2 has a trench gate vertical type IGBT structure. The monitor transistor structure T2 includes a monitor gate electrically connected to the gate pad GP, a monitor emitter electrically connected to the monitor pad MP, and a monitor collector electrically connected to the collector pad CoP.

The monitor transistor structure T2 is on/off controlled at the same timing as the main transistor structure T1 according to the gate potential applied from the gate pad GP, and generates the monitor current Im for monitoring the output current Ice between the monitor pad MP and the collector pad CoP. The monitor current Im is an emitter collector current of the monitor transistor structure T2.

The monitor current Im is less than the output current Ice. The current ratio Im/Ice of the monitor current Im to the output current Ice may be 1/2000 or more and 1/10 or less. The current ratio Im/Ice may have a value belonging to at least one of the ranges of 1/2000 or more and 1/1750 or less, 1/1750 or more and 1/1500 or less, 1/1500 or more and 1/1250 or less, 1/1250 or more and 1/1000 or less, 1/1000 or more and 1/750 or less, 1/750 or more and 1/500 or less, 1/500 or more and 1/250 or less, 1/250 or more and 1/100 or less, 1/100 or more and 1/75 or less, 1/75 or more and 1/50 or less, 1/50 or more and 1/25 or less, and 1/25 or more and 1/10 or less.

The temperature-sensitive diode structure D has a parallel circuit PC including one or a plurality of (four in this embodiment) first diodes D1 and one or a plurality of (four in this embodiment) second diodes D2. The number of the second diodes D2 is the same as the number of the first diodes D1. As a matter of course, the number of the second diodes D2 may be larger than the number of the first diodes D1, or may be smaller than the number of the first diodes D1.

The plurality of first diodes D1 are connected in series in the forward direction and constitute a first series circuit SC1. The anode of the first series circuit SC1 is electrically connected to the anode pad AP. The cathode of the first series circuit SC1 is electrically connected to the cathode pad CaP.

The plurality of second diodes D2 are connected in series in the forward direction and constitute a second series circuit SC2. The cathode of the second series circuit SC2 is electrically connected to the anode pad AP. The anode of the second series circuit SC2 is electrically connected to the cathode pad CaP. That is, the second series circuit SC2 is connected in reverse-bias parallel to a first series circuit SC1, and constitutes the parallel circuit PC together with the first series circuit SC1.

The first series circuit SC1 functions as a temperature sensor, and the second series circuit SC2 functions as a protection circuit. The first series circuit SC1 (the plurality of first diodes D1) has a temperature characteristic (for example, a positive temperature characteristic) that fluctuates according to a temperature change with respect to a forward voltage, and outputs a forward current according to the temperature of a chip 2.

The second series circuit SC2 provides tolerance to the noise signal. The second series circuit SC2 preferably has electrical characteristics (high-frequency impedance characteristics) substantially equal to those of the first series circuit SC1. When the protection function by the second series circuit SC2 is unnecessary, the second series circuit SC2 may be removed.

The semiconductor device 1A includes a monitor capacitor structure CM electrically interposed between the emitter pad EP and the monitor pad MP. The monitor capacitor structure CM functions as a capacitor between the emitter pad EP and the monitor pad MP when a voltage is applied between the emitter pad EP and the monitor pad MP.

The monitor capacitor structure CM also functions as a capacitor between the gate pad GP and the monitor pad MP when a voltage is applied between the gate pad GP and the monitor pad MP.

The semiconductor device 1A includes an anode capacitor structure CA electrically interposed between the emitter pad EP and the anode pad AP. The anode capacitor structure CA functions as a capacitor between the emitter pad EP and the anode pad AP when a voltage is applied between the emitter pad EP and the anode pad AP.

The anode capacitor structure CA functions as a capacitor between the gate pad GP and the anode pad AP when a voltage is applied between the gate pad GP and the anode pad AP.

The semiconductor device 1A includes a cathode capacitor structure CC electrically interposed between the emitter pad EP and the cathode pad CaP. The cathode capacitor structure CC functions as a capacitor between the emitter pad EP and the cathode pad CaP when a voltage is applied between the emitter pad EP and the cathode pad CaP.

The cathode capacitor structure CC also functions as a capacitor between the gate pad GP and the cathode pad CaP when a voltage is applied between the gate pad GP and the cathode pad CaP.

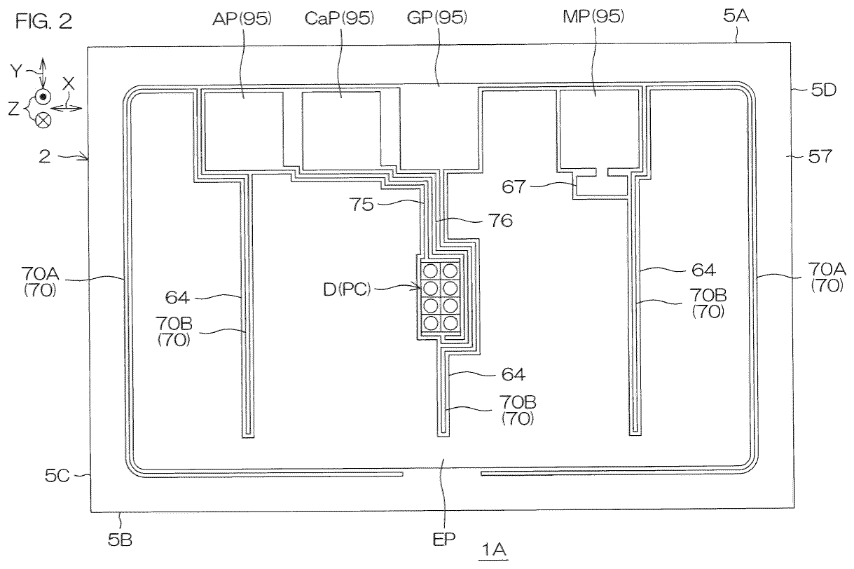

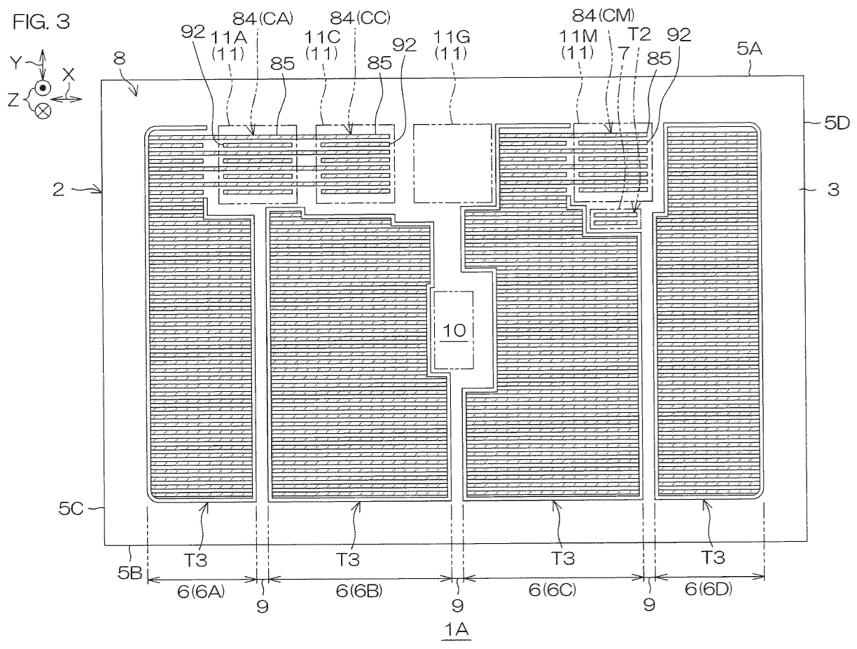

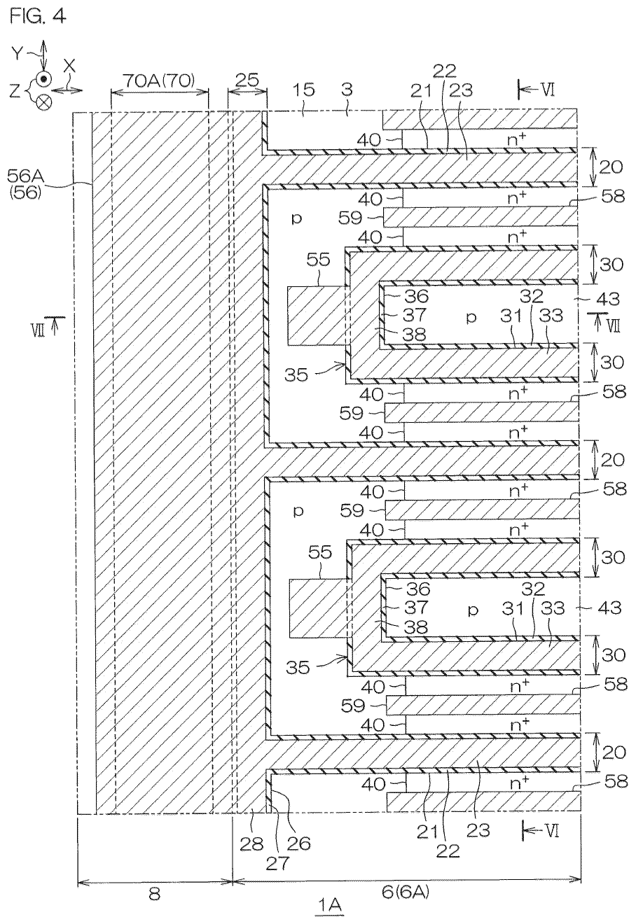

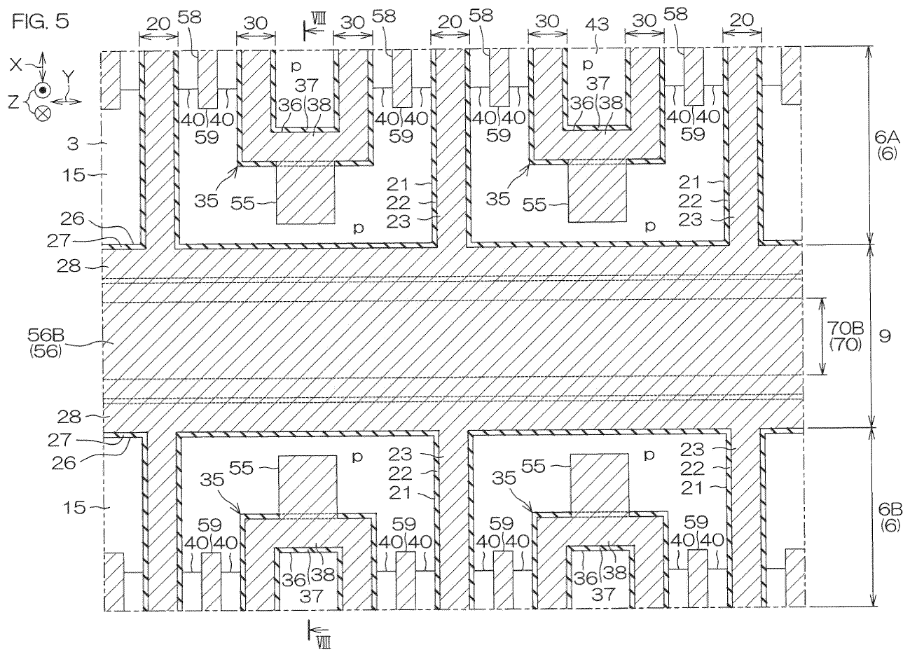

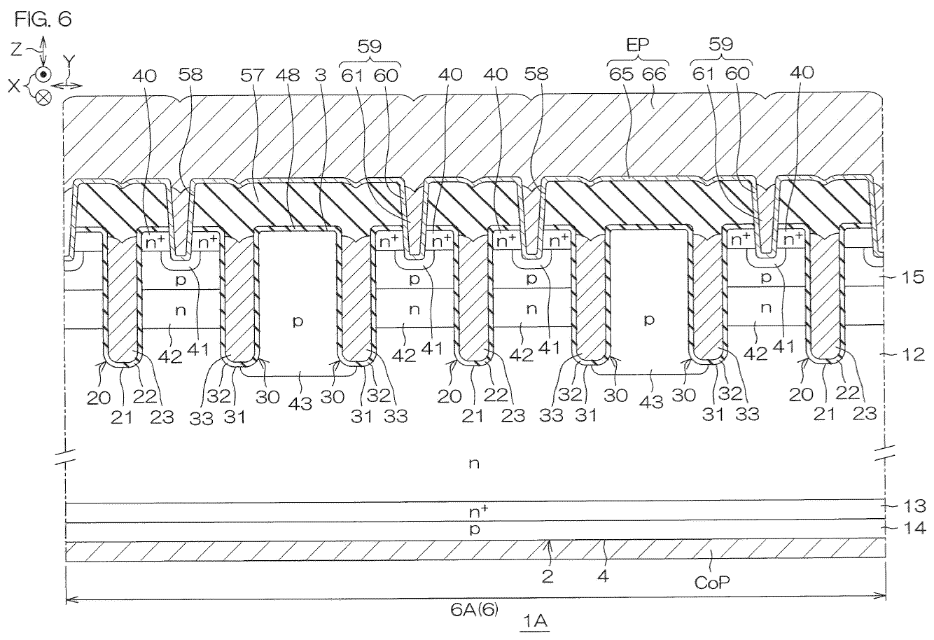

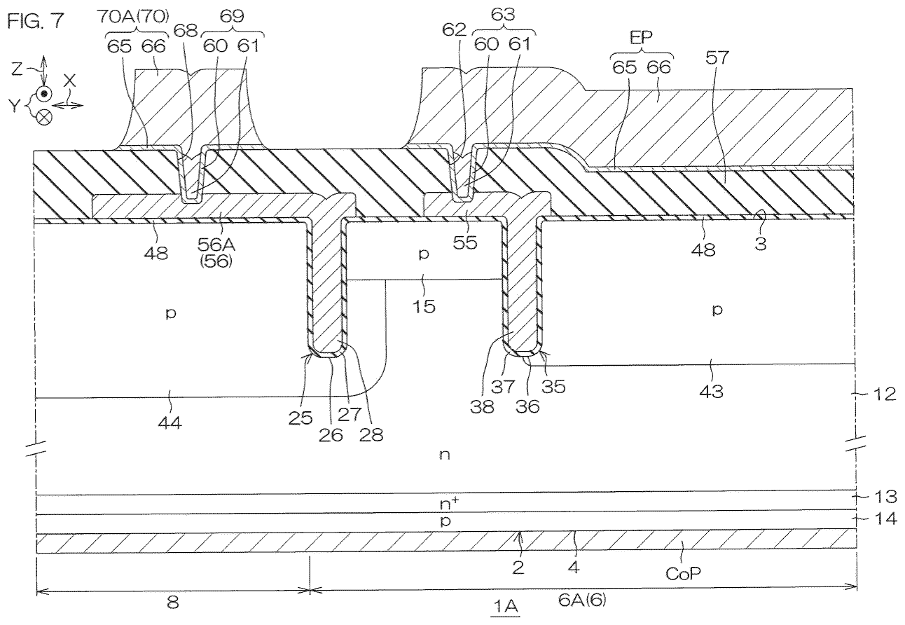

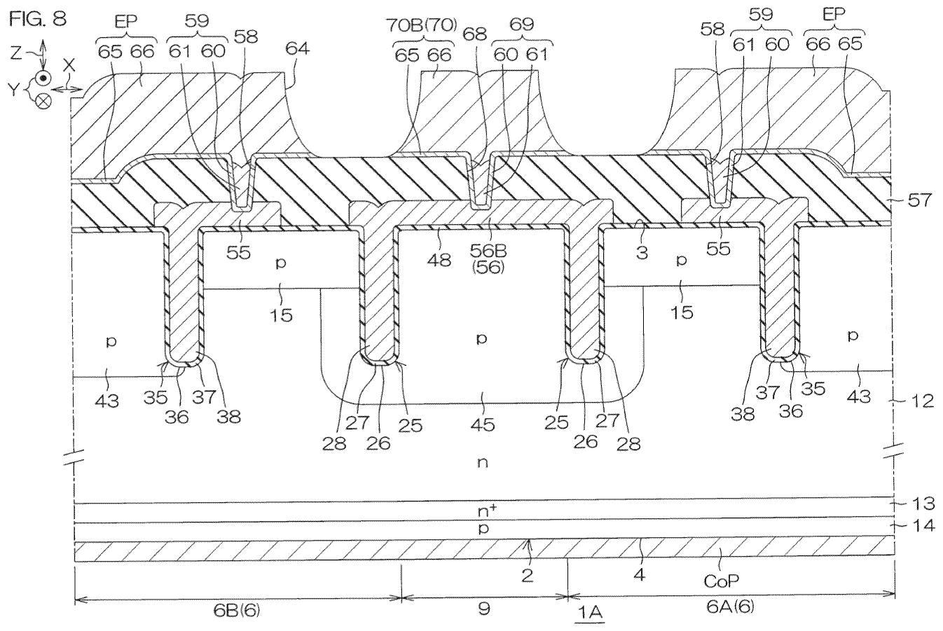

FIG. 2 is a plan view of the semiconductor device 1A shown in FIG. 1. FIG. 3 is a plan view showing a layout example of a first main surface 3. FIG. 4 is an enlarged plan view showing a main portion of an active region 6. FIG. 5 is an enlarged plan view showing another main portion of the active region 6. FIG. 6 is a cross-sectional view taken along line VI-VI shown in FIG. 4. FIG. 7 is a cross-sectional view taken along line VII-VII shown in FIG. 4. FIG. 8 is a cross-sectional view taken along line VIII-VIII shown in FIG. 5.

With reference to FIGS. 2 to 8, the semiconductor device 1A includes the chip 2 having a hexahedral shape (specifically, a rectangular parallelepiped shape). The chip 2 includes one or both of a silicon single crystal and a wide bandgap semiconductor single crystal.

The wide bandgap semiconductor is a semiconductor having a bandgap larger than a bandgap of silicon. GaN (gallium nitride), SiC (silicon carbide), C (diamond), and the like, can be given as examples of the wide bandgap semiconductor. The chip 2 may be referred to as a “semiconductor chip,” a “silicon chip,” a “wide bandgap semiconductor chip,” or the like.

When SiC single crystal is adopted as the wide bandgap semiconductor single crystal, the chip 2 is preferably formed of hexagonal SiC single crystal. The hexagonal SiC single crystal has a plurality of polytypes including a 2H (hexagonal)-SiC single crystal, a 4H-SiC single crystal, a 6H-SiC single crystal, and the like. The chip 2 preferably contains 4H-SiC single crystal. As a matter of course, the chip 2 may include other polytypes. In this embodiment, the chip 2 has a single-layer structure formed of silicon single crystal.

The chip 2 may have a thickness of 50 μm or more and 500 μm or less. The thickness of the chip 2 may have a value belonging to at least one of the ranges of 50 μm or more and 100 μm or less, 100 μm or more and 150 μm or less, 150 μm or more and 200 μm or less, 200 μm or more and 300 μm or less, 300 μm or more and 400 μm or less, and 400 μm or more and 500 μm or less.

The chip 2 has the first main surface 3 on one side, a second main surface 4 on the other side, and first to fourth side surfaces 5A to 5D connected to the first main surface 3 and the second main surface 4. In plan view as viewed from a vertical direction Z (hereinafter referred to simply as “plan view”), the first main surface 3 and the second main surface 4 are formed in quadrangular shapes. The vertical direction Z is also a thickness direction of the chip 2.

The first side surface 5A and the second side surface 5B extend in a first direction X along the first main surface 3, and face away from (opposed to) each other in a second direction Y intersecting the first direction X along the first main surface 3. Specifically, the second direction Y is orthogonal to the first direction X. The third side surface 5C and the fourth side surface 5D extend in the second direction Y and face away from (opposed to) each other in the first direction X.

In the following, directions extending along the first main surface 3 are expressed at times as “horizontal directions.” The horizontal directions are also an XY plane (horizontal plane) formed by the first direction X and the second direction Y and are orthogonal to the vertical direction Z.

The semiconductor device 1A includes one or a plurality of active regions 6 provided in the first main surface 3. The active region 6 is a region having the transistor structure T3. The number of the active regions 6 is optional, and is appropriately adjusted according to the size of the chip 2 (first main surface 3).

In this embodiment, the semiconductor device 1A includes a plurality of (four in this embodiment) active regions 6. The plurality of active regions 6 include a first active region 6A, a second active region 6B, a third active region 6C, and a fourth active region 6D arranged from the third side surface 5C side toward the fourth side surface 5D side.

The plurality of active regions 6 are provided in the inner portion of the first main surface 3 at an interval from the peripheral edge (first to fourth side surfaces 5A to 5D) of the first main surface 3. The plurality of active regions 6 are arranged at an interval in the first direction X and extend in a band shape in the second direction Y. The plurality of active regions 6 are unevenly distributed on the second side surface 5B side with respect to the first side surface 5A.

A planar shape of the plurality of active regions 6 is optional. In this embodiment, the plurality of active regions 6 are defined into a polygonal shape having four sides parallel to the peripheral edge of the chip 2. The width in the first direction X, the length in the second direction Y, the planar area, and the like of the plurality of active regions 6 may be different from each other. At least two of the plurality of active regions 6 may be partially connected.

The semiconductor device 1A includes a monitor region 7 provided in the first main surface 3. The monitor region 7 is a region having the monitor transistor structure T2. The monitor region 7 is provided in a region outside the plurality of active regions 6. The layout location of the monitor region 7 is optional. In this embodiment, the monitor region 7 is arranged on the first side surface 5A side with respect to the plurality of active regions 6.

In this embodiment, the monitor region 7 is arranged in the vicinity of a corner portion connecting the first side surface 5A and the fourth side surface 5D. The monitor region 7 may oppose at least one active region 6 in the second direction Y. The monitor region 7 has a planar area less than the planar areas of the plurality of active regions 6. The planar area of the monitor region 7 is optional, and is appropriately adjusted according to the size of the chip 2 (first main surface 3) and the monitor current Im.

The semiconductor device 1A includes an outer peripheral region 8 provided in a peripheral edge portion of the first main surface 3. The outer peripheral region 8 is a region not having the monitor transistor structure T2 and the transistor structure T3. The outer peripheral region 8 is provided in a region outside the plurality of active regions 6 and the monitor region 7 in the peripheral edge portion of the first main surface 3. The outer peripheral region 8 is formed in an annular shape extending along the peripheral edge of the first main surface 3, and surrounds the plurality of active regions 6 and the monitor region 7.

The semiconductor device 1A includes one or a plurality of (in this embodiment, a plurality of) street regions 9 provided in the first main surface 3. The street region 9 is a region not having the monitor transistor structure T2 and the transistor structure T3.

The plurality of street regions 9 are provided in regions outside the plurality of active regions 6 and the monitor region 7. The plurality of street regions 9 are respectively defined into regions between the plurality of active regions 6 adjacent to each other, and extend in a band shape along the second direction Y in conformance to the extension direction of the plurality of active regions 6.

The semiconductor device 1A includes a temperature detection region 10 provided in the first main surface 3. The temperature detection region 10 is a region including the temperature-sensitive diode structure D for temperature detection of the chip 2. The temperature detection region 10 may be referred to as a “diode region,” a “temperature-sensitive diode region,” or the like. The temperature detection region 10 is provided in a region outside the plurality of active regions 6 and the monitor region 7.

In this embodiment, the temperature detection region 10 is formed using a part of the street region 9 in regions between the plurality of active regions 6, and opposes the plurality of active regions 6 in the first direction X. In this embodiment, the temperature detection region 10 is formed in a region between the second active region 6B and the third active region 6C.

The temperature detection region 10 has a planar area less than the planar area of the plurality of active regions 6. A layout location of the temperature detection region 10 is optional. The temperature of the inner portion of the first main surface 3 (chip 2) is relatively likely to rise. Therefore, it is preferable that the temperature detection region 10 is provided in the inner portion (for example, the vicinity of the central portion) of the first main surface 3.

In this case, the temperature of the chip 2 is appropriately detected. When a first virtual line passing through the central portion of the first main surface 3 in the first direction X and a second virtual line passing through the central portion of the first main surface 3 in the second direction Y are set, a part of the temperature detection region 10 may overlap one or both of the first virtual line and the second virtual line.

The semiconductor device 1A includes a plurality of pad regions 11 provided in the first main surface 3. The plurality of pad regions 11 are regions where external terminals for external connection are arranged. The plurality of pad regions 11 are provided in regions outside the plurality of active regions 6, the monitor region 7, the plurality of street regions 9, and the temperature detection region 10.

A layout location of the plurality of pad regions 11 is optional. In this embodiment, the plurality of pad regions 11 are formed using a part of the outer peripheral region 8 in a region on the first side surface 5A side with respect to the plurality of active regions 6.

The plurality of pad regions 11 include a gate pad region 11G, a monitor pad region 11M, an anode pad region 11A, and a cathode pad region 11C. The gate pad region 11G is a region where the gate pad GP is arranged. The monitor pad region 11M is a region where the monitor pad MP is arranged. The anode pad region 11A is a region where the anode pad AP is arranged. The cathode pad region 11C is a region where the cathode pad CaP is arranged.

The gate pad region 11G is provided in a region on the first side surface 5A side with respect to the plurality of active regions 6. Specifically, the gate pad region 11G may be provided in the vicinity of the central portion of the first side surface 5A, and may oppose one or the plurality of active regions 6 in one or both of the first direction X and the second direction Y. In this embodiment, the gate pad region 11G opposes the temperature detection region 10 in the second direction Y.

The monitor pad region 11M is provided in a region on the first side surface 5A side with respect to the plurality of active regions 6. Specifically, the monitor pad region 11M is provided in a region on the fourth side surface 5D side with respect to the gate pad region 11G, and opposes the gate pad region 11G in the first direction X. In this embodiment, the monitor pad region 11M opposes the gate pad region 11G with a part of at least one active region 6 (in this embodiment, the third active region 6C) interposed therebetween.

The monitor pad region 11M is provided in a region on the first side surface 5A side with respect to the monitor region 7, and opposes the monitor region 7 in the second direction Y. The monitor pad region 11M opposes one or the plurality of active regions 6 (in this embodiment, the third active region 6C) in the second direction Y with the monitor region 7 interposed therebetween.

The anode pad region 11A is provided in a region on the first side surface 5A side with respect to the plurality of active regions 6. Specifically, the anode pad region 11A is provided in a region on the third side surface 5C side with respect to the gate pad region 11G, and opposes the gate pad region 11G in the first direction X. The anode pad region 11A may oppose one or the plurality of active regions 6 in the second direction Y.

The cathode pad region 11C is provided in a region on the first side surface 5A side with respect to the plurality of active regions 6. Specifically, the cathode pad region 11C is provided in a region on the third side surface 5C side with respect to the gate pad region 11G, and opposes the gate pad region 11G in the first direction X.

More specifically, the cathode pad region 11C is interposed in a region between the gate pad region 11G and the anode pad region 11A, and opposes both the gate pad region 11G and the anode pad region 11A in the first direction X. The cathode pad region 11C may oppose one or the plurality of active regions 6 in the second direction Y.

The semiconductor device 1A includes an n-type drift region 12 formed inside the chip 2. The drift region 12 may be referred to as a “semiconductor region.” The drift region 12 is formed over the entire thickness range between the first main surface 3 and the second main surface 4, and extends in a layer shape along the first main surface 3 (second main surface 4).

In this embodiment, the drift region 12 is formed over the entire region inside the chip 2, and is exposed from the first main surface 3 and the first to fourth side surfaces 5A to 5D. In this embodiment, the chip 2 is constituted of an n-type semiconductor substrate (n-type chip 2), and the drift region 12 is formed using the n-type chip 2.

The semiconductor device 1A includes an n-type buffer region 13 formed in a surface layer portion of the second main surface 4. The buffer region 13 has an n-type impurity concentration higher than the n-type impurity concentration of the drift region 12. In this embodiment, the buffer region 13 is formed in a layer shape extending along the second main surface 4 over the entire region of the second main surface 4, and is exposed from the first to fourth side surfaces 5A to 5D. The presence or absence of the buffer region 13 is optional, and an embodiment without the buffer region 13 may be adopted instead.

The semiconductor device 1A includes a p-type collector region 14 formed in a surface layer portion of the second main surface 4. The collector region 14 forms a collector of the main transistor structure T1 (transistor structure T3). The collector region 14 is formed in a region on the second main surface 4 side with respect to the buffer region 13. The collector region 14 has a p-type impurity concentration higher than the n-type impurity concentration of the drift region 12, and replaces the conductivity type of the drift region 12 from n-type to p-type.

The collector region 14 has a p-type impurity concentration higher than the n-type impurity concentration of the buffer region 13, and replaces the conductivity type of the buffer region 13 from n-type to p-type. In this embodiment, the collector region 14 is formed in a layer shape extending along the second main surface 4 over the entire region of the second main surface 4, and is exposed from the second main surface 4 and the first to fourth side surfaces 5A to 5D.

Hereinafter, configurations of the plurality of active regions 6, the monitor region 7, the outer peripheral region 8, the plurality of street regions 9, the temperature detection region 10, and the plurality of pad regions 11 will be described. The semiconductor device 1A includes the plurality of transistor structures T3 respectively formed in the plurality of active regions 6.

The plurality of transistor structures T3 are connected in parallel to each other and constitute one main transistor structure T1. Since the plurality of transistor structures T3 have the same configuration, the configuration of one transistor structure T3 as one constituent element of the semiconductor device 1A will be described below.

The transistor structure T3 includes a p-type base region 15 formed in a surface layer portion of the first main surface 3 of the corresponding active region 6. The base region 15 may be referred to as a “body region,” a “channel region,” or the like. The base region 15 is formed in a surface layer portion of the drift region 12. In this embodiment, the base region 15 has a p-type impurity concentration higher than the n-type impurity concentration of the drift region 12, and the conductivity type of the drift region 12 is replaced from the n-type to the p-type.

The base regions 15 are formed in each corresponding active region 6 in a layered shape extending along the first main surface 3. The base region 15 is formed at an interval on the first main surface 3 side from the depth position of the intermediate portion of the drift region 12, and opposes the buffer region 13 and the collector region 14 with the drift region 12 interposed therebetween.

The transistor structure T3 includes a plurality of trench electrode type gate structures 20 formed in the first main surface 3 of the corresponding active region 6. The plurality of gate structures 20 form gates of the main transistor structure T1 (transistor structure T3). The gate structure 20 may be referred to as a “first trench structure,” a “trench gate structure,” or the like. A gate potential is to be applied to the gate structure 20.

The plurality of gate structures 20 each extend in a band shape in the first direction X and are arranged at an interval in the second direction Y. That is, the plurality of gate structures 20 are arranged in a stripe shape extending in the first direction X. The plurality of gate structures 20 each have one end portion on one side (third side surface 5C side) and the other end portion on the other side (fourth side surface 5D side) in the longitudinal direction (first direction X).

The plurality of gate structures 20 may each have a width less than the width of the plurality of street regions 9. The width of the gate structure 20 is a width in a direction (second direction Y) orthogonal to the extension direction (first direction X) of the gate structure 20.

The width of the gate structure 20 may be 0.5 μm or more and 5 μm or less. The width of the gate structure 20 may have a value belonging to at least one of the ranges of 0.5 μm or more and 1 μm or less, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less. The width of the gate structure 20 is preferably 1 μm or more and 2.5 μm or less.

The plurality of gate structures 20 penetrate the base region 15 to reach the drift region 12. The plurality of gate structures 20 are respectively formed at an interval on the first main surface 3 side from the depth position of the intermediate portion of the drift region 12, and oppose the buffer region 13 and the collector region 14 with a part of the drift region 12 interposed therebetween in the thickness direction.

The plurality of gate structures 20 may be formed in a tapered shape toward the bottom wall. As a matter of course, the plurality of gate structures 20 may be formed substantially perpendicular to the first main surface 3. The plurality of gate structures 20 may have a bottom wall formed in a curved shape toward the second main surface 4. As a matter of course, the bottom walls of the plurality of gate structures 20 may be formed substantially parallel to the first main surface 3. In this case, the bottom wall corner portions of the plurality of gate structures 20 may be formed in a curved shape.

The plurality of gate structures 20 may each have a depth of 1 μm or more and 10 μm or less. The depth of the gate structure 20 may have a value belonging to at least one of the ranges of 1 μm or more and 2 μm or less, 2 μm or more and 4 μm or less, 4 μm or more and 6 μm or less, 6 μm or more and 8 μm or less, and 8 μm or more and 10 μm or less. The depth of the gate structure 20 is preferably 4 μm or more and 8 μm or less.

The plurality of gate structures 20 each include a gate trench 21, a gate insulating film 22, and a gate embedded electrode 23. The gate trench 21 is formed in the first main surface 3 and defines a wall surface (side wall and bottom wall) of the gate structure 20.

The gate insulating film 22 covers the wall surface of the gate trench 21. The gate insulating film 22 may include at least one among a silicon oxide film, a silicon nitride film, and a silicon oxynitride film. In this embodiment, the gate insulating film 22 has a single-layer structure formed of the silicon oxide film. The gate insulating film 22 particularly preferably includes the silicon oxide film formed of the oxide of the chip 2.

The gate insulating film 22 may have a thickness of 10 nm or more and 200 nm or less. The thickness of the gate insulating film 22 may have a value belonging to at least one of the ranges of 10 nm or more and 25 nm or less, 25 nm or more and 50 nm or less, 50 nm or more and 75 nm or less, 75 nm or more and 100 nm or less, 100 nm or more and 125 nm or less, 125 nm or more and 150 nm or less, 150 nm or more and 175 nm or less, and 175 nm or more and 200 nm or less. The thickness of the gate insulating film 22 is preferably 100 nm or more and 150 nm or less.

The gate embedded electrode 23 is embedded in the gate trench 21 with the gate insulating film 22 interposed therebetween. The gate embedded electrode 23 opposes the drift region 12 and the base region 15 with the gate insulating film 22 interposed therebetween. The electrode surface of the gate embedded electrode 23 may be located on the bottom wall side of the gate trench 21 with respect to the first main surface 3. The gate embedded electrode 23 may contain one or both of the p-type conductive polysilicon and the n-type conductive polysilicon.

The transistor structure T3 includes a plurality of trench electrode type gate connection structures 25 formed in the first main surface 3 to be connected to the plurality of gate structures 20 in the corresponding active region 6. A gate potential is to be applied to the plurality of gate connection structures 25. The gate connection structure 25 may be referred to as a “first trench connection structure,” a “trench gate connection structure,” or the like.

The plurality of gate connection structures 25 are respectively arranged on both end portion sides of the plurality of gate structures 20 to be connected to one end portion and the other end portion of the plurality of gate structures 20 in the first direction X, and define the corresponding active region 6 together with the outermost plurality of gate structures 20.

The plurality of gate connection structures 25 include the gate connection structure 25 on one end portion side of the plurality of gate structures 20 and the gate connection structure 25 on the other end portion side of the plurality of gate structures 20. The gate connection structure 25 on one end portion side extends in a band shape in the second direction Y and is connected to one end portions of the plurality of gate structures 20. The gate connection structure 25 on the other end portion side extends in a band shape in the second direction Y and is connected to the other end portions of the plurality of gate structures 20.

The plurality of gate connection structures 25 may each have a width substantially equal to the width of the gate structure 20. As a matter of course, the width of the gate connection structure 25 may be larger than the width of the gate structure 20, or may be smaller than the width of the gate structure 20.

The width of the gate connection structure 25 may be 0.5 μm or more and 5 μm or less. The width of the gate connection structure 25 may have a value belonging to at least one of the ranges of 0.5 μm or more and 1 μm or less, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less. The width of the gate connection structure 25 is preferably 1 μm or more and 2.5 μm or less.

The plurality of gate connection structures 25 penetrate the base region 15 to reach the drift region 12. The plurality of gate connection structures 25 are formed at an interval on the first main surface 3 side from the depth position of the intermediate portion of the drift region 12, and oppose the buffer region 13 and the collector region 14 with a part of the drift region 12 interposed therebetween in the thickness direction.

The plurality of gate connection structures 25 may be formed in a tapered shape toward the bottom wall. As a matter of course, the plurality of gate connection structures 25 may be formed substantially perpendicular to the first main surface 3. The plurality of gate connection structures 25 may have a bottom wall formed in a curved shape toward the second main surface 4. As a matter of course, the bottom walls of the plurality of gate connection structures 25 may be formed substantially parallel to the first main surface 3. In this case, the bottom wall corner portions of the plurality of gate connection structures 25 may be formed in a curved shape.

The plurality of gate connection structures 25 may each have a depth substantially equal to the depth of the gate structure 20. As a matter of course, the depth of the gate connection structure 25 may be larger than the depth of the gate structure 20, or may be smaller than the depth of the gate structure 20.

The depths of the plurality of gate connection structures 25 may be 0.5 μm or more and 10 μm or less. The depth of the gate connection structure 25 may have a value belonging to at least one of the ranges of 0.5 μm or more and 1 μm or less, 1 μm or more and 2 μm or less, 2 μm or more and 4 μm or less, 4 μm or more and 6 μm or less, 6 μm or more and 8 μm or less, and 8 μm or more and 10 μm or less. The depth of the gate connection structure 25 is preferably 4 μm or more and 8 μm or less.

The plurality of gate connection structures 25 each include a gate connection trench 26, a gate connection insulating film 27, and a gate connection embedded electrode 28. The gate connection trench 26 is formed in the first main surface 3 and defines the wall surface (side wall and bottom wall) of the gate connection structure 25. The gate connection trench 26 communicates with the plurality of gate trenches 21.

The gate connection insulating film 27 may include at least one of a silicon oxide film, a silicon nitride film, and a silicon oxynitride film. The gate connection insulating film 27 preferably includes the same type of insulator as the gate insulating film 22. In this embodiment, the gate connection insulating film 27 has a single-layer structure formed of a silicon oxide film. The gate connection insulating film 27 particularly preferably includes a silicon oxide film formed of oxide of the chip 2.

The gate connection insulating film 27 covers the wall surface of the gate connection trench 26 in a film shape. The gate connection insulating film 27 is connected to the gate insulating film 22 at a communication portion between the gate trench 21 and the gate connection trench 26.

The gate connection insulating film 27 may have a thickness substantially equal to the thickness of the gate insulating film 22. As a matter of course, the thickness of the gate connection insulating film 27 may be larger than the thickness of the gate insulating film 22, or may be smaller than the thickness of the gate insulating film 22.

The thickness of the gate connection insulating film 27 may be 10 nm or more and 200 nm or less. The thickness of the gate connection insulating film 27 may have a value belonging to at least one of the ranges of 10 nm or more and 25 nm or less, 25 nm or more and 50 nm or less, 50 nm or more and 75 nm or less, 75 nm or more and 100 nm or less, 100 nm or more and 125 nm or less, 125 nm or more and 150 nm or less, 150 nm or more and 175 nm or less, and 175 nm or more and 200 nm or less. The thickness of the gate connection insulating film 27 is preferably 100 nm or more and 150 nm or less.

The gate connection embedded electrode 28 is embedded in the gate connection trench 26 with the gate connection insulating film 27 interposed therebetween. The gate connection embedded electrode 28 is connected to the gate embedded electrode 23 at a communication portion between the gate trench 21 and the gate connection trench 26. The gate connection embedded electrode 28 opposes the drift region 12 and the base region 15 with the gate connection insulating film 27 interposed therebetween.

The electrode surface of the gate connection embedded electrode 28 may be located on the bottom wall side of the gate connection trench 26 with respect to the first main surface 3. The gate connection embedded electrode 28 may contain one or both of the p-type conductive polysilicon and the n-type conductive polysilicon. The gate connection embedded electrode 28 preferably contains the same type of conductor as the gate embedded electrode 23.

The transistor structure T3 includes a plurality of trench electrode type emitter structures 30 formed in the first main surface 3 in the corresponding active region 6. The emitter structure 30 may be referred to as a “second trench structure,” a “trench emitter structure,” or the like. A potential (emitter potential in this embodiment) different from the gate potential is to be applied to the emitter structure 30.

In this embodiment, at least two emitter structures 30 are respectively arranged in regions between adjacent pairs of gate structures 20. Specifically, the plurality of emitter structures 30 are respectively formed in a mesa region defined by the pair of gate structures 20 and the pair of gate connection structures 25.

The plurality of emitter structures 30 each extend in a band shape in the first direction X in conformance to the extension direction of the plurality of gate structures 20, and are formed at an interval in the second direction Y from the plurality of gate connection structures 25.

The plurality of emitter structures 30 each have a length shorter than the length of the plurality of gate structures 20 in the longitudinal direction (first direction X). The plurality of emitter structures 30 each have one end portion on one side (third side surface 5C side) and the other end portion on the other side (fourth side surface 5D side) in the longitudinal direction (first direction X).

The plurality of emitter structures 30 may each have a width less than the widths of the plurality of street regions 9. The width of the emitter structure 30 is a width in a direction (second direction Y) orthogonal to the extension direction (first direction X) of the emitter structure 30. The width of the emitter structure 30 may be substantially equal to the width of the gate structure 20. As a matter of course, the width of the emitter structure 30 may be larger than the width of the gate structure 20, or may be smaller than the width of the gate structure 20.

The width of the emitter structure 30 may be 0.5 μm or more and 5 μm or less. The width of the emitter structure 30 may have a value belonging to at least one of the ranges of 0.5 μm or more and 1 μm or less, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less. The width of the emitter structure 30 is preferably 1 μm or more and 2.5 μm or less.

The plurality of emitter structures 30 penetrate the base region 15 to reach the drift region 12. The plurality of emitter structures 30 are respectively formed at an interval on the first main surface 3 side from the depth position of the intermediate portion of the drift region 12, and oppose the buffer region 13 and the collector region 14 with a part of the drift region 12 interposed therebetween in the thickness direction.

The plurality of emitter structures 30 may be formed in a tapered shape toward the bottom wall. As a matter of course, the plurality of emitter structures 30 may be formed substantially perpendicular to the first main surface 3. The plurality of emitter structures 30 may have bottom walls formed in a curved shape toward the second main surface 4. As a matter of course, the bottom walls of the plurality of emitter structures 30 may be formed substantially parallel to the first main surface 3. In this case, the bottom wall corner portions of the plurality of emitter structures 30 may be formed in a curved shape.

The emitter structure 30 may have a depth substantially equal to the depth of the gate structure 20. As a matter of course, the depth of the emitter structure 30 may be larger than the depth of the gate structure 20, or may be smaller than the depth of the gate structure 20.

The depths of the plurality of emitter structures 30 may be 0.5 μm or more and 10 μm or less. The depth of the emitter structure 30 may have a value belonging to at least one of the ranges of 0.5 μm or more and 1 μm or less, 1 μm or more and 2 μm or less, 2 μm or more and 4 μm or less, 4 μm or more and 6 μm or less, 6 μm or more and 8 μm or less, and 8 μm or more and 10 μm or less. The depth of the emitter structure 30 is preferably 4 μm or more and 8 μm or less.

A first trench pitch between the central portion of the gate structure 20 and the central portion of the emitter structure 30 may be 1 μm or more and 5 μm or less. The first trench pitch may have a value belonging to at least one of the ranges of 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less. The first trench pitch is preferably 1.5 μm or more and 3.5 μm or less.

The plurality of emitter structures 30 each include an emitter trench 31, an emitter insulating film 32, and an emitter embedded electrode 33. The emitter trench 31 is formed in the first main surface 3 and defines a wall surface (side wall and bottom wall) of the emitter structure 30.

The emitter insulating film 32 covers the wall surface of the emitter trench 31. The emitter insulating film 32 may include at least one of a silicon oxide film, a silicon nitride film, and a silicon oxynitride film. The emitter insulating film 32 preferably includes the same type of insulator as the gate insulating film 22. In this embodiment, the emitter insulating film 32 has a single-layer structure formed of a silicon oxide film. The emitter insulating film 32 particularly preferably includes a silicon oxide film formed of the oxide of the chip 2.

The emitter insulating film 32 may have a thickness substantially equal to the thickness of the gate insulating film 22. As a matter of course, the thickness of the emitter insulating film 32 may be larger than the thickness of the gate insulating film 22, or may be smaller than the thickness of the gate insulating film 22.

The emitter insulating film 32 may have a thickness of 10 nm or more and 200 nm or less. The thickness of the emitter insulating film 32 may have a value belonging to at least one of the ranges of 10 nm or more and 25 nm or less, 25 nm or more and 50 nm or less, 50 nm or more and 75 nm or less, 75 nm or more and 100 nm or less, 100 nm or more and 125 nm or less, 125 nm or more and 150 nm or less, 150 nm or more and 175 nm or less, and 175 nm or more and 200 nm or less. The thickness of the emitter insulating film 32 is preferably 100 nm or more and 150 nm or less.

The emitter embedded electrode 33 is embedded in the emitter trench 31 with the emitter insulating film 32 interposed therebetween. The emitter embedded electrode 33 opposes the drift region 12 and the base region 15 with the emitter insulating film 32 interposed therebetween.

The electrode surface of the emitter embedded electrode 33 may be located on the bottom wall side of the emitter trench 31 with respect to the first main surface 3. The emitter embedded electrode 33 may contain one or both of the p-type conductive polysilicon and the n-type conductive polysilicon. The emitter embedded electrode 33 preferably contains the same type of conductor as the gate embedded electrode 23.

The transistor structure T3 includes a plurality of emitter connection structures 35 formed in the first main surface 3 to be connected to the plurality of emitter structures 30 in the corresponding active region 6. An emitter potential is to be applied to the plurality of emitter connection structures 35. The emitter connection structure 35 may be referred to as a “second trench connection structure,” a “trench emitter connection structure,” or the like.

The plurality of emitter connection structures 35 are respectively arranged on both end portion sides of the plurality of emitter structures 30 to be connected to one end portion and the other end portion of the plurality of emitter structures 30 in the first direction X.

The plurality of emitter connection structures 35 include the emitter connection structure 35 on one end portion side of the plurality of emitter structures 30 and the emitter connection structure 35 on the other end portion side of the plurality of emitter structures 30. The emitter connection structure 35 on one end portion side extends in a band shape in the second direction Y and is connected to one end portions of the plurality of adjacent emitter structures 30. The emitter connection structure 35 on the other end portion side extends in a band shape in the second direction Y and is connected to the other end portions of the plurality of adjacent emitter structures 30.

The plurality of emitter connection structures 35 penetrate the base region 15 to reach the drift region 12. The plurality of emitter connection structures 35 are respectively formed at an interval on the first main surface 3 side from the depth position of the intermediate portion of the drift region 12, and oppose the buffer region 13 and the collector region 14 with a part of the drift region 12 interposed therebetween in the thickness direction.

The plurality of emitter connection structures 35 may be formed in a tapered shape toward the bottom wall. As a matter of course, the plurality of emitter connection structures 35 may be formed substantially perpendicular to the first main surface 3.

The plurality of emitter connection structures 35 may have bottom walls formed in a curved shape toward the second main surface 4. As a matter of course, the bottom walls of the plurality of emitter connection structures 35 may be formed substantially parallel to the first main surface 3. In this case, the bottom wall corner portions of the plurality of emitter connection structures 35 may be formed in a curved shape.

The plurality of emitter connection structures 35 may each have a width substantially equal to the width of the emitter structure 30 (gate structure 20). As a matter of course, the width of the emitter connection structure 35 may be larger than the width of the emitter structure 30, or may be smaller than the width of the emitter structure 30.

The width of the emitter connection structure 35 may be 0.5 μm or more and 5 μm or less. The width of the emitter connection structure 35 may have a value belonging to at least one of the ranges of 0.5 μm or more and 1 μm or less, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less. The width of the emitter connection structure 35 is preferably 1 μm or more and 2.5 μm or less.

The plurality of emitter connection structures 35 may each have a depth substantially equal to the depth of the emitter structure 30 (gate structure 20). As a matter of course, the depth of the emitter connection structure 35 may be larger than the depth of the emitter structure 30, or may be smaller than the depth of the emitter structure 30.

The depth of the emitter connection structure 35 may be 0.5 μm or more and 10 μm or less. The depth of the emitter connection structure 35 may have a value belonging to at least one of the ranges of 0.5 μm or more and 1 μm or less, 1 μm or more and 2 μm or less, 2 μm or more and 4 μm or less, 4 μm or more and 6 μm or less, 6 μm or more and 8 μm or less, and 8 μm or more and 10 μm or less. The depth of the emitter connection structure 35 is preferably 4 μm or more and 8 μm or less.

The plurality of emitter connection structures 35 each include an emitter connection trench 36, an emitter connection insulating film 37, and an emitter connection embedded electrode 38. The emitter connection trench 36 is formed in the first main surface 3 and defines a wall surface (side wall and bottom wall) of the emitter connection structure 35. The emitter connection trench 36 communicates with the plurality of emitter trenches 31.

The emitter connection insulating film 37 may include at least one of a silicon oxide film, a silicon nitride film, and a silicon oxynitride film. The emitter connection insulating film 37 preferably includes the same type of insulator as the emitter insulating film 32 (gate insulating film 22). In this embodiment, the emitter connection insulating film 37 has a single-layer structure formed of a silicon oxide film. The emitter connection insulating film 37 particularly preferably includes a silicon oxide film formed of the oxide of the chip 2.

The emitter connection insulating film 37 covers the wall surface of the emitter connection trench 36 in a film shape. The emitter connection insulating film 37 is connected to the emitter insulating film 32 at a communication portion between the emitter trench 31 and the emitter connection trench 36.

The emitter connection insulating film 37 may have a thickness substantially equal to the thickness of the emitter insulating film 32 (gate insulating film 22). As a matter of course, the thickness of the emitter connection insulating film 37 may be larger than the thickness of the emitter insulating film 32 (gate insulating film 22), or may be smaller than the thickness of the emitter insulating film 32 (gate insulating film 22).

The emitter connection insulating film 37 may have a thickness of 10 nm or more and 200 nm or less. The thickness of the emitter connection insulating film 37 may have a value belonging to at least one of the ranges of 10 nm or more and 25 nm or less, 25 nm or more and 50 nm or less, 50 nm or more and 75 nm or less, 75 nm or more and 100 nm or less, 100 nm or more and 125 nm or less, 125 nm or more and 150 nm or less, 150 nm or more and 175 nm or less, and 175 nm or more and 200 nm or less. The thickness of the emitter connection insulating film 37 is preferably 100 nm or more and 150 nm or less.

The emitter connection embedded electrode 38 is embedded in the emitter connection trench 36 with the emitter connection insulating film 37 interposed therebetween. The emitter connection embedded electrode 38 is connected to the emitter embedded electrode 33 at a communication portion between the emitter trench 31 and the emitter connection trench 36. The emitter connection embedded electrode 38 opposes the drift region 12 and the base region 15 with the emitter connection insulating film 37 interposed therebetween.

The electrode surface of the emitter connection embedded electrode 38 may be located on the bottom wall side of the emitter connection trench 36 with respect to the first main surface 3. The emitter connection embedded electrode 38 may contain one or both of the p-type conductive polysilicon and the n-type conductive polysilicon. The emitter connection embedded electrode 38 preferably contains the same type of conductor as the emitter embedded electrode 33 (gate embedded electrode 23).

The transistor structure T3 includes a plurality of n-type emitter regions 40 (impurity regions) formed in a surface layer portion of the first main surface 3 of the corresponding active region 6. The plurality of emitter regions 40 form emitters of the main transistor structure T1.

The emitter region 40 has an n-type impurity concentration higher than the n-type impurity concentration of the drift region 12. In this embodiment, the emitter region 40 has an n-type impurity concentration higher than the p-type impurity concentration of the base region 15, and the conductivity type of the base region 15 is replaced from the p-type to the n-type.

The plurality of emitter regions 40 are respectively formed in the surface layer portion of the base region 15 on both sides of the plurality of gate structures 20, and extend in a band shape in the first direction X in conformance to the extension direction of the plurality of gate structures 20. The plurality of emitter regions 40 are formed at an interval on the first main surface 3 side from the bottom portion of the base region 15.

The plurality of emitter regions 40 oppose the gate embedded electrode 23 of the corresponding gate structure 20 with the gate insulating film 22 of the corresponding gate structure 20 interposed therebetween. The plurality of emitter regions 40 may oppose the emitter embedded electrode 33 of the corresponding emitter structure 30 with the emitter insulating film 32 of the corresponding emitter structure 30 interposed therebetween. As a matter of course, the plurality of emitter regions 40 may be formed at an interval from the plurality of emitter structures 30.

The transistor structure T3 includes a plurality of p-type contact regions 41 formed in a region different from the plurality of emitter regions 40 in the surface layer portion of the base region 15. The plurality of contact regions 41 have a p-type impurity concentration higher than the p-type impurity concentration of the base region 15. The plurality of contact regions 41 are respectively formed on both sides of the plurality of gate structures 20 at an interval from the plurality of gate structures 20 and the plurality of emitter structures 30.

The plurality of contact regions 41 are respectively formed in regions on the bottom portion side of the base region 15 with respect to the plurality of emitter regions 40. The plurality of contact regions 41 are formed at an interval on the first main surface 3 side from the bottom portion of the base region 15. The plurality of contact regions 41 each extend in a band shape in the first direction X in conformance to the extension direction of the plurality of gate structures 20.

The transistor structure T3 includes a plurality of n-type storage regions 42 formed in the surface layer portion of the first main surface 3 of the corresponding active region 6. The storage region 42 may be referred to as a “carrier storage region.” The plurality of storage regions 42 have an n-type impurity concentration higher than the n-type impurity concentration of the drift region 12. The n-type impurity concentration of the plurality of storage regions 42 may be lower than the n-type impurity concentration of the emitter region 40.

The plurality of storage regions 42 are formed in regions immediately below the base region 15 on both sides of the plurality of gate structures 20, and respectively oppose the corresponding emitter regions 40 in the thickness direction. The plurality of storage regions 42 extend in a band shape in the first direction X in conformance to the extension direction of the plurality of gate structures 20.

The plurality of storage regions 42 are formed in a thickness range between the bottom portion of the base region 15 and the bottom wall of the gate structure 20. The plurality of storage regions 42 are formed at an interval on the bottom portion side of the base region 15 from the depth position of the bottom wall of the gate structure 20.

The bottom portions of the plurality of storage regions 42 may be located on the first main surface 3 side with respect to the depth position of the intermediate portion of the gate structure 20. The bottom portion of the plurality of storage regions 42 may be located on the bottom wall side of the gate structure 20 with respect to the depth position of the intermediate portion of the gate structure 20.

The transistor structure T3 includes a plurality of p-type well regions 43 formed in the surface layer portion of the first main surface 3 in the corresponding active region 6. The plurality of well regions 43 have a p-type impurity concentration lower than the p-type impurity concentration of the contact region 41.

The plurality of well regions 43 may have a p-type impurity concentration higher than the p-type impurity concentration of the base region 15. As a matter of course, the p-type impurity concentration of the plurality of well regions 43 may be lower than the p-type impurity concentration of the base region 15. In this embodiment, the plurality of well regions 43 are formed in an electrically floating state.

The plurality of well regions 43 are respectively formed in regions between adjacent pairs of emitter structures 30. Specifically, the plurality of well regions 43 are respectively formed in a mesa region defined by the plurality of emitter structures 30 and the plurality of emitter connection structures 35.

The plurality of well regions 43 each have a bottom portion located on the bottom wall side of the plurality of emitter structures 30 with respect to the depth position of the bottom portion of the base region 15. The bottom portions of the plurality of well regions 43 are respectively located closer to the bottom wall side of the plurality of emitter structures 30 than the depth position of the intermediate portion of the plurality of emitter structures 30. In this embodiment, the bottom portions of the plurality of well regions 43 are located on the second main surface 4 side with respect to the bottom walls of the plurality of emitter structures 30.

The plurality of well regions 43 may have portions (bottom portions) covering the bottom walls of the plurality of emitter structures 30 and the bottom walls of the plurality of emitter connection structures 35. The plurality of well regions 43 each extend in a band shape in the first direction X in conformance to the extension direction of the emitter structure 30, and are connected to the plurality of emitter structures 30 and the plurality of emitter connection structures 35.

The plurality of well regions 43 constitute an injection enhanced structure (IE structure) together with the plurality of emitter structures 30. The IE structure restricts a movement path of holes flowing into the base region 15 and accumulates holes in a region immediately below the base region 15. That is, the IE structure promotes reduction in on-resistance and reduction in on-voltage from the inside of the chip 2.

With reference to FIG. 7, the semiconductor device 1A includes a p-type outer peripheral well region 44 formed in the surface layer portion of the first main surface 3 in the outer peripheral region 8. The outer peripheral well region 44 has a p-type impurity concentration lower than the p-type impurity concentration of the contact region 41. The outer peripheral well region 44 may have a p-type impurity concentration higher than the p-type impurity concentration of the base region 15. As a matter of course, the p-type impurity concentration of the outer peripheral well region 44 may be lower than the p-type impurity concentration of the base region 15.

The p-type impurity concentration of the outer peripheral well region 44 may be substantially equal to the p-type impurity concentration of the well region 43. As a matter of course, the p-type impurity concentration of the outer peripheral well region 44 may be higher than the p-type impurity concentration of the well region 43, or may be lower than the p-type impurity concentration of the well region 43.

The outer peripheral well region 44 is formed at an interval inward from the peripheral edge of the first main surface 3, and extends in a band shape along the peripheral edge of the first main surface 3. In this embodiment, the outer peripheral well region 44 is formed in an annular shape surrounding the plurality of active regions 6.

The outer peripheral well region 44 is formed deeper than the base region 15 and is in contact with the outermost gate connection structure 25. The outer peripheral well region 44 is formed deeper than the outermost gate connection structure 25, and has a portion along the bottom wall of the outermost gate connection structure 25. In this embodiment, the outer peripheral well region 44 has portions led out from the outside of the plurality of active regions 6 into the plurality of active regions 6 and covering the bottom walls of the plurality of gate structures 20.

The outer peripheral well region 44 extends in the vertical direction Z along the side walls of the plurality of gate structures 20 and the side walls of the plurality of gate connection structures 25 in the plurality of active regions 6, and is connected to the plurality of base regions 15 in the surface layer portion of the first main surface 3. An emitter potential is to be applied to the outer peripheral well region 44 through the plurality of base regions 15.

The depth of the outer peripheral well region 44 may be substantially equal to the depths of the plurality of well regions 43. As a matter of course, the depth of the outer peripheral well region 44 may be larger than the depths of the plurality of well regions 43, or may be smaller than the depths of the plurality of well regions 43.

With reference to FIG. 8, the semiconductor device 1A includes a plurality of p-type street well regions 45 respectively formed in a surface layer portion of the first main surface 3 in the plurality of street regions 9. One street well region 45 has a portion formed in a surface layer portion of the first main surface 3 in the temperature detection region 10.

The street well region 45 may have a p-type impurity concentration higher than the p-type impurity concentration of the base region 15. As a matter of course, the p-type impurity concentration of the street well region 45 may be lower than the p-type impurity concentration of the base region 15.

The p-type impurity concentration of the street well region 45 may be substantially equal to the p-type impurity concentration of the well region 43. As a matter of course, the p-type impurity concentration of the street well region 45 may be higher than the p-type impurity concentration of the well region 43, or may be lower than the p-type impurity concentration of the well region 43.

The p-type impurity concentration of the street well region 45 may be substantially equal to the p-type impurity concentration of the outer peripheral well region 44. As a matter of course, the p-type impurity concentration of the street well region 45 may be higher than the p-type impurity concentration of the outer peripheral well region 44, or may be lower than the p-type impurity concentration of the outer peripheral well region 44.

The plurality of street well regions 45 are formed in a layer shape extending along the first main surface 3 in regions between the gate connection structure 25 on one active region 6 side and the gate connection structure 25 on the other active region 6 side, and are exposed from the first main surface 3. The plurality of street well regions 45 each extend in a band shape in the second direction Y in conformance to the extension direction of the plurality of street regions 9. The plurality of street well regions 45 are connected to the outer peripheral well region 44 in the outer peripheral region 8.

The plurality of street well regions 45 are formed deeper than the plurality of base regions 15 and are in contact with the plurality of gate connection structures 25. Specifically, the plurality of street well regions 45 are formed deeper than the plurality of gate connection structures 25, and have portions along the bottom walls of the plurality of gate connection structures 25.

In this embodiment, the plurality of street well regions 45 have a width larger than the width of the corresponding street region 9, protrude from the corresponding street region 9 into the plurality of active regions 6, and have portions that cover the bottom walls of the plurality of gate structures 20.

The plurality of street well regions 45 extend in the vertical direction Z along the side walls of the plurality of gate structures 20 and the side walls of the plurality of gate connection structures 25 in the plurality of active regions 6, and are connected to the plurality of base regions 15 in the surface layer portion of the first main surface 3. An emitter potential is to be applied to the plurality of street well regions 45 through the plurality of base regions 15.

The depths of the plurality of street well regions 45 may be substantially equal to the depths of the plurality of well regions 43. As a matter of course, the depths of the plurality of street well regions 45 may be larger than the depths of the plurality of well regions 43, or may be smaller than the depths of the plurality of street well regions 45.

The depths of the plurality of street well regions 45 may be substantially equal to the depth of the outer peripheral well region 44. As a matter of course, the depths of the plurality of street well regions 45 may be larger than the depth of the outer peripheral well region 44, or may be smaller than the depth of the outer peripheral well region 44.

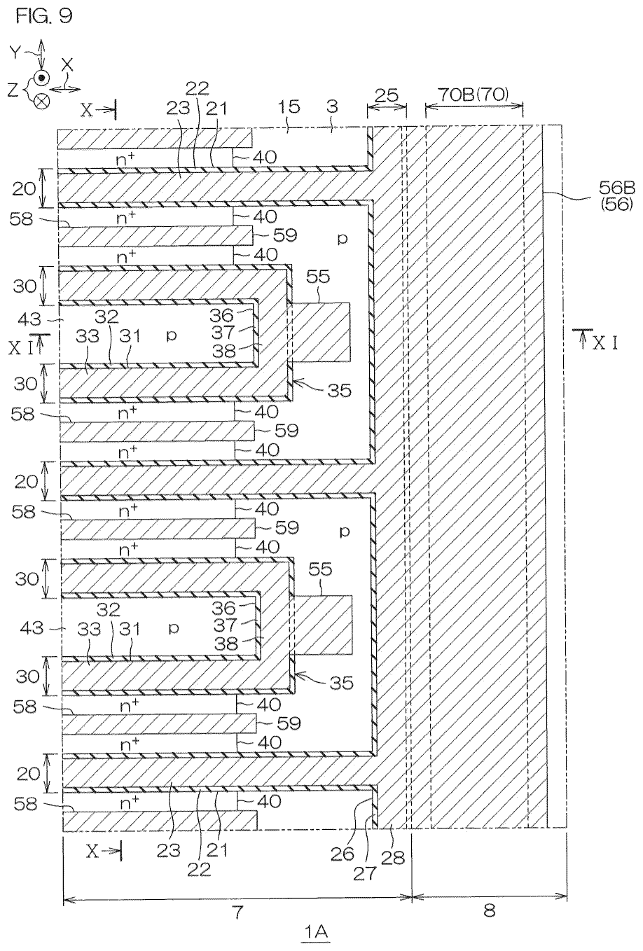

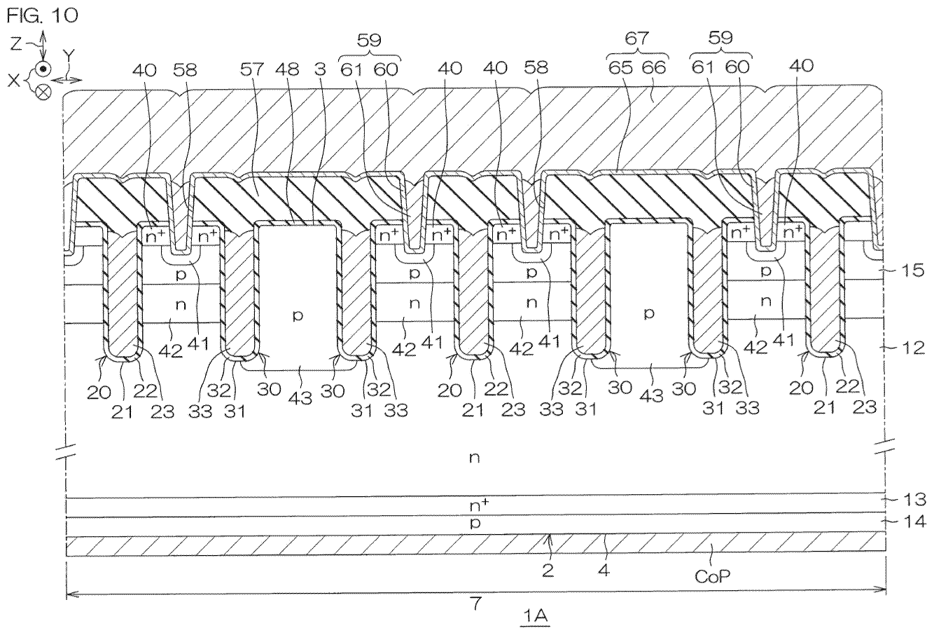

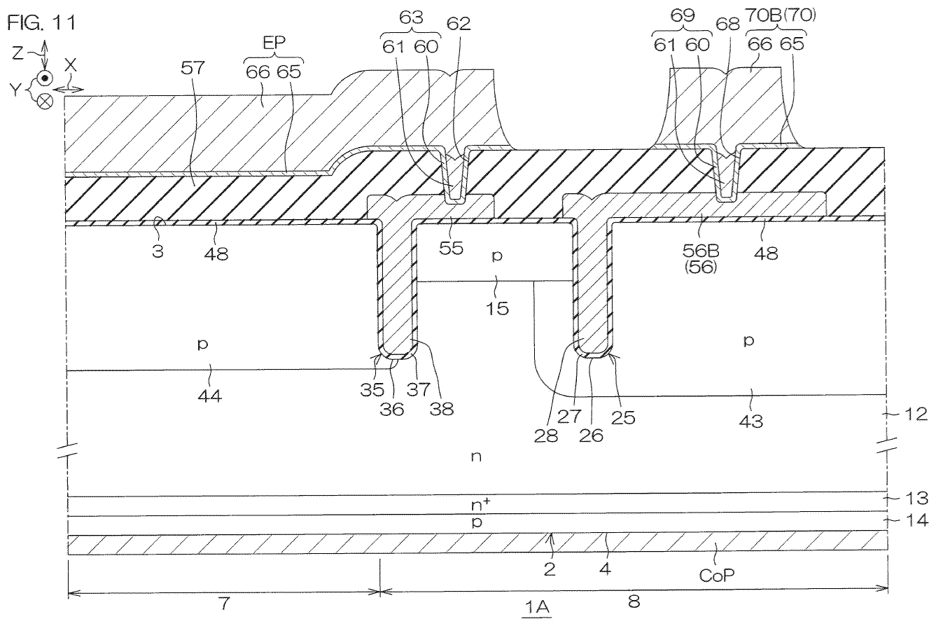

FIG. 9 is an enlarged plan view showing a main portion of the monitor region 7. FIG. 10 is a cross-sectional view taken along line X-X shown in FIG. 9. FIG. 11 is a cross-sectional view taken along line XI-XI shown in FIG. 9.

Referring to FIGS. 9 to 11, the semiconductor device 1A includes the monitor transistor structure T2 in the monitor region 7. Similarly to the transistor structure T3 (active region 6), the monitor transistor structure T2 (monitor region 7) includes the base region 15, the plurality of gate structures 20, the plurality of gate connection structures 25, the plurality of emitter structures 30, the plurality of emitter connection structures 35, the plurality of emitter regions 40, the contact region 41, the plurality of storage regions 42, and the plurality of well regions 43.

The base region 15, the gate structure 20, the gate connection structure 25, the emitter structure 30, the emitter connection structure 35, the emitter region 40, the contact region 41, the storage region 42, and the well region 43 of the monitor region 7 may be referred to as a “monitor base region (15),” a “monitor gate structure (20),” a “monitor gate connection structure (25),” a “monitor emitter structure (30),” a “monitor emitter connection structure (35),” a “monitor emitter region (40),” a “monitor contact region (41),” a “monitor storage region (42),” and a “monitor well region (43),” respectively.

These constituent elements in the monitor region 7 each have the same layout as the corresponding constituent elements in the active region 6. The description of corresponding constituent elements in the active region 6 applies to the description of these constituent elements in the monitor region 7. These constituent elements of the monitor region 7 are laid out in a planar area smaller than the total planar area of the plurality of active regions 6.

That is, since the channel area of the monitor region 7 (total area of the emitter region 40) is smaller than the channel area of the active region 6 (total area of the emitter region 40), the monitor current Im of the monitor transistor structure T2 is less than the output current Ice of the main transistor structure T1 (transistor structure T3).

The semiconductor device 1A includes a main surface insulating film 48 selectively covering the first main surface 3. The main surface insulating film 48 may be referred to as an “insulating film,” a “first dielectric film,” or the like. The main surface insulating film 48 may include at least one among a silicon oxide film, a silicon nitride film, and a silicon oxynitride film.

The main surface insulating film 48 preferably includes the same type of insulator as the gate insulating film 22 (emitter insulating film 32). In this embodiment, the main surface insulating film 48 has a single-layer structure formed of the silicon oxide film. The main surface insulating film 48 particularly preferably includes a silicon oxide film constituted of an oxide of the chip 2.

The main surface insulating film 48 has portions selectively covering the plurality of active regions 6, a portion selectively covering the monitor region 7, a portion selectively covering the outer peripheral region 8, and portions selectively covering the plurality of street regions 9.

The main surface insulating film 48 covers the plurality of base regions 15, the plurality of emitter regions 40, and the plurality of well regions 43 in the plurality of active regions 6. The main surface insulating film 48 is connected to the plurality of gate insulating films 22, the plurality of gate connection insulating films 27, the plurality of emitter insulating films 32, and the plurality of emitter connection insulating films 37 in the plurality of active regions 6, and exposes the plurality of gate embedded electrodes 23, the plurality of gate connection embedded electrodes 28, the plurality of emitter embedded electrodes 33, and the plurality of emitter connection embedded electrodes 38.

The main surface insulating film 48 covers the plurality of base regions 15, the plurality of emitter regions 40, and the plurality of well regions 43 in the monitor region 7. The main surface insulating film 48 is connected to the plurality of gate insulating films 22, the plurality of gate connection insulating films 27, the plurality of emitter insulating films 32, and the plurality of emitter connection insulating films 37 in the monitor region 7, and exposes the plurality of gate embedded electrodes 23, the plurality of gate connection embedded electrodes 28, the plurality of emitter embedded electrodes 33, and the plurality of emitter connection embedded electrodes 38.

The main surface insulating film 48 covers the outer peripheral well region 44 in the outer peripheral region 8. The main surface insulating film 48 is connected to the plurality of gate connection insulating films 27 in the outer peripheral region 8, and exposes the plurality of gate connection embedded electrodes 28. The main surface insulating film 48 may be continuous with the peripheral edge (first to fourth side surfaces 5A to 5D) of the chip 2. As a matter of course, the main surface insulating film 48 may be formed at an interval inward from the peripheral edge of the chip 2, and expose the drift region 12 from the peripheral edge portion of the chip 2.

The main surface insulating film 48 covers the plurality of street well regions 45 in the plurality of street regions 9. The main surface insulating film 48 is connected to the plurality of gate connection insulating films 27 in the plurality of street regions 9, and exposes the plurality of gate connection embedded electrodes 28.

The main surface insulating film 48 may have a thickness substantially equal to the thickness of the gate insulating film 22 (gate connection insulating film 27). As a matter of course, the thickness of the main surface insulating film 48 may be larger than the thickness of the gate insulating film 22 (gate connection insulating film 27), or may be smaller than the thickness of the gate insulating film 22 (gate connection insulating film 27).

The thickness of the main surface insulating film 48 may be substantially equal to the thickness of the emitter insulating film 32 (emitter connection insulating film 37). As a matter of course, the thickness of the main surface insulating film 48 may be larger than the thickness of the emitter insulating film 32 (emitter connection insulating film 37), or may be smaller than the thickness of the emitter insulating film 32 (emitter connection insulating film 37).

The thickness of the main surface insulating film 48 may be 10 nm or more and 200 nm or less. The thickness of the main surface insulating film 48 may have a value belonging to at least one of the ranges of 10 nm or more and 25 nm or less, 25 nm or more and 50 nm or less, 50 nm or more and 75 nm or less, 75 nm or more and 100 nm or less, 100 nm or more and 125 nm or less, 125 nm or more and 150 nm or less, 150 nm or more and 175 nm or less, and 175 nm or more and 200 nm or less. The thickness of the main surface insulating film 48 is preferably 100 nm or more and 150 nm or less.

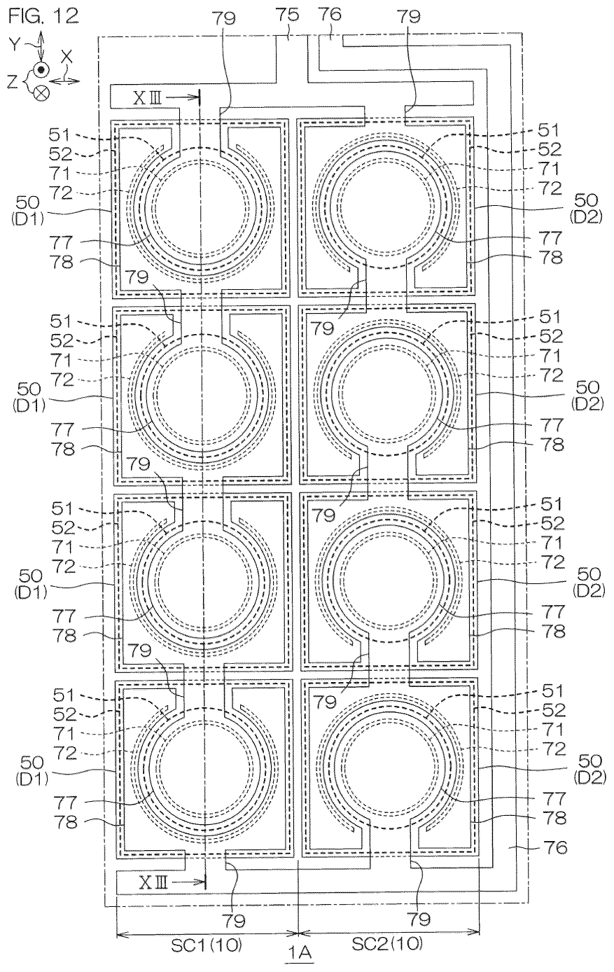

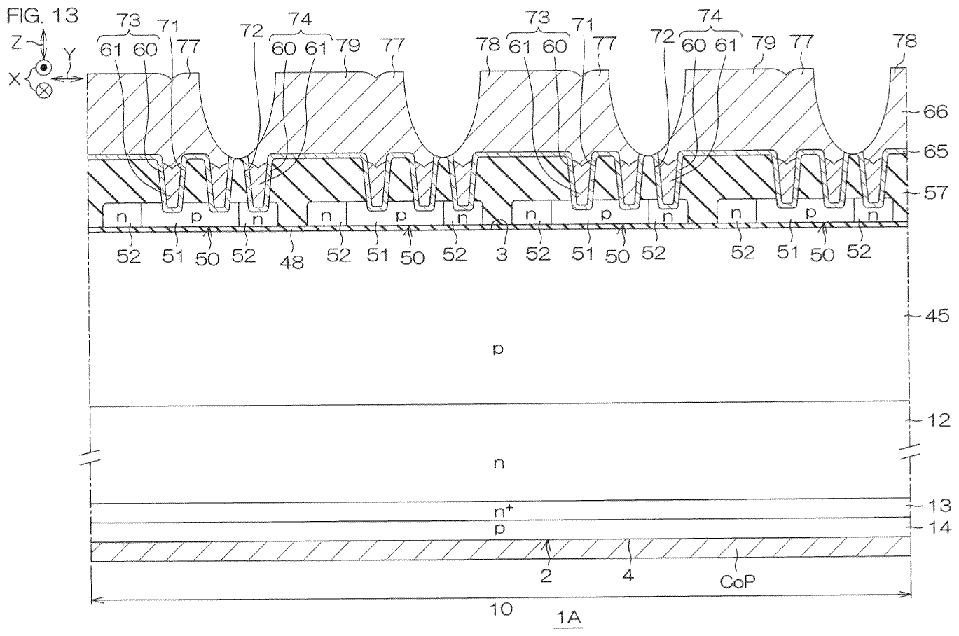

FIG. 12 is an enlarged plan view showing the temperature detection region 10. FIG. 13 is a cross-sectional view taken along line XIII-XIII shown in FIG. 12. With reference to FIGS. 12 and 13, the semiconductor device 1A includes the temperature-sensitive diode structure D arranged on the main surface insulating film 48 in the temperature detection region 10. Hereinafter, the configuration of the temperature-sensitive diode structure D as one constituent element of the semiconductor device 1A will be described.

The temperature-sensitive diode structure D includes one or a plurality of (in this embodiment, a plurality of) polysilicon layers 50 arranged on the main surface insulating film 48. The number of polysilicon layers 50 is optional, and is appropriately adjusted according to the number of first diodes D1 and the number of second diodes D2.

In this embodiment, the semiconductor device 1A includes four polysilicon layers 50 for the first diode D1 and four polysilicon layers 50 for the second diode D2. In this embodiment, the plurality of polysilicon layers 50 are arranged in a matrix of 4 rows×2 columns at an interval in the first direction X and the second direction Y.

In this embodiment, the four polysilicon layers 50 for the first diode D1 are arranged in a row in the first column (one side in the second direction Y), and the four polysilicon layers 50 for the second diode D2 are arranged in a row in the second column (the other side in the second direction Y).

The plurality of polysilicon layers 50 are directly arranged on the main surface insulating film 48, and oppose the street well region 45 with the main surface insulating film 48 interposed therebetween. In this embodiment, the plurality of polysilicon layers 50 are formed in a polygonal shape having four sides parallel to a peripheral edge of the chip 2 in plan view. The plurality of polysilicon layers 50 may be formed in a quadrangular shape, a hexagonal shape, a circular shape, or the like in plan view.

The plurality of polysilicon layers 50 have a thickness larger than the thickness of the main surface insulating film 48. The thicknesses of the plurality of polysilicon layers 50 may be less than the depth (thickness) of the street well region 45. The thicknesses of the plurality of polysilicon layers 50 may be less than the depth of the gate structure 20 (emitter structure 30). The thicknesses of the plurality of polysilicon layers 50 may be less than the depth of the gate connection structure 25 (emitter connection structure 35).

The thicknesses of the plurality of polysilicon layers 50 may be 0.1 μm or more and 2 μm or less. The thickness of the polysilicon layer 50 may have a value belonging to at least one of the ranges of 0.1 μm or more and 0.25 μm or less, 0.25 μm or more and 0.5 μm or less, 0.5 μm or more and 0.75 μm or less, 0.75 μm or more and 1 μm or less, 1.25 μm or more and 1.5 μm or less, 1.5 μm or more and 1.75 μm or less, and 1.75 μm or more and 2 μm or less. The thickness of the polysilicon layer 50 is preferably 0.25 μm or more and 1.25 μm or less.

The temperature-sensitive diode structure D includes a plurality of p-type anode regions 51 respectively formed in the plurality of polysilicon layers 50. The plurality of anode regions 51 are formed in an inner portion (preferably a central portion) of the corresponding polysilicon layer 50 at an interval from a peripheral edge of the corresponding polysilicon layer 50.

The plurality of anode regions 51 are formed in a polygonal shape or a circular shape in plan view. The plurality of anode regions 51 may be formed in a quadrangular shape, a hexagonal shape, or the like in plan view. The plurality of anode regions 51 are formed over the entire thickness range of the corresponding polysilicon layer 50.

The temperature-sensitive diode structure D includes a plurality of n-type cathode regions 52 respectively formed in the plurality of polysilicon layers 50. The plurality of cathode regions 52 are respectively formed at peripheral edge portions of the corresponding polysilicon layers 50.

The plurality of cathode regions 52 each extend in a band shape along the peripheral edge of the corresponding anode region 51 in plan view. In this embodiment, the plurality of cathode regions 52 each extend in an annular shape along the peripheral edge of the corresponding polysilicon layer 50 in plan view, and are respectively connected electrically to the corresponding anode regions 51 over the entire periphery.

The plurality of cathode regions 52 are formed over the entire thickness range of the corresponding polysilicon layer 50, and are respectively exposed from the side walls of the corresponding polysilicon layer 50. The plurality of cathode regions 52 each form a pn-junction portion as the first diode D1 or a pn-junction portion as the second diode D2 with the corresponding anode region 51.

Hereinafter, the wiring structure on the first main surface 3 will be described. With reference to FIGS. 1 to 11 again, the semiconductor device 1A includes a plurality of emitter wirings 55 respectively connected electrically to the corresponding emitter connection structure 35 on the first main surface 3 in the plurality of active regions 6 and the monitor region 7.

The plurality of emitter wirings 55 are respectively arranged on the main surface insulating film 48, and are respectively connected to the corresponding emitter connection structures 35. In this embodiment, the plurality of emitter wirings 55 are respectively formed integrally with the corresponding emitter connection embedded electrode 38, and each include a lead-out portion led out from the corresponding emitter connection embedded electrode 38 onto the main surface insulating film 48.

That is, the plurality of emitter wirings 55 each include the same type of conductor as the emitter connection embedded electrode 38 (one or both of the p-type conductive polysilicon and the n-type conductive polysilicon). The plurality of emitter wirings 55 are formed at an interval on the corresponding emitter connection structure 35 side from the plurality of gate connection structures 25, and oppose the base region 15 in the thickness direction with the main surface insulating film 48 interposed therebetween.

The plurality of emitter wirings 55 have a thickness larger than the thickness of the main surface insulating film 48. The thicknesses of the plurality of emitter wirings 55 may be less than the depth (thickness) of the well region 43. The thicknesses of the plurality of emitter wirings 55 may be less than the depth of the gate structure 20 (gate connection structure 25) and the depth of the emitter structure 30 (emitter connection structure 35). As a matter of course, the thicknesses of the plurality of emitter wirings 55 may be larger than the depth of the gate structure 20 (gate connection structure 25) and the depth of the emitter structure 30 (emitter connection structure 35).

The thicknesses of the plurality of emitter wirings 55 may be substantially equal to the thicknesses of the plurality of polysilicon layers 50. As a matter of course, the thicknesses of the plurality of emitter wirings 55 may be larger than the thicknesses of the plurality of polysilicon layers 50, or may be smaller than the thicknesses of the plurality of polysilicon layers 50.

The plurality of emitter wirings 55 may have a thickness of 0.1 μm or more and 2 μm or less. The thickness of the emitter wiring 55 may have a value belonging to at least one of the ranges of 0.1 μm or more and 0.25 μm or less, 0.25 μm or more and 0.5 μm or less, 0.5 μm or more and 0.75 μm or less, 0.75 μm or more and 1 μm or less, 1.25 μm or more and 1.5 μm or less, 1.5 μm or more and 1.75 μm or less, and 1.75 μm or more and 2 μm or less. The thickness of the emitter wiring 55 is preferably 0.25 μm or more and 1.25 μm or less.

The semiconductor device 1A includes a plurality of gate wirings 56 respectively connected electrically to the corresponding gate connection structures 25 on the first main surface 3 in the outer peripheral region 8 and the plurality of street regions 9.

The plurality of gate wirings 56 are respectively arranged on the main surface insulating film 48, and are respectively connected to the corresponding gate connection structures 25. In this embodiment, the plurality of gate wirings 56 are respectively formed integrally with the corresponding gate connection embedded electrode 28, and each include a lead-out portion led out from the corresponding gate connection embedded electrode 28 onto the main surface insulating film 48.

That is, the plurality of gate wirings 56 each include the same type of conductor as the gate connection embedded electrode 28 (one or both of the p-type conductive polysilicon and the n-type conductive polysilicon).

The plurality of gate wirings 56 include one or a plurality of (in this embodiment, a plurality of) first gate wirings 56A arranged in the outer peripheral region 8 and one or a plurality of (in this embodiment, a plurality of) second gate wirings 56B arranged in the plurality of street regions 9.

The plurality of first gate wirings 56A are arranged on the main surface insulating film 48 in the outer peripheral region 8, and are routed in a band shape to regions between the gate pad region 11G and the corresponding gate connection structure 25 (gate connection embedded electrode 28). The plurality of first gate wirings 56A are formed along the plurality of active regions 6, and each have a portion extending in the first direction X and a portion extending in the second direction Y.

The plurality of first gate wirings 56A oppose the outer peripheral well region 44 with the main surface insulating film 48 interposed therebetween. The plurality of first gate wirings 56A are led out from above the main surface insulating film 48 onto the gate connection structure 25 (gate connection embedded electrode 28) adjacent to the outer peripheral region 8, and are connected to the gate connection structure 25 (gate connection embedded electrode 28). The plurality of first gate wirings 56A are electrically connected to the plurality of gate structures 20 via the gate connection structure 25 (gate connection embedded electrode 28).

The plurality of second gate wirings 56B are respectively arranged on the main surface insulating film 48 in the plurality of street regions 9, and are routed in a band shape to regions between the gate pad region 11G and the corresponding gate connection structure 25 (gate connection embedded electrode 28).

The plurality of second gate wirings 56B each extend in a band shape in the second direction Y in conformance to the extension direction of the plurality of street regions 9. One second gate wiring 56B is routed to the street region 9 to bypass the plurality of polysilicon layers 50 (temperature-sensitive diode structure D).

The plurality of second gate wirings 56B are respectively connected to the gate connection structures 25 (gate connection embedded electrodes 28) of one and the other active regions 6 adjacent to each other in the first direction X. That is, the plurality of second gate wirings 56B are electrically connected to the plurality of gate structures 20 via the plurality of gate connection structures 25 (gate connection embedded electrodes 28) defining the plurality of street regions 9.

At least one gate wiring 56 (in this embodiment, one second gate wiring 56B) among the plurality of gate wirings 56 is connected to the gate connection structure 25 (gate connection embedded electrode 28) of the monitor region 7. As a result, the gate structure 20 of the monitor region 7 is on/off controlled simultaneously with the gate structure 20 of the active region 6.

The plurality of gate wirings 56 have a thickness larger than the thickness of the main surface insulating film 48. The thicknesses of the plurality of gate wirings 56 may be less than the depth (thickness) of the well region 43. The thicknesses of the plurality of gate wirings 56 may be less than the depth of the gate structure 20 (gate connection structure 25) and the depth of the emitter structure 30 (emitter connection structure 35). As a matter of course, the thicknesses of the plurality of gate wirings 56 may be larger than the depth of the gate structure 20 (gate connection structure 25) and the depth of the emitter structure 30 (emitter connection structure 35).

The thicknesses of the plurality of gate wirings 56 may be substantially equal to the thicknesses of the plurality of polysilicon layers 50. As a matter of course, the thicknesses of the plurality of gate wirings 56 may be larger than the thicknesses of the plurality of polysilicon layers 50, or may be smaller than the thicknesses of the plurality of polysilicon layers 50.

The thicknesses of the plurality of gate wirings 56 may be substantially equal to the thicknesses of the plurality of emitter wirings 55. As a matter of course, the thicknesses of the plurality of gate wirings 56 may be larger than the thicknesses of the plurality of emitter wirings 55, or may be smaller than the thicknesses of the plurality of emitter wirings 55.

The thicknesses of the plurality of gate wirings 56 may be 0.1 μm or more and 2 μm or less. The thickness of the gate wiring 56 may have a value belonging to at least one of the ranges of 0.1 μm or more and 0.25 μm or less, 0.25 μm or more and 0.5 μm or less, 0.5 μm or more and 0.75 μm or less, 0.75 μm or more and 1 μm or less, 1.25 μm or more and 1.5 μm or less, 1.5 μm or more and 1.75 μm or less, and 1.75 μm or more and 2 μm or less. The thickness of the gate wiring 56 is preferably 0.25 μm or more and 1.25 μm or less.

The semiconductor device 1A includes an interlayer film 57 that selectively covers the main surface insulating film 48. The interlayer film 57 may include at least one among a silicon oxide film, a silicon nitride film, and a silicon oxynitride film. The interlayer film 57 may have a single-layer structure including a single insulating film or a laminated structure including a plurality of insulating films.

In this case, the interlayer film 57 may include at least one among a non-doped silicate glass (NSG) film, a phosphor silicate glass (PSG) film, and a boron phosphor silicate glass (BPSG) film as an example of a silicon oxide film.

The interlayer film 57 has portions covering the plurality of active regions 6, a portion covering the monitor region 7, a portion covering the outer peripheral region 8, portions covering the plurality of street regions 9, and a portion covering the temperature detection region 10.

The interlayer film 57 covers the plurality of base regions 15, the plurality of emitter regions 40, and the plurality of well regions 43 in the plurality of active regions 6 and the monitor region 7 with the main surface insulating film 48 interposed therebetween. The interlayer film 57 covers the plurality of gate structures 20, the plurality of gate connection structures 25, the plurality of emitter structures 30, and the plurality of emitter connection structures 35 in the plurality of active regions 6 and the monitor region 7.

Specifically, the interlayer film 57 covers the plurality of gate embedded electrodes 23, the plurality of gate connection embedded electrodes 28, the plurality of emitter embedded electrodes 33, and the plurality of emitter connection embedded electrodes 38. In this embodiment, the interlayer film 57 enters the plurality of gate trenches 21, the plurality of gate connection trenches 26, the plurality of emitter trenches 31, and the plurality of emitter connection trenches 36 from above the main surface insulating film 48.

The interlayer film 57 has portions covering the electrode surfaces of the plurality of gate embedded electrodes 23 in the plurality of gate trenches 21. The interlayer film 57 has portions covering the electrode surfaces of the plurality of gate connection embedded electrodes 28 in the plurality of gate connection trenches 26.

The interlayer film 57 has portions covering the electrode surfaces of the plurality of emitter embedded electrodes 33 in the plurality of emitter trenches 31. The interlayer film 57 has portions covering the electrode surfaces of the plurality of emitter connection embedded electrodes 38 in the plurality of emitter connection trenches 36.

The interlayer film 57 covers the outer peripheral well region 44 with the main surface insulating film 48 interposed therebetween in the outer peripheral region 8. The interlayer film 57 may be continuous with the peripheral edge (first to fourth side surfaces 5A to 5D) of the chip 2. As a matter of course, the interlayer film 57 may be formed at an interval inward from the peripheral edge of the chip 2, and expose the drift region 12 from the peripheral edge portion of the chip 2.

The interlayer film 57 covers the plurality of street well regions 45 with the main surface insulating film 48 interposed therebetween in the plurality of street regions 9. The interlayer film 57 covers the plurality of polysilicon layers 50 in the temperature detection region 10.

The interlayer film 57 collectively covers the plurality of polysilicon layers 50 by filling gap portions between the plurality of polysilicon layers 50. The interlayer film 57 is in contact with the main surface insulating film 48 in the gap portion. That is, the interlayer film 57 opposes the street well region 45 with the main surface insulating film 48 interposed therebetween in the gap portion.

The interlayer film 57 has a thickness larger than the thickness of the main surface insulating film 48. The thickness of the interlayer film 57 may be less than the depth of the gate structure 20 (gate connection structure 25) and the depth of the emitter structure 30 (emitter connection structure 35). As a matter of course, the thickness of the interlayer film 57 may be larger than the depth of the gate structure 20 (gate connection structure 25) and the depth of the emitter structure 30 (emitter connection structure 35).

The thickness of the interlayer film 57 is preferably larger than the thicknesses of the plurality of polysilicon layers 50. As a matter of course, the thickness of the interlayer film 57 may be smaller than the thicknesses of the plurality of polysilicon layers 50. The thickness of the interlayer film 57 is preferably larger than the thicknesses of the plurality of emitter wirings 55.

As a matter of course, the thickness of the interlayer film 57 may be smaller than the thicknesses of the plurality of emitter wirings 55. The thickness of the interlayer film 57 is preferably larger than the thicknesses of the plurality of gate wirings 56. As a matter of course, the thickness of the interlayer film 57 may be smaller than the thicknesses of the plurality of gate wirings 56.

The interlayer film 57 may have a thickness of 0.1 μm or more and 3 μm or less. The thickness of the interlayer film 57 may have a value belonging to at least one of the ranges of 0.1 μm or more and 0.5 μm or less, 0.5 μm or more and 1 μm or less, 1 μm or more and 1.5 μm or less, 1.5 μm or more and 2 μm or less, 2 μm or more and 2.5 μm or less, and 2.5 μm or more and 3 μm or less. The thickness of the interlayer film 57 is preferably 0.5 μm or more and 2 μm or less.

The semiconductor device 1A includes a plurality of first emitter openings 58 formed in the interlayer film 57 in the plurality of active regions 6 and the monitor region 7. The plurality of first emitter openings 58 are respectively formed on both sides of the plurality of gate structures 20 at an interval from the plurality of gate structures 20, and penetrate the main surface insulating film 48 and the interlayer film 57 and expose the chip 2. Specifically, the plurality of first emitter openings 58 each expose the corresponding emitter region 40 and the corresponding contact region 41.

The plurality of first emitter openings 58 each have a bottom wall dug down in the thickness direction of the chip 2 from the height position of the first main surface 3 and located inside the chip 2. The bottom walls of the plurality of first emitter openings 58 are formed at an interval on the first main surface 3 side from the bottom portion of the corresponding base region 15, and each expose the corresponding contact region 41. The bottom walls of the plurality of first emitter openings 58 are formed at an interval on the first main surface 3 side from the bottom portion of the corresponding contact region 41.

The plurality of first emitter openings 58 may be formed in a tapered shape toward the bottom wall. As a matter of course, the plurality of first emitter openings 58 may be formed substantially perpendicular to the first main surface 3.

The plurality of first emitter openings 58 may have bottom walls formed in a curved shape toward the second main surface 4. As a matter of course, the plurality of first emitter openings 58 may be formed substantially parallel to the first main surface 3. In this case, the bottom wall corner portions of the plurality of first emitter openings 58 may be formed in a curved shape.

The plurality of first emitter openings 58 each extend in a band shape in conformance to the first direction X in conformance to the extension direction of the plurality of gate structures 20. The plurality of first emitter openings 58 each have a length shorter than the lengths of the plurality of gate structures 20 in the longitudinal direction (first direction X). The length of the plurality of first emitter openings 58 may be shorter than the length of the plurality of emitter structures 30.

The semiconductor device 1A includes a plurality of first emitter via electrodes 59 respectively embedded in the plurality of first emitter openings 58. The plurality of first emitter via electrodes 59 are electrically connected to the corresponding emitter region 40 and the corresponding contact region 41 in the plurality of first emitter openings 58.

The plurality of first emitter via electrodes 59 may have a laminated structure including a first electrode 60 and a second electrode 61 laminated in this order from the wall surface side of the plurality of first emitter openings 58.

The first electrode 60 is formed as a barrier electrode in a film shape on the wall surface of the first emitter opening 58. The first electrode 60 is electrically connected to the emitter region 40 and the contact region 41 in the first emitter opening 58.

The first electrode 60 may have a single-layer structure including a titanium film or a titanium nitride film. The first electrode 60 may have a laminated structure including a titanium film and a titanium nitride film. In this case, the titanium nitride film may be laminated on the titanium film.

The second electrode 61 is embedded in the first emitter opening 58 with the first electrode 60 interposed therebetween, and is electrically connected to the emitter region 40 and the contact region 41 via the first electrode 60. The second electrode 61 may include at least one of a tungsten film, a molybdenum film, a nickel film, a pure aluminum film, a pure copper film, an AlCu alloy film, an AlSi alloy film, or an AlSiCu alloy film. The second electrode 61 preferably includes a tungsten film.

The semiconductor device 1A includes a plurality of second emitter openings 62 formed in the interlayer film 57 in the plurality of active regions 6 and the monitor region 7. The plurality of second emitter openings 62 penetrate the interlayer film 57, and each expose the corresponding emitter wiring 55. In this embodiment, the plurality of second emitter openings 62 each have a bottom wall which is further dug down from the wiring surface of the corresponding emitter wiring 55 toward the main surface insulating film 48 side and is located within the corresponding emitter wiring 55.

The plurality of second emitter openings 62 may be formed in a tapered shape toward the bottom wall. As a matter of course, the plurality of second emitter openings 62 may be formed substantially perpendicular to the first main surface 3. The plurality of second emitter openings 62 may be formed in a polygonal shape, a circular shape, or the like in plan view. The plurality of second emitter openings 62 may be formed in a quadrangular shape or a hexagonal shape in plan view.

The semiconductor device 1A includes a plurality of second emitter via electrodes 63 respectively embedded in the plurality of second emitter openings 62. The plurality of second emitter via electrodes 63 are respectively connected mechanically and electrically to the corresponding emitter wiring 55 in the plurality of second emitter openings 62. Similarly to the first emitter via electrode 59, the plurality of second emitter via electrodes 63 may have a laminated structure including the first electrode 60 and the second electrode 61.

The semiconductor device 1A includes the above-described emitter pad EP that collectively covers the plurality of active regions 6 on the first main surface 3. The emitter pad EP is a terminal to which an emitter potential is to be applied from an exterior. The emitter pad EP may be referred to as an “emitter pad electrode,” an “emitter terminal electrode,” an “emitter external terminal,” or the like.

The emitter pad EP is arranged on portions of the interlayer film 57 covering the plurality of active regions 6. The emitter pad EP is electrically separated from the plurality of gate structures 20 and the plurality of gate connection structures 25 by the interlayer film 57.

The emitter pad EP is mechanically and electrically connected to the plurality of first emitter via electrodes 59 and the plurality of second emitter via electrodes 63 on the interlayer film 57, and is electrically connected to the plurality of emitter structures 30, the plurality of emitter connection structures 35, the plurality of emitter regions 40, and the plurality of contact regions 41 via the plurality of first emitter via electrodes 59 and the plurality of second emitter via electrodes 63.

The emitter pad EP includes a plurality of street removal portions 64. The plurality of street removal portions 64 each expose portions of the interlayer film 57 covering the plurality of street regions 9, and each extend in a band shape in the second direction Y in conformance to the extension direction of the corresponding street region 9.

The emitter pad EP may have a thickness larger than the thickness of the interlayer film 57. The thickness of the emitter pad EP may be 0.5 μm or more and 10 μm or less. The thickness of the emitter pad EP may have a value belonging to at least one of the ranges of 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less.

The emitter pad EP may have a laminated structure including the first electrode film 65 and the second electrode film 66 laminated in this order from the interlayer film 57 side. The first electrode film 65 covers the interlayer film 57 in a film shape as a barrier electrode. The first electrode film 65 is electrically connected to the plurality of first emitter via electrodes 59 and the plurality of second emitter via electrodes 63 on the interlayer film 57.

The first electrode film 65 is connected to the first electrodes 60 of the plurality of first emitter via electrodes 59 and the first electrodes 60 of the plurality of second emitter via electrodes 63. As a matter of course, the first electrode film 65 may cover the first electrodes 60 of the plurality of first emitter via electrodes 59 and the first electrodes 60 of the plurality of second emitter via electrodes 63.

The first electrode film 65 may have a single-layer structure including a titanium film or a titanium nitride film. The first electrode film 65 may have a laminated structure including a titanium film and a titanium nitride film. In this case, the titanium nitride film may be laminated on the titanium film.

The second electrode film 66 has a thickness larger than the thickness of the first electrode film 65, and covers the first electrode film 65 in a film shape. The second electrode film 66 covers the plurality of first emitter via electrodes 59 and the plurality of second emitter via electrodes 63 in a film shape.

The second electrode film 66 is electrically connected to the plurality of first emitter via electrodes 59 and the plurality of second emitter via electrodes 63. The second electrode 61 may include at least one of a pure aluminum film, a pure copper film, an AlCu alloy film, an AlSi alloy film, and an AlSiCu alloy film.

The semiconductor device 1A includes a monitor electrode 67 covering the monitor region 7 on the first main surface 3. The monitor electrode 67 is arranged on a portion of the interlayer film 57 covering the monitor region 7. The monitor electrode 67 is electrically separated from the plurality of gate structures 20 and the plurality of gate connection structures 25 by the interlayer film 57 in the monitor region 7. The monitor electrode 67 is mechanically and electrically connected to the plurality of first emitter via electrodes 59 and the plurality of second emitter via electrodes 63 on the interlayer film 57 in the monitor region 7.

The monitor electrode 67 is electrically connected to the plurality of emitter structures 30, the plurality of emitter connection structures 35, the plurality of emitter regions 40, and the plurality of contact regions 41 via the plurality of first emitter via electrodes 59 and the plurality of second emitter via electrodes 63. Similarly to the emitter pad EP, the monitor electrode 67 may have a laminated structure including the first electrode film 65 and the second electrode film 66 laminated in this order from the interlayer film 57 side.

The monitor electrode 67 may have a thickness larger than the thickness of the interlayer film 57. The thickness of the monitor electrode 67 may be substantially equal to the thickness of the emitter pad EP. The thickness range of the monitor electrode 67 is similar to the thickness range (0.5 μm or more and 10 μm or less) of the emitter pad EP.

The semiconductor device 1A includes a plurality of gate openings 68 formed in the interlayer film 57 in the outer peripheral region 8 and the plurality of street regions 9. The plurality of gate openings 68 penetrate the interlayer film 57 and selectively expose parts of the plurality of gate wirings 56.

The plurality of gate openings 68 may each extend in a band shape in conformance to the extension direction of the plurality of gate wirings 56. The plurality of gate openings 68 may be formed at an interval in conformance to the extension direction of the plurality of gate wirings 56. In this case, the plurality of gate openings 68 may be formed in a polygonal shape or a circular shape in plan view. The plurality of gate openings 68 may be formed in a quadrangular shape, a hexagonal shape, or the like in plan view.

In this embodiment, the plurality of gate openings 68 each have a bottom wall that is further dug down from the wiring surface of the corresponding gate wiring 56 toward the main surface insulating film 48 side and is located within the corresponding gate wiring 56. The plurality of gate openings 68 may be formed in a tapered shape toward the bottom wall. As a matter of course, the plurality of gate openings 68 may be formed substantially perpendicular to the first main surface 3.

The semiconductor device 1A includes a plurality of gate via electrodes 69 respectively embedded in the plurality of gate openings 68. The plurality of gate via electrodes 69 are respectively connected mechanically and electrically to the corresponding gate wirings 56 in the plurality of gate openings 68. Similarly to the first emitter via electrode 59, the plurality of gate via electrodes 69 may have a laminated structure including the first electrode 60 and the second electrode 61.

The semiconductor device 1A includes a plurality of gate fingers 70 arranged on the interlayer film 57. The gate finger 70 may be referred to as a “gate finger electrode,” a “finger electrode,” or the like. The plurality of gate fingers 70 are arranged on portions of the interlayer film 57 covering the plurality of gate wirings 56.

The plurality of gate fingers 70 are mechanically and electrically connected to the plurality of gate via electrodes 69 on the interlayer film 57, and are electrically connected to the plurality of gate wirings 56 via the plurality of gate via electrodes 69. The plurality of gate fingers 70 are electrically connected to the plurality of gate structures 20 in the plurality of active regions 6 and the plurality of gate structures 20 in the monitor region 7 via the plurality of gate wirings 56.

The plurality of gate fingers 70 include a plurality of first gate fingers 70A arranged in the outer peripheral region 8 and a plurality of second gate fingers 70B arranged in the plurality of street regions 9.

The plurality of first gate fingers 70A are respectively arranged on the plurality of first gate wirings 56A in the outer peripheral region 8. The plurality of first gate fingers 70A are routed in a band shape to regions between the gate pad region 11G and the corresponding gate connection structure 25 (gate connection embedded electrode 28) in conformance to the extension direction of the plurality of first gate wirings 56A.

The plurality of first gate fingers 70A are formed along the plurality of active regions 6, and each have a portion extending in the first direction X and a portion extending in the second direction Y. The plurality of first gate fingers 70A are mechanically and electrically connected to the plurality of gate via electrodes 69 on the interlayer film 57, and are electrically connected to the plurality of first gate wirings 56A via the plurality of gate via electrodes 69.

The plurality of second gate fingers 70B are respectively arranged on the plurality of second gate wirings 56B in the plurality of street regions 9. The plurality of second gate fingers 70B are routed in a band shape to regions between the gate pad region 11G and the corresponding gate connection structure 25 (gate connection embedded electrode 28) in conformance to the extension direction of the plurality of first gate wirings 56A.

The plurality of second gate fingers 70B each have a portion interposed in the plurality of street removal portions 64 of the emitter pad EP, and each extend in a band shape in the second direction Y in conformance to the extension direction of the corresponding street region 9. One second gate finger 70B is routed to the street region 9 to bypass the plurality of polysilicon layers 50 (temperature-sensitive diode structure D).

The plurality of second gate fingers 70B are mechanically and electrically connected to the plurality of gate via electrodes 69 on the interlayer film 57, and are electrically connected to the plurality of second gate wirings 56B via the plurality of gate via electrodes 69. Similarly to the emitter pad EP, the plurality of gate fingers 70 may have a laminated structure including the first electrode film 65 and the second electrode film 66 laminated in this order from the interlayer film 57 side.

The gate finger 70 may have a thickness larger than the thickness of the interlayer film 57. The thickness of the gate finger 70 may be substantially equal to the thickness of the emitter pad EP. The thickness range of the gate finger 70 is similar to the thickness range (0.5 μm or more and 10 μm or less) of the emitter pad EP.

With reference to FIGS. 12 and 13 again, the semiconductor device 1A includes a plurality of anode openings 71 respectively formed in portions of the interlayer film 57 covering the plurality of polysilicon layers 50 in the temperature detection region 10. The plurality of anode openings 71 penetrate the interlayer film 57, and each expose the corresponding anode regions 51. The plurality of anode openings 71 each extend in a band shape along the corresponding anode region 51 in plan view.

In this embodiment, the plurality of anode openings 71 are formed in an annular shape extending along the corresponding anode region 51 in plan view, and surround the corresponding cathode region 52. The plurality of anode openings 71 may be formed in a quadrangular annular shape, a hexagonal annular shape, a polygonal annular shape, an annular shape, or the like in plan view. As a matter of course, the plurality of anode openings 71 may be formed in an ended annular shape extending along the corresponding anode openings 71.

In the temperature detection region 10, the semiconductor device 1A includes a plurality of cathode openings 72 respectively formed in portions of the interlayer film 57 covering the plurality of polysilicon layers 50. The plurality of cathode openings 72 penetrate the interlayer film 57 at an interval of the plurality of anode openings 71, and each expose the corresponding cathode regions 52. The plurality of cathode openings 72 each extend in a band shape along the corresponding cathode region 52.

In this embodiment, the plurality of cathode openings 72 are formed in an ended annular shape extending along the corresponding cathode region 52 in plan view, and surround the corresponding anode region 51. The plurality of cathode openings 72 may be formed in an ended quadrangular annular shape, an ended hexagonal annular shape, an ended polygonal annular shape, an ended circular annular shape, or the like in plan view. As a matter of course, the plurality of cathode openings 72 may be formed in a quadrangular shape, a hexagonal shape, a polygonal shape, or a circular shape in plan view.

The semiconductor device 1A includes a plurality of anode via electrodes 73 respectively embedded in the plurality of anode openings 71. The plurality of anode via electrodes 73 are mechanically and electrically connected to the corresponding anode regions 51 within the corresponding anode openings 71. Similarly to the plurality of first emitter via electrodes 59, the plurality of anode via electrodes 73 may have a laminated structure including the first electrode 60 and the second electrode 61.

The semiconductor device 1A includes a plurality of cathode via electrodes 74 respectively embedded in the plurality of cathode openings 72. The plurality of cathode via electrodes 74 are mechanically and electrically connected to the corresponding cathode regions 52 within the corresponding cathode openings 72. Similarly to the plurality of first emitter via electrodes 59, the plurality of cathode via electrodes 74 may have a laminated structure including the first electrode 60 and the second electrode 61.

The semiconductor device 1A includes an anode wiring 75 arranged on the interlayer film 57. The anode wiring 75 is routed from the temperature detection region 10 to the anode pad region 11A through the street region 9. The anode wiring 75 has a portion extending in a band shape in the second direction Y in conformance to the extension direction of the street region 9 in the street region 9, and a portion extending in a band shape in an optional direction (first direction X) toward the anode pad region 11A outside the street region 9.

The anode wiring 75 has a portion extending parallel to the gate finger 70 in the street region 9. Similarly to the emitter pad EP, the anode wiring 75 may have a laminated structure including the first electrode film 65 and the second electrode film 66 laminated in this order from the interlayer film 57 side.

The anode wiring 75 may have a thickness larger than the thickness of the interlayer film 57. The thickness of the anode wiring 75 may be substantially equal to the thickness of the emitter pad EP. The thickness range of the anode wiring 75 is similar to the thickness range (0.5 μm or more and 10 μm or less) of the emitter pad EP.

The semiconductor device 1A includes a cathode wiring 76 arranged on the interlayer film 57. The cathode wiring 76 is routed from the temperature detection region 10 to the cathode pad region 11C through the street region 9. The cathode wiring 76 has a portion extending in a band shape in the second direction Y in conformance to the extension direction of the street region 9 in the street region 9, and a portion extending in a band shape in an optional direction (first direction X) toward the cathode pad region 11C outside the street region 9.

The cathode wiring 76 has a portion extending in parallel to both the gate finger 70 and the anode wiring 75 in the street region 9. Similarly to the emitter pad EP, the cathode wiring 76 may have a laminated structure including the first electrode film 65 and the second electrode film 66 laminated in this order from the interlayer film 57 side.

The cathode wiring 76 may have a thickness larger than the thickness of the interlayer film 57. The thickness of the cathode wiring 76 may be substantially equal to the thickness of the emitter pad EP. The thickness range of the cathode wiring 76 is similar to the thickness range (0.5 μm or more and 10 μm or less) of the emitter pad EP.

The semiconductor device 1A includes a plurality of anode connection wirings 77 respectively formed in portions of the interlayer film 57 covering the plurality of polysilicon layers 50. The plurality of anode connection wirings 77 have portions extending along the corresponding anode via electrodes 73 on the interlayer film 57, and are respectively connected mechanically and electrically to the corresponding anode via electrodes 73.

The plurality of anode connection wirings 77 may be formed in a polygonal shape, a circular shape, or the like in plan view. The plurality of anode connection wirings 77 may be formed in a quadrangular shape, a hexagonal shape, or the like in plan view. Similarly to the emitter pad EP, the plurality of anode connection wirings 77 may have a laminated structure including the first electrode film 65 and the second electrode film 66 laminated in this order from the interlayer film 57 side.

The anode connection wiring 77 may have a thickness larger than the thickness of the interlayer film 57. The thickness of the anode connection wiring 77 may be substantially equal to the thickness of the emitter pad EP. The thickness range of the anode connection wiring 77 is similar to the thickness range (0.5 μm or more and 10 μm or less) of the emitter pad EP.

The semiconductor device 1A includes a plurality of cathode connection wirings 78 respectively formed in portions of the interlayer film 57 covering the plurality of polysilicon layers 50. The plurality of cathode connection wirings 78 have portions extending in a band shape along the corresponding cathode via electrodes 74 on the interlayer film 57, and are respectively connected mechanically and electrically to the corresponding cathode via electrodes 74. Similarly to the emitter pad EP, the plurality of cathode connection wirings 78 may have a laminated structure including the first electrode 60 and the second electrode 61 laminated in this order from the interlayer film 57 side.

The cathode connection wiring 78 may have a thickness larger than the thickness of the interlayer film 57. The thickness of the cathode connection wiring 78 may be substantially equal to the thickness of the emitter pad EP. The thickness range of the cathode connection wiring 78 is similar to the thickness range of the emitter pad EP (0.5 μm or more and 10 μm or less).

The semiconductor device 1A includes a plurality of connection wirings 79 respectively formed in portions of the interlayer film 57 covering the plurality of polysilicon layers 50. The plurality of connection wirings 79 are respectively interposed in regions between the plurality of polysilicon layers 50 adjacent to each other in the second direction Y on the interlayer film 57, and each connect the corresponding anode wiring 75 electrically to the corresponding cathode wiring 76. The plurality of connection wirings 79 each extend in a band shape in the second direction Y in plan view.

One connection wiring 79 located on the outermost side on one side in the second direction Y electrically connects the outermost anode connection wiring 77 to the anode wiring 75. The other connection wiring 79 located on the outermost side on one side in the second direction Y electrically connects the outermost cathode connection wiring 78 to the anode wiring 75. As a result, the first series circuit SC1 including the plurality of first diodes D1 is configured.

One connection wiring 79 located on the outermost side on the other side in the second direction Y electrically connects the outermost cathode connection wiring 78 to the cathode wiring 76. The other connection wiring 79 located on the outermost side on the other side in the second direction Y electrically connects the outermost anode connection wiring 77 to the cathode wiring 76. As a result, the second series circuit SC2 including the plurality of second diodes D2 is configured.

The connection wiring 79 may have a thickness larger than the thickness of the interlayer film 57. The thickness of the connection wiring 79 may be substantially equal to the thickness of the emitter pad EP. The thickness range of the connection wiring 79 is similar to the thickness range of the emitter pad EP (0.5 μm or more and 10 μm or less).

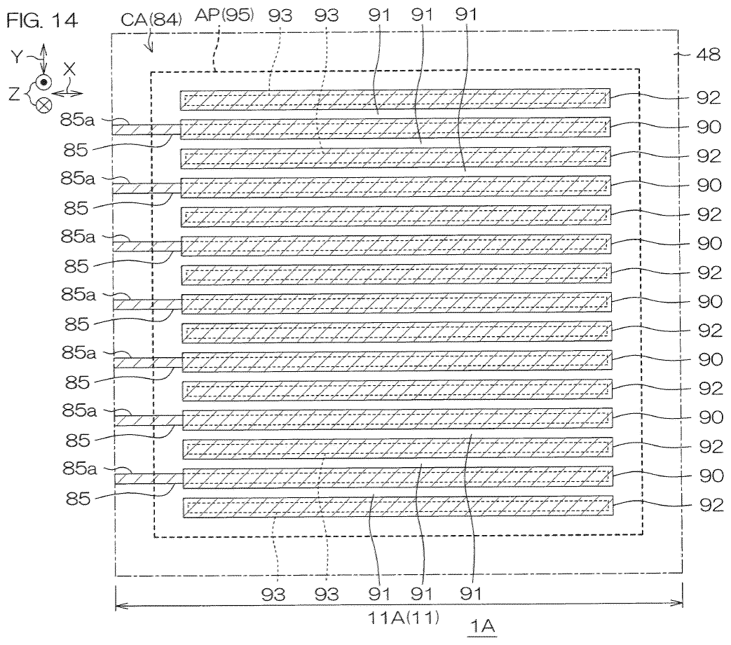

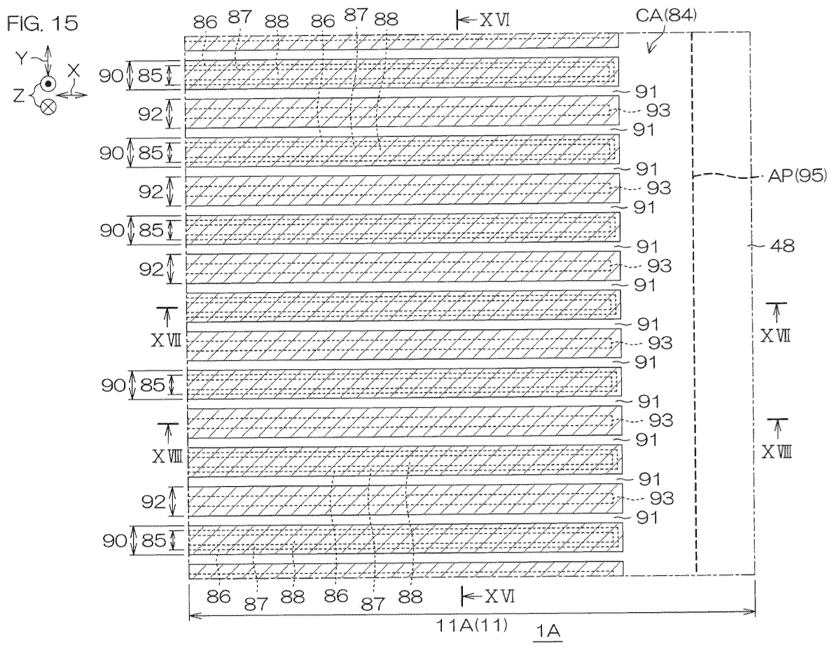

Hereinafter, the configuration in the plurality of pad regions 11 will be described. FIG. 14 is an enlarged plan view showing a configuration in the pad region 11 together with a pad capacitor structure 84 according to the first layout example and a pad opening 93 according to the first layout example. FIG. 15 is an enlarged plan view showing a main portion of the pad region 11.

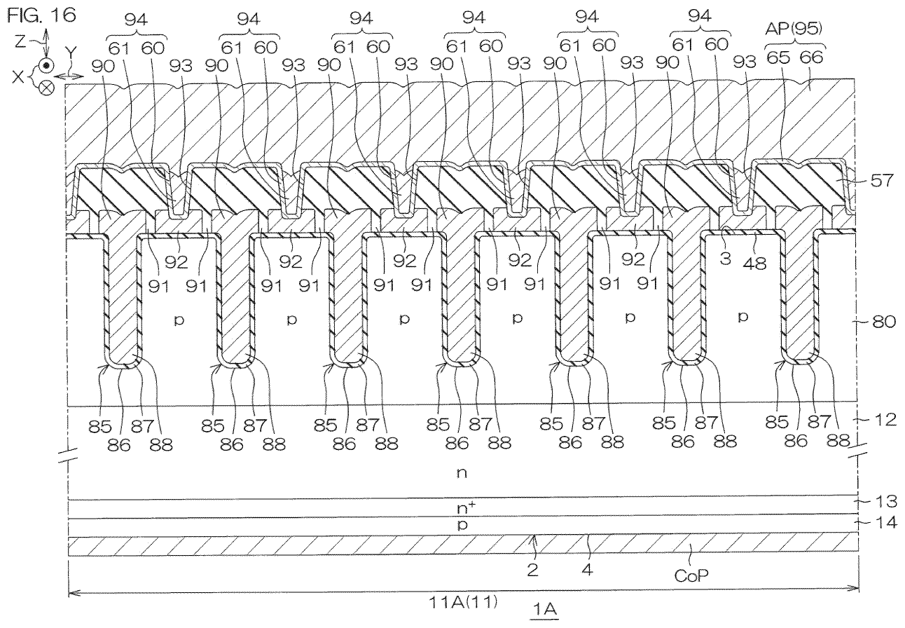

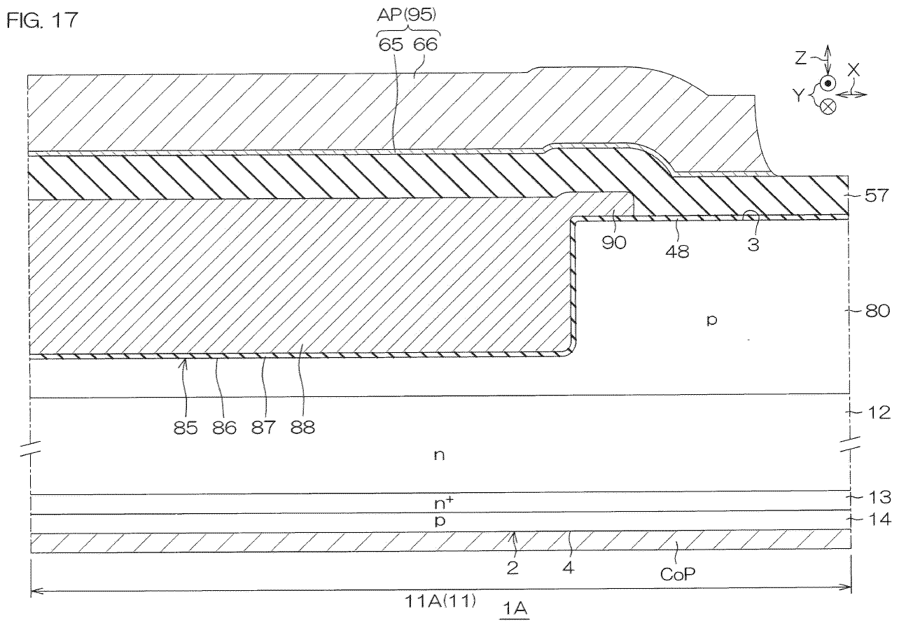

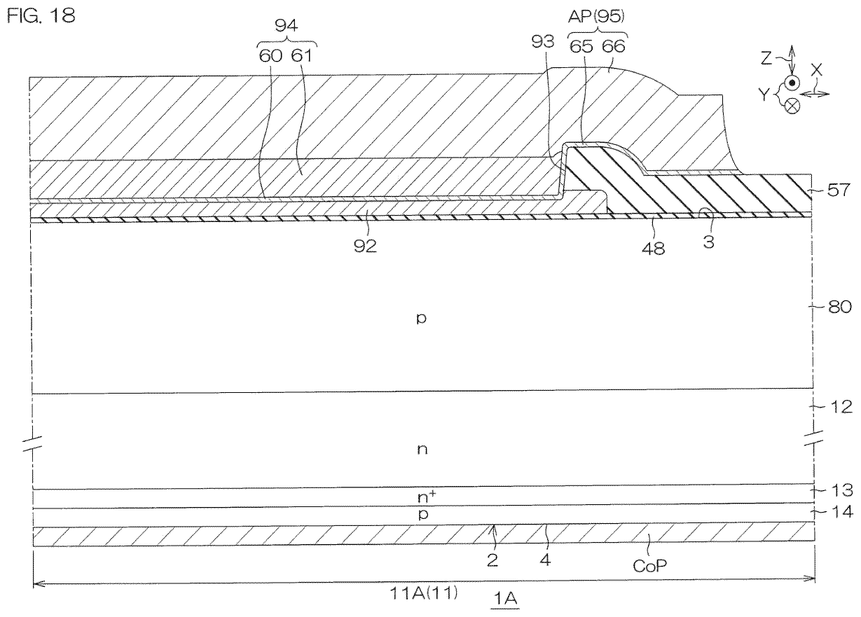

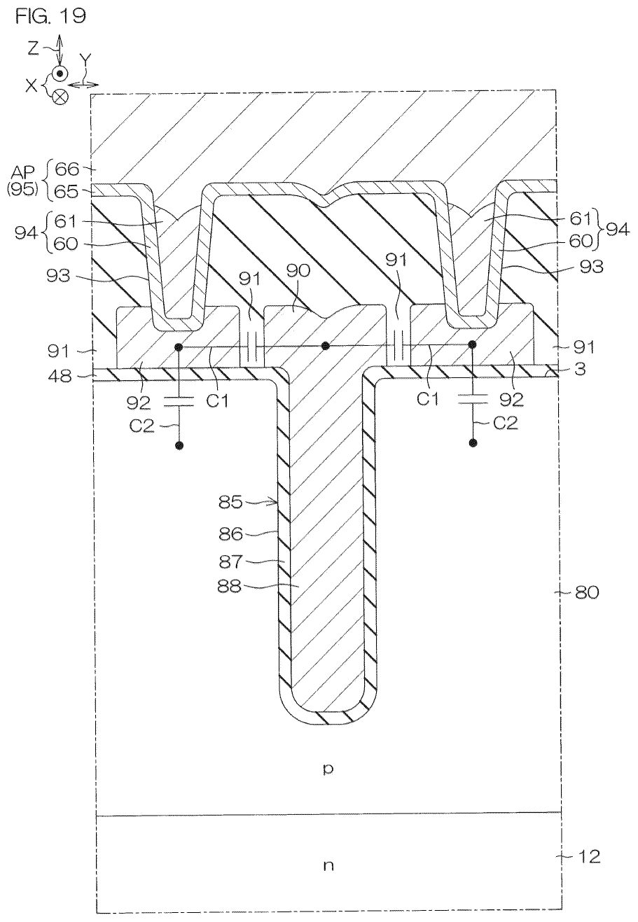

FIG. 16 is a cross-sectional view taken along line XVI-XVI shown in FIG. 15. FIG. 17 is a cross-sectional view taken along line XVII-XVII shown in FIG. 15. FIG. 18 is a cross-sectional view taken along line XVIII-XVIII shown in FIG. 15. FIG. 19 is an enlarged plan view showing a main portion shown in FIG. 16.

The semiconductor device 1A includes a plurality of p-type pad well regions 80 respectively formed in the surface layer portion of the first main surface 3 in the plurality of pad regions 11. The pad well region 80 has a p-type impurity concentration higher than the n-type impurity concentration of the drift region 12, and replaces the conductivity type of the drift region 12 from n-type to p-type.

The pad well region 80 may have a p-type impurity concentration higher than the p-type impurity concentration of the base region 15. As a matter of course, the p-type impurity concentration of the pad well region 80 may be lower than the p-type impurity concentration of the base region 15. The p-type impurity concentration of the pad well region 80 is lower than the p-type impurity concentration of the contact region 41.

The p-type impurity concentration of the pad well region 80 may be substantially equal to the p-type impurity concentration of the outer peripheral well region 44. As a matter of course, the p-type impurity concentration of the pad well region 80 may be higher than the p-type impurity concentration of the outer peripheral well region 44, or may be lower than the p-type impurity concentration of the outer peripheral well region 44.

The p-type impurity concentration of the pad well region 80 may be substantially equal to the p-type impurity concentration of the street well region 45. As a matter of course, the p-type impurity concentration of the pad well region 80 may be higher than the p-type impurity concentration of the street well region 45, or may be lower than the p-type impurity concentration of the street well region 45.

An emitter potential is to be applied to the plurality of pad well regions 80. The plurality of pad well regions 80 are formed over the entire region of the corresponding pad region 11. In this embodiment, the plurality of pad well regions 80 are connected to the outer peripheral well region 44 and the plurality of street well regions 45, and are integrally formed with the plurality of street well regions 45 and the outer peripheral well region 44.

That is, the plurality of pad well regions 80 are electrically connected to the plurality of base regions 15 via the plurality of street well regions 45 and the outer peripheral well region 44. In this embodiment, the plurality of pad well regions 80 have a width larger than the width of the plurality of street well regions 45 in the first direction X.

The plurality of pad well regions 80 are formed deeper than the plurality of base regions 15. Specifically, the plurality of pad well regions 80 are formed deeper than the plurality of gate structures 20, the plurality of gate connection structures 25, the plurality of emitter structures 30, and the plurality of emitter connection structures 35.

The plurality of pad well regions 80 may have a depth substantially equal to the depths of the plurality of well regions 43. As a matter of course, the depths of the plurality of pad well regions 80 may be larger than the depths of the plurality of well regions 43, or may be smaller than the depths of the plurality of well regions 43.

The depths of the plurality of pad well regions 80 may be substantially equal to the depth of the outer peripheral well region 44. As a matter of course, the depths of the plurality of pad well regions 80 may be larger than the depth of the outer peripheral well region 44, or may be smaller than the depth of the outer peripheral well region 44.

The depths of the plurality of pad well regions 80 may be substantially equal to the depths of the plurality of street well regions 45. As a matter of course, the depths of the plurality of pad well regions 80 may be larger than the depths of the plurality of street well regions 45, or may be smaller than the depths of the plurality of street well regions 45.

The semiconductor device 1A includes a plurality of pad capacitor structures 84 respectively formed in a plurality of pad regions 11 (also refer to FIG. 3). In this embodiment, the plurality of pad capacitor structures 84 include the monitor capacitor structure CM formed in the monitor pad region 11M, the anode capacitor structure CA formed in the anode pad region 11A, and the cathode capacitor structure CC formed in the cathode pad region 11C. Hereinafter, the configuration of the anode capacitor structure CA will be mainly described as an example of the pad capacitor structure 84.

The configuration of the monitor capacitor structure CM is obtained by replacing “anode capacitor structure CA” with “monitor capacitor structure CM” and replacing “anode pad region 11A” with “monitor pad region 11M” in the following description.

The configuration of the cathode capacitor structure CC is obtained by replacing “anode capacitor structure CA” with “cathode capacitor structure CC” and replacing “anode pad region 11A” with “cathode pad region 11C” in the following description.

The anode capacitor structure CA includes a plurality of trench electrode type capacitor structures 85 formed in the first main surface 3. The emitter potential of the transistor structure T3 is to be applied to the plurality of capacitor structures 85. That is, the same potential as the potential applied to the pad well region 80 is to be applied to the plurality of capacitor structures 85.

The plurality of capacitor structures 85 do not form a voltage drop caused by a potential applied from the outside with respect to the pad well region 80 except for a voltage drop caused by an electric field distribution formed in the chip 2. The plurality of capacitor structures 85 are electrically disconnected from the monitor potential of the monitor transistor structure T2.

The number of capacitor structures 85 is less than the number of gate structures 20. The total area (total extension) of the plurality of capacitor structures 85 is less than the total area (total extension) of the plurality of gate structures 20. The number of capacitor structures 85 is less than the number of emitter structures 30. The total area (total extension) of the plurality of capacitor structures 85 is less than the total area (total extension) of the plurality of emitter structures 30.

The plurality of capacitor structures 85 each extend in a band shape in the first direction X in the anode pad region 11A, and are arranged at an interval in the second direction Y. That is, the plurality of capacitor structures 85 are arranged in a stripe shape extending in the first direction X. The extension direction of the plurality of capacitor structures 85 coincides with the extension direction of the plurality of gate structures 20. The extension direction of the plurality of capacitor structures 85 coincides with the extension direction of the plurality of emitter structures 30.

The plurality of capacitor structures 85 may each have a width less than the widths of the plurality of street regions 9. The width of the capacitor structure 85 is a width in a direction (second direction Y) orthogonal to the extension direction (first direction X) of the capacitor structure 85.

The width of the capacitor structure 85 may be substantially equal to the width of the gate structure 20. As a matter of course, the width of the capacitor structure 85 may be larger than the width of the gate structure 20, or may be smaller than the width of the gate structure 20. The width of the capacitor structure 85 may be substantially equal to the width of the gate connection structure 25. As a matter of course, the width of the capacitor structure 85 may be larger than the width of the gate connection structure 25, or may be smaller than the width of the gate connection structure 25.

The width of the capacitor structure 85 may be substantially equal to the width of the emitter structure 30. As a matter of course, the width of the emitter structure 30 may be larger than the width of the emitter structure 30, or may be smaller than the width of the emitter structure 30. The width of the capacitor structure 85 may be substantially equal to the width of the emitter connection structure 35. As a matter of course, the width of the capacitor structure 85 may be larger than the width of the emitter connection structure 35, or may be smaller than the width of the emitter connection structure 35.

The width of the capacitor structure 85 may be 0.5 μm or more and 5 μm or less. The width of the capacitor structure 85 may have a value belonging to at least one of the ranges of 0.5 μm or more and 1 μm or less, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less. The width of the capacitor structure 85 is preferably 1 μm or more and 2.5 μm or less.

A second trench pitch between the central portions of the plurality of capacitor structures 85 may be substantially equal to the first trench pitch between the central portion of the gate structure 20 and the central portion of the emitter structure 30. As a matter of course, the second trench pitch may be larger than the first trench pitch, or may be smaller than the first trench pitch.

The second trench pitch may be 1 μm or more and 5 μm or less. The second trench pitch may have a value belonging to at least one of the ranges of 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less. The second trench pitch is preferably 1.5 μm or more and 3.5 μm or less.

The plurality of capacitor structures 85 are respectively formed at an interval on the first main surface 3 side from the depth position of the intermediate portion of the drift region 12. Specifically, the plurality of capacitor structures 85 are formed in the first main surface 3 to be located within the pad well region 80.

More specifically, the plurality of capacitor structures 85 are formed at an interval on the first main surface 3 side from the bottom portion of the pad well region 80, and oppose the drift region 12 with a part of the pad well region 80 interposed therebetween in the thickness direction. That is, the plurality of capacitor structures 85 are connected to the pad well region 80 over the entire region in the depth direction.

The plurality of capacitor structures 85 may each have a bottom wall located on the bottom portion side of the pad well region 80 with respect to the depth position of the intermediate portion of the pad well region 80. As a matter of course, the bottom walls of the plurality of capacitor structures 85 may be located on the first main surface 3 side with respect to the depth position of the intermediate portion of the pad well region 80. As a matter of course, the plurality of capacitor structures 85 may penetrate the pad well region 80 to reach the drift region 12.

The plurality of capacitor structures 85 may be formed in a tapered shape toward the bottom wall. As a matter of course, the plurality of capacitor structures 85 may be formed substantially perpendicular to the first main surface 3.

The bottom walls of the plurality of capacitor structures 85 may be formed in a curved shape toward the second main surface 4. As a matter of course, the bottom walls of the plurality of capacitor structures 85 may be formed substantially parallel to the first main surface 3. In this case, the bottom wall corner portions of the plurality of capacitor structures 85 may be formed in a curved shape.

The plurality of capacitor structures 85 may have a depth substantially equal to the depths of the plurality of gate structures 20. As a matter of course, the depth of the capacitor structure 85 may be larger than the depth of the gate structure 20, or may be smaller than the depth of the gate structure 20.

The depth of the capacitor structure 85 may be substantially equal to the depth of the gate connection structure 25. As a matter of course, the depth of the capacitor structure 85 may be larger than the depth of the gate connection structure 25, or may be smaller than the depth of the gate connection structure 25.

The depth of the capacitor structure 85 may be substantially equal to the depth of the emitter structure 30. As a matter of course, the depth of the capacitor structure 85 may be larger than the depth of the emitter structure 30, or may be smaller than the depth of the emitter structure 30.

The depth of the capacitor structure 85 may be substantially equal to the depth of the emitter connection structure 35. As a matter of course, the depth of the capacitor structure 85 may be larger than the depth of the emitter connection structure 35, or may be smaller than the depth of the emitter connection structure 35.

The depth of the capacitor structure 85 may be 0.5 μm or more and 10 μm or less. The depth of the capacitor structure 85 may have a value belonging to at least one of the ranges of 0.5 μm or more and 1 μm or less, 1 μm or more and 2 μm or less, 2 μm or more and 4 μm or less, 4 μm or more and 6 μm or less, 6 μm or more and 8 μm or less, and 8 μm or more and 10 μm or less. The depth of the capacitor structure 85 is preferably 4 μm or more and 8 μm or less.

The plurality of capacitor structures 85 each have a lead-out portion 85a led out from the anode pad region 11A to the active region 6 (in this embodiment, the first active region 6A), and respectively connected electrically to the plurality of emitter structures 30 in the active region 6.

For example, the plurality of lead-out portions 85a may be led out to the active region 6 through an open portion of the gate connection structure 25 in which the gate connection structure 25 does not exist, and respectively connected to the plurality of emitter structures 30 in the active region 6. As a result, the emitter potential is to be applied to the plurality of capacitor structures 85 via the plurality of emitter structures 30.

The plurality of lead-out portions 85a (capacitor structures 85) may be respectively connected mechanically to the plurality of emitter structures 30 in the active region 6. The plurality of lead-out portions 85a (capacitor structures 85) may be respectively connected to the plurality of emitter connection structures 35 in the active region 6. In this case, the plurality of capacitor structures 85 are mechanically and electrically connected to the plurality of emitter structures 30 via the plurality of emitter connection structures 35.

The plurality of capacitor structures 85 (lead-out portions 85a) may be led out from the plurality of emitter structures 30 to the anode pad region 11A in a one-to-one correspondence. In this case, the plurality of capacitor structures 85 may be led out at the same trench pitch (third trench pitch) as the trench pitches of the plurality of emitter structures 30.

The plurality of capacitor structures 85 (lead-out portions 85a) do not necessarily need to be led out from the plurality of emitter structures 30 to the anode pad region 11A in a one-to-one correspondence. Therefore, one or a plurality of capacitor structures 85 (lead-out portions 85a) may be led out from the corresponding one emitter structure 30 to the anode pad region 11A. As a matter of course, one capacitor structure 85 (lead-out portion 85a) may be led out from the plurality of emitter structures 30 to the anode pad region 11A.

One or a plurality of lead-out portions 85a (capacitor structure 85) may have both a portion extending in the first direction X and a portion extending in the second direction Y in the active region 6 and/or the anode pad region 11A, and may be configured such that a trench pitch (third trench pitch) in the anode pad region 11A is adjusted.

As a matter of course, the one or a plurality of capacitor structures 85 may have one or a plurality of lead-out portions 85a extending in the second direction Y and be connected to the one or a plurality of emitter structures 30 of the active regions 6 (for example, the first active region 6A or the second active region 6B) adjacent to each other in the second direction Y.

The plurality of capacitor structures 85 each include a capacitor trench 86, a capacitor insulating film 87, and a capacitor embedded electrode 88. The capacitor trench 86 is formed in the first main surface 3 and defines a wall surface (side wall and bottom wall) of the capacitor structure 85.

The capacitor trench 86 communicates with the emitter trench 31 of the corresponding one or a plurality of emitter structures 30. When the capacitor structure 85 is connected to the emitter connection structure 35, the capacitor trench 86 may communicate with the emitter connection trench 36. That is, the capacitor trench 86 may communicate with the emitter trench 31 through the emitter connection trench 36.

The capacitor insulating film 87 may include at least one of a silicon oxide film, a silicon nitride film, and a silicon oxynitride film. The capacitor insulating film 87 preferably includes the same type of insulator as the gate insulating film 22 (emitter insulating film 32). In this embodiment, the capacitor insulating film 87 has a single-layer structure formed of a silicon oxide film. The capacitor insulating film 87 particularly preferably includes a silicon oxide film formed of the oxide of the chip 2.

The capacitor insulating film 87 covers the wall surface of the capacitor trench 86. The capacitor insulating film 87 is connected to the emitter insulating film 32 at a communication portion between the emitter trench 31 and the capacitor trench 86.

When the capacitor structure 85 is connected to the emitter connection structure 35, the capacitor insulating film 87 may be connected to the emitter connection insulating film 37 at a communication portion between the emitter trench 31 and the capacitor trench 86. That is, the capacitor insulating film 87 may be connected to the emitter insulating film 32 through the emitter connection insulating film 37.

The thickness of the capacitor insulating film 87 may be substantially equal to the thickness of the gate insulating film 22. As a matter of course, the thickness of the capacitor insulating film 87 may be larger than the thickness of the gate insulating film 22, or may be smaller than the thickness of the gate insulating film 22.

The thickness of the capacitor insulating film 87 may be substantially equal to the thickness of the gate connection insulating film 27. As a matter of course, the thickness of the capacitor insulating film 87 may be larger than the thickness of the gate connection insulating film 27, or may be smaller than the thickness of the gate connection insulating film 27.

The thickness of the capacitor insulating film 87 may be substantially equal to the thickness of the emitter insulating film 32. As a matter of course, the thickness of the capacitor insulating film 87 may be larger than the thickness of the emitter insulating film 32, or may be smaller than the thickness of the emitter insulating film 32.

The thickness of the capacitor insulating film 87 may be substantially equal to the thickness of the emitter connection insulating film 37. As a matter of course, the thickness of the capacitor insulating film 87 may be larger than the thickness of the emitter connection insulating film 37, or may be smaller than the thickness of the emitter connection insulating film 37.

The thickness of the capacitor insulating film 87 may be 10 nm or more and 200 nm or less. The thickness of the capacitor insulating film 87 may have a value belonging to at least one of the ranges of 10 nm or more and 25 nm or less, 25 nm or more and 50 nm or less, 50 nm or more and 75 nm or less, 75 nm or more and 100 nm or less, 100 nm or more and 125 nm or less, 125 nm or more and 150 nm or less, 150 nm or more and 175 nm or less, and 175 nm or more and 200 nm or less. The thickness of the capacitor insulating film 87 is preferably 100 nm or more and 150 nm or less.

The capacitor embedded electrode 88 is embedded in the capacitor trench 86 with the capacitor insulating film 87 interposed therebetween. The capacitor embedded electrode 88 opposes the pad well region 80 with the capacitor insulating film 87 interposed therebetween. Specifically, the capacitor embedded electrode 88 opposes the pad well region 80 on the side wall and the bottom wall of the capacitor trench 86.

When the capacitor trench 86 penetrates the pad well region 80, the capacitor embedded electrode 88 may have a portion opposing the pad well region 80 via the capacitor insulating film 87 and a portion opposing the drift region 12 via the capacitor insulating film 87.

The capacitor embedded electrode 88 is connected to the emitter embedded electrode 33 at a communication portion between the emitter trench 31 and the capacitor trench 86. When the capacitor structure 85 is connected to the emitter connection structure 35, the capacitor embedded electrode 88 may be connected to the emitter connection embedded electrode 38 at a communication portion between the emitter trench 31 and the capacitor trench 86. That is, the capacitor insulating film 87 may be connected to the emitter embedded electrode 33 through the emitter connection embedded electrode 38.

The capacitor embedded electrode 88 may contain one or both of the p-type conductive polysilicon and the n-type conductive polysilicon. The capacitor embedded electrode 88 preferably contains the same type of conductor as the gate embedded electrode 23 (emitter embedded electrode 33).

The anode capacitor structure CA includes the above-described main surface insulating film 48 that covers the first main surface 3 of the anode pad region 11A. The main surface insulating film 48 is formed as a main surface dielectric film (first dielectric film) in the anode pad region 11A.

In the anode capacitor structure CA, the main surface insulating film 48 covers the pad well region 80 on the first main surface 3. The main surface insulating film 48 is connected to the capacitor insulating film 87 in the anode pad region 11A. The thickness of the main surface insulating film 48 may be substantially equal to the thickness of the capacitor insulating film 87. As a matter of course, the thickness of the main surface insulating film 48 may be larger or smaller than the thickness of the capacitor insulating film 87.

The anode capacitor structure CA includes a plurality of first capacitor electrode films 90 arranged on the first main surface 3 in the anode pad region 11A. The first capacitor electrode film 90 may also be referred to as a “first electrode.” The plurality of first capacitor electrode films 90 cover the plurality of capacitor structures 85, respectively, and are electrically connected to the plurality of capacitor structures 85, respectively.

That is, an emitter potential is to be applied to the plurality of first capacitor electrode films 90. Also, the same potential as the potential applied to the pad well region 80 is to be applied to the plurality of first capacitor electrode films 90. The plurality of first capacitor electrode films 90 do not form a voltage drop with the pad well region 80 due to the potential applied from outside, except for a voltage drop due to the electric field distribution formed in the chip 2.

In this embodiment, the plurality of first capacitor electrode films 90 cover the plurality of capacitor structures 85 in one-to-one correspondence. The plurality of first capacitor electrode films 90 extend in a band shape in the first direction X in conformance to the extension direction of the corresponding capacitor structures 85 in the anode pad region 11A, respectively.

Each of the plurality of first capacitor electrode films 90 may cover the entire region of a portion of the corresponding capacitor structure 85 positioned in the anode pad region 11A (a portion other than the lead-out portion 85a). As a matter of course, each of the plurality of first capacitor electrode films 90 may partially cover the portion of the corresponding capacitor structure 85 positioned in the anode pad region 11A.

Each of the plurality of first capacitor electrode films 90 may have a portion covering the lead-out portion 85a of the corresponding capacitor structure 85. Each of the plurality of first capacitor electrode films 90 may cover the entire region of the corresponding lead-out portion 85a. In this case, the plurality of first capacitor electrode films 90 may be connected to one or a plurality of emitter wirings 55 via the corresponding lead-out portions 85a.

The plurality of first capacitor electrode films 90 may have a width larger than the width of the plurality of capacitor structures 85. The width of the first capacitor electrode film 90 is a width in a direction orthogonal to the extension direction of the first capacitor electrode film 90.

As a matter of course, the first capacitor electrode film 90 may have a smaller width than the capacitor structure 85. In this embodiment, each of the plurality of first capacitor electrode films 90 is formed to be wider than the corresponding capacitor structure 85, and has a portion positioned in a region outside the corresponding capacitor structure 85.

Specifically, each of the plurality of first capacitor electrode films 90 has a portion covering the capacitor embedded electrode 88 of the corresponding capacitor structure 85 and a portion covering the main surface insulating film 48. The plurality of first capacitor electrode films 90 face the first main surface 3 with the main surface insulating film 48 interposed therebetween.

Specifically, the first capacitor electrode film 90 faces the pad well region 80 with the main surface insulating film 48 interposed therebetween. As a matter of course, each of the plurality of first capacitor electrode films 90 may be formed only on the corresponding capacitor embedded electrode 88, and may face only the capacitor embedded electrode 88 in the thickness direction.

The first capacitor electrode film 90 may have a side wall extending substantially perpendicular to the first main surface 3. As a matter of course, the side wall of the first capacitor electrode film 90 may be inclined obliquely downward from the main electrode surface toward the chip 2 (first main surface 3) side.

The first capacitor electrode film 90 may be formed of a conductor film other than metal. In this embodiment, the first capacitor electrode film 90 is formed of the same type of conductor as the capacitor embedded electrode 88 (either or both of p-type conductive polysilicon and n-type conductive polysilicon).

In this embodiment, the plurality of first capacitor electrode films 90 are formed integrally with the corresponding capacitor embedded electrodes 88 as projecting portions projecting above the height position of the first main surface 3 from the corresponding capacitor embedded electrodes 88, respectively. Each of the plurality of first capacitor electrode films 90 may have a recess recessed toward the bottom wall of the corresponding capacitor structure 85 in a portion covering the corresponding capacitor structure 85.

As a matter of course, the first capacitor electrode film 90 may be formed of a metal film. In this case, the first capacitor electrode films 90 may be mechanically and electrically connected to the plurality of capacitor structures 85 (capacitor embedded electrodes 88) on the main surface insulating film 48.

The first capacitor electrode film 90 has a thickness larger than the thickness of the main surface insulating film 48. The thickness of the first capacitor electrode film 90 is the thickness (projection amount) of the first capacitor electrode film 90 with the insulating surface of the main surface insulating film 48 as a reference. The thickness of the first capacitor electrode film 90 is preferably smaller than the depth (thickness) of the pad well region 80. The thickness of the first capacitor electrode film 90 is preferably smaller than the depth of the capacitor structure 85.

The thickness of the first capacitor electrode film 90 is preferably smaller than the depth of the gate structure 20 (emitter structure 30). The thickness of the first capacitor electrode film 90 is preferably smaller than the depth of the gate connection structure 25 (emitter connection structure 35).

The thickness of the first capacitor electrode film 90 may be substantially equal to the thickness of the polysilicon layer 50. As a matter of course, the thickness of the first capacitor electrode film 90 may be larger or smaller than the thickness of the polysilicon layer 50.

The thickness of the first capacitor electrode film 90 may be substantially equal to the thickness of the emitter wiring 55. As a matter of course, the thickness of the first capacitor electrode film 90 may be larger or smaller than the thickness of the emitter wiring 55.

The thickness of the first capacitor electrode film 90 may be substantially equal to the thickness of the gate wiring 56. As a matter of course, the thickness of the first capacitor electrode film 90 may be larger or smaller than the thickness of the gate wiring 56.

The thickness of the first capacitor electrode film 90 may be 0.1 μm or more and 2 μm or less. The thickness of the first capacitor electrode film 90 may have a value belonging to at least one of the following ranges, 0.1 μm or more and 0.25 μm or less, 0.25 μm or more and 0.5 μm or less, 0.5 μm or more and 0.75 μm or less, 0.75 μm or more and 1 μm or less, 1.25 μm or more and 1.5 μm or less, 1.5 μm or more and 1.75 μm or less, and 1.75 μm or more and 2 μm or less. The thickness of the first capacitor electrode film 90 is preferably 0.25 μm or more and 1.25 μm or less.

The anode capacitor structure CA includes a plurality of side wall dielectric films 91 that respectively cover the side walls of the plurality of first capacitor electrode films 90 in the anode pad region 11A. The side wall dielectric film 91 may also be referred to as a “side wall insulating film,” “second dielectric film,” or the like.

The plurality of side wall dielectric films 91 cover the side walls of the corresponding first capacitor electrode films 90 in a film shape. The plurality of side wall dielectric films 91 cover the entire periphery of the side walls of the corresponding first capacitor electrode films 90, and surround the corresponding first capacitor electrode films 90.

The plurality of side wall dielectric films 91 extend in a film shape in the vertical direction Z (inclination direction) in conformance to the extension direction (inclination angle) of the side wall of the corresponding first capacitor electrode film 90. The plurality of side wall dielectric films 91 are connected to the main surface insulating film 48 in portions covering the side walls of the corresponding first capacitor electrode films 90. The plurality of side wall dielectric films 91 face the pad well region 80 with the main surface insulating film 48 interposed therebetween.

The plurality of side wall dielectric films 91 may include at least one of a silicon oxide film, a silicon nitride film, and a silicon oxynitride film. The plurality of side wall dielectric films 91 each may be formed of the same type of insulator as the insulator of the gate insulating film 22 (emitter insulating film 32), or may be formed of an insulator different from the insulator of the gate insulating film 22 (emitter insulating film 32).

The plurality of side wall dielectric films 91 each may be formed of the same type of insulator as the insulator of the main surface insulating film 48, or may be formed of an insulator different from the insulator of the main surface insulating film 48. In this embodiment, the plurality of side wall dielectric films 91 have a single layer structure formed of the same type of insulator (silicon oxide film) as the insulator of the main surface insulating film 48 (gate insulating film 22), and have a denseness different from the denseness of the insulator of the main surface insulating film 48 (gate insulating film 22).

The plurality of side wall dielectric films 91 have a thickness smaller than the thickness of the first capacitor electrode film 90. The thickness of the side wall dielectric film 91 may be larger than the thickness of the gate insulating film 22 (emitter insulating film 32). As a matter of course, the thickness of the side wall dielectric film 91 may be smaller than the thickness of the gate insulating film 22 (emitter insulating film 32). The thickness of the side wall dielectric film 91 may be larger than the thickness of the main surface insulating film 48. As a matter of course, the thickness of the side wall dielectric film 91 may be smaller than the thickness of the main surface insulating film 48.

The thickness of the side wall dielectric film 91 may be 10 nm or more and 500 nm or less. The thickness of the side wall dielectric film 91 may have a value belonging to at least one of the following ranges, 10 nm or more and 25 nm or less, 25 nm or more and 50 nm or less, 50 nm or more and 75 nm or less, 75 nm or more and 100 nm or less, 100 nm or more and 125 nm or less, 125 nm or more and 150 nm or less, 150 nm or more and 175 nm or less, 175 nm or more and 200 nm or less, 200 nm or more and 225 nm or less, 225 nm or more and 250 nm or less, 250 nm or more and 275 nm or less, 275 nm or more and 300 nm or less, 300 nm or more and 325 nm or less, 325 nm or more and 350 nm or less, 350 nm or more and 375 nm or less, 375 nm or more and 400 nm or less, 400 nm or more and 425 nm or less, 425 nm or more and 450 nm or less, 450 nm or more and 475 nm or less, and 475 nm or more and 500 nm or less. The thickness of the side wall dielectric film 91 is preferably 100 nm or more and 200 nm or less.

The anode capacitor structure CA includes a plurality of second capacitor electrode films 92 arranged on the first main surface 3 in the anode pad region 11A. The second capacitor electrode film 92 may also be referred to as a “second electrode.”

A potential different from the potential (emitter potential) applied to the plurality of capacitor structures 85 (plurality of first capacitor electrode films 90) is to be applied to the plurality of second capacitor electrode films 92. That is, a potential different from the potential (emitter potential) applied to the pad well region 80 is to be applied to the plurality of second capacitor electrode films 92.

The plurality of second capacitor electrode films 92 are arranged on the main surface insulating film 48 at intervals from the plurality of capacitor structures 85 (plurality of first capacitor electrode films 90). The plurality of second capacitor electrode films 92 form a capacitive coupling with the chip 2 through the main surface insulating film 48. Specifically, the plurality of second capacitor electrode films 92 cover the pad well region 80 with the main surface insulating film 48 interposed therebetween, and form a capacitive coupling with the pad well region 80 through the main surface insulating film 48.

Therefore, the plurality of second capacitor electrode films 92 form a plurality of first capacitors C1 with the chip 2 (pad well region 80) in the anode pad region 11A. The plurality of first capacitors C1 are connected in parallel to each other.

The plurality of second capacitor electrode films 92 are arranged on the first main surface 3 (main surface insulating film 48) at an interval from one or a plurality of first capacitor electrode films 90 in the horizontal direction, and face the one or a plurality of first capacitor electrode films 90 in the horizontal direction.

In this embodiment, the plurality of second capacitor electrode films 92 are arranged at an interval from one or a plurality of first capacitor electrode films 90 in the second direction Y, respectively, and are adjacent to the one or a plurality of first capacitor electrode films 90 in the second direction Y.

Specifically, the plurality of second capacitor electrode films 92 are respectively arranged in regions between the plurality of first capacitor electrode films 90 adjacent to one another in the second direction Y, and are alternately aligned with the plurality of first capacitor electrode films 90 in the second direction Y.

The plurality of second capacitor electrode films 92 extend in a band shape in the first direction X in conformance to the extension direction of the plurality of first capacitor electrode films 90, respectively. That is, the plurality of second capacitor electrode films 92 are aligned in a stripe shape extending along the first direction X.

The plurality of second capacitor electrode films 92 may have a width larger than the width of the plurality of capacitor structures 85. The width of the second capacitor electrode film 92 is a width in a direction orthogonal to the extension direction of the second capacitor electrode film 92. As a matter of course, the width of the second capacitor electrode film 92 may be smaller than the width of the capacitor structure 85.

The width of the second capacitor electrode film 92 may be substantially equal to or different from the width of the first capacitor electrode film 90. The width of the second capacitor electrode film 92 may be larger or smaller than the width of the first capacitor electrode film 90.

In this embodiment, the plurality of second capacitor electrode films 92 include a plurality of outermost second capacitor electrode films 92 arranged on both sides of the plurality of first capacitor electrode films 90 in the second direction Y. The outermost second capacitor electrode film 92 arranged on one side in the second direction Y faces one first capacitor electrode film 90 on the other side in the second direction Y.

The outermost second capacitor electrode film 92 arranged on the other side in the second direction Y faces one first capacitor electrode film 90 on one side in the second direction Y. As a matter of course, the plurality of second capacitor electrode films 92 may be arranged only in regions between the plurality of first capacitor electrode films 90.

The plurality of second capacitor electrode films 92 face one or a plurality of first capacitor electrode films 90 in the horizontal direction with one or a plurality of side wall dielectric films 91 interposed therebetween, and form a capacitive coupling with the one or a plurality of first capacitor electrode films 90 through the one or a plurality of side wall dielectric films 91.

The plurality of second capacitor electrode films 92 form a capacitive coupling with the first capacitor electrode film 90 only in the horizontal direction. That is, the plurality of second capacitor electrode films 92 have no portion covering the main electrode surface of the first capacitor electrode film 90, and form no capacitive coupling with the first capacitor electrode film 90 in the thickness direction.

The entire region of a side wall of the second capacitor electrode film 92 preferably faces the side wall of the corresponding first capacitor electrode film 90 through the corresponding side wall dielectric film 91. As a matter of course, a part of the side wall of the second capacitor electrode film 92 may face the side wall of the corresponding first capacitor electrode film 90 through the corresponding side wall dielectric film 91.

The second capacitor electrode film 92 may have a side wall extending substantially perpendicular to the first main surface 3. As a matter of course, the side wall of the second capacitor electrode film 92 may be inclined obliquely downward from the main electrode surface toward the chip 2 (first main surface 3) side.

The plurality of second capacitor electrode films 92 form a plurality of second capacitors C2 with the corresponding first capacitor electrode films 90 in the anode pad region 11A. The plurality of second capacitors C2 are connected in parallel to each other. The plurality of second capacitors C2 are connected in parallel to the plurality of first capacitors C1.

In this embodiment, the thickness of the side wall dielectric film 91 is larger than the thickness of the main surface insulating film 48. Therefore, the capacitance value of the second capacitor C2 is smaller than the capacitance value of the first capacitor C1. As a matter of course, the thickness of the side wall dielectric film 91 may be smaller than the thickness of the main surface insulating film 48. That is, the capacitance value of the second capacitor C2 may be larger than the capacitance value of the first capacitor C1.

The second capacitor electrode film 92 may be formed of a conductor film other than metal. In this embodiment, the second capacitor electrode film 92 is formed of the same type of conductor as the first capacitor electrode film 90 (capacitor embedded electrode 88) (either or both of p-type conductive polysilicon and n-type conductive polysilicon).

The conductive type of the second capacitor electrode film 92 may be the same as or different from the conductive type of the first capacitor electrode film 90. The second capacitor electrode film 92 may be formed of a metal film.

The second capacitor electrode film 92 has a thickness larger than the thickness of the main surface insulating film 48. The thickness of the second capacitor electrode film 92 is the thickness of the second capacitor electrode film 92 with the insulating surface of the main surface insulating film 48 as a reference.

The thickness of the second capacitor electrode film 92 is preferably smaller than the depth (thickness) of the pad well region 80. The thickness of the second capacitor electrode film 92 is preferably smaller than the depth of the capacitor structure 85.

The thickness of the second capacitor electrode film 92 is preferably smaller than the depth of the gate structure 20 (emitter structure 30). The thickness of the second capacitor electrode film 92 is preferably smaller than the depth of the gate connection structure 25 (emitter connection structure 35).

The thickness of the second capacitor electrode film 92 may be substantially equal to the thickness of the polysilicon layer 50. As a matter of course, the thickness of the second capacitor electrode film 92 may be larger or smaller than the thickness of the polysilicon layer 50.

The thickness of the second capacitor electrode film 92 may be substantially equal to the thickness of the emitter wiring 55. As a matter of course, the thickness of the second capacitor electrode film 92 may be larger or smaller than the thickness of the emitter wiring 55.

The thickness of the second capacitor electrode film 92 may be substantially equal to the thickness of the gate wiring 56. As a matter of course, the thickness of the second capacitor electrode film 92 may be larger or smaller than the thickness of the gate wiring 56.

The thickness of the second capacitor electrode film 92 is preferably substantially equal to the thickness of the first capacitor electrode film 90. As a matter of course, the thickness of the second capacitor electrode film 92 may be larger or smaller than the thickness of the first capacitor electrode film 90.

The thickness of the second capacitor electrode film 92 may be 0.1 μm or more and 2 μm or less. The thickness of the second capacitor electrode film 92 may have a value belonging to at least one of the following ranges, 0.1 μm or more and 0.25 μm or less, 0.25 μm or more and 0.5 μm or less, 0.5 μm or more and 0.75 μm or less, 0.75 μm or more and 1 μm or less, 1.25 μm or more and 1.5 μm or less, 1.5 μm or more and 1.75 μm or less, and 1.75 μm or more and 2 μm or less. The thickness of the second capacitor electrode film 92 is preferably 0.25 μm or more and 1.25 μm or less.

The anode capacitor structure CA includes the above-described interlayer film 57 that covers the plurality of first capacitor electrode films 90 and the plurality of second capacitor electrode films 92 in the anode pad region 11A. The interlayer film 57 is connected to the plurality of side wall dielectric films 91 on the plurality of first capacitor electrode films 90 and the plurality of second capacitor electrode films 92.

In this embodiment, the interlayer film 57 is formed integrally with the plurality of side wall dielectric films 91. That is, the interlayer film 57 has the plurality of side wall dielectric films 91 as a plurality of embedded portions embedded in gap portions between the plurality of first capacitor electrode films 90 and the plurality of second capacitor electrode films 92.

The interlayer film 57 covers the pad well region 80 with the main surface insulating film 48 and the plurality of first capacitor electrode films 90 interposed therebetween, and covers the pad well region 80 with the main surface insulating film 48 and the plurality of second capacitor electrode films 92 interposed therebetween.

The thickness of the interlayer film 57 is preferably larger than the thickness of the first capacitor electrode film 90. As a matter of course, the thickness of the interlayer film 57 may be smaller than the thickness of the first capacitor electrode film 90. The thickness of the interlayer film 57 is preferably larger than the thickness of the second capacitor electrode film 92. As a matter of course, the thickness of the interlayer film 57 may be smaller than the thickness of the second capacitor electrode film 92.

The anode capacitor structure CA includes a plurality of pad openings 93 selectively formed in the interlayer film 57 in the anode pad region 11A. The plurality of pad openings 93 selectively expose parts of the plurality of second capacitor electrode films 92. Specifically, the plurality of pad openings 93 expose parts of the plurality of second capacitor electrode films 92 at intervals from the plurality of first capacitor electrode films 90 (capacitor structures 85), respectively.

In this embodiment, the plurality of pad openings 93 are formed in one-to-one correspondence with the plurality of second capacitor electrode films 92, and extend in a band shape in the first direction X in conformance to the extension direction of the corresponding second capacitor electrode films 92, respectively. The plurality of pad openings 93 expose inner portions of the corresponding second capacitor electrode films 92 at intervals from the peripheral edges of the corresponding second capacitor electrode films 92.

In this embodiment, the plurality of pad openings 93 have a bottom wall that is formed deeper from the main electrode surface of the corresponding second capacitor electrode film 92 toward the first main surface 3 (main surface insulating film 48) side and is positioned in the corresponding second capacitor electrode film 92. The bottom walls of the plurality of pad openings 93 are preferably formed at intervals from a thickness position of an intermediate portion of the corresponding second capacitor electrode film 92 to the main electrode surface side of the corresponding second capacitor electrode film 92.

As a matter of course, the bottom walls of the plurality of pad openings 93 may be positioned on the first main surface 3 (main surface insulating film 48) side relative to the thickness position of the intermediate portion of the corresponding second capacitor electrode film 92. The plurality of pad openings 93 may be formed in a tapered shape toward the bottom wall. As a matter of course, the plurality of pad openings 93 may be formed substantially perpendicular to the first main surface 3.

The plurality of pad openings 93 may be formed in one-to-many correspondence with the plurality of second capacitor electrode films 92, and may be formed at intervals in conformance to the extension direction (first direction X) of the corresponding second capacitor electrode films 92. In this case, the plurality of pad openings 93 may be formed in a polygonal shape, a circular shape, or the like in plan view. The plurality of pad openings 93 may be formed in a quadrangular shape, a hexagonal shape, or the like in plan view.

The anode capacitor structure CA includes a plurality of pad via electrodes 94 respectively embedded in the plurality of pad openings 93 in the anode pad region 11A. Each of the plurality of pad via electrodes 94 has a portion in contact with the interlayer film 57 and the corresponding second capacitor electrode film 92. The plurality of pad via electrodes 94 are mechanically and electrically connected to the corresponding second capacitor electrode films 92 in the corresponding pad openings 93.

Similar to the first emitter via electrode 59, the pad via electrode 94 may have a laminated structure including the first electrode 60 and the second electrode 61 laminated in this order from the wall surface side of the pad opening 93.

The first electrode 60 is formed in a film shape on the wall surface of the pad opening 93, and is mechanically and electrically connected to the corresponding second capacitor electrode film 92 in the pad opening 93. The second electrode 61 is embedded in the pad opening 93 with the first electrode 60 interposed therebetween, and is electrically connected to the corresponding second capacitor electrode film 92 through the first electrode 60.

The anode capacitor structure CA includes a pad electrode 95 arranged on the interlayer film 57 in the anode pad region 11A. The pad electrode 95 may also be referred to as a “pad,” “terminal electrode,” “external terminal,” or the like.

The pad electrode 95 in the anode pad region 11A constitutes the above-described anode pad AP. The anode pad AP is a terminal to which an anode potential is to be applied from outside. The anode pad AP may also be referred to as an “anode pad electrode,” “anode terminal electrode,” “anode external terminal,” or the like.

The anode pad AP is arranged on a portion of the interlayer film 57 covering the plurality of first capacitor electrode films 90 (plurality of capacitor structures 85) and the plurality of second capacitor electrode films 92. The anode pad AP is electrically insulated from the plurality of first capacitor electrode films 90 (plurality of capacitor structures 85) by the interlayer film 57, and is electrically connected to the plurality of second capacitor electrode films 92 through the plurality of pad openings 93.

Specifically, the anode pad AP is mechanically and electrically connected to the plurality of pad via electrodes 94 on the interlayer film 57, and is electrically connected to the plurality of second capacitor electrode films 92 through the plurality of pad via electrodes 94. Therefore, the anode potential applied to the anode pad AP is to be applied to the plurality of second capacitor electrode films 92.

The anode pad AP has a peripheral edge positioned outside the peripheral edges of the plurality of first capacitor electrode films 90 (plurality of capacitor structures 85) and the peripheral edges of the plurality of second capacitor electrode films 92 in plan view, and collectively covers the plurality of first capacitor electrode films 90 (plurality of capacitor structures 85) and the plurality of second capacitor electrode films 92.

In this embodiment, the anode pad AP is formed in a polygonal shape having four sides parallel to the peripheral edge of the chip 2 in plan view (in this embodiment, quadrangular shape). The anode pad AP may be formed in a hexagonal shape or a circular shape in plan view.

The anode pad AP is mechanically and electrically connected to the anode wiring 75 on the interlayer film 57. Therefore, the anode potential applied to the anode pad AP is to be applied to the temperature-sensitive diode structure D through the anode wiring 75.

The anode pad AP may have a thickness larger than the thickness of the interlayer film 57. The thickness of the anode pad AP is preferably larger than the thicknesses of the plurality of first capacitor electrode films 90 and the plurality of second capacitor electrode films 92.

The thickness of the anode pad AP may be 0.5 μm or more and 10 μm or less. The thickness of the anode pad AP may have a value belonging to at least one of the following ranges, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less.

Similar to the emitter pad EP, the anode pad AP may have a laminated structure including the first electrode film 65 and the second electrode film 66 laminated in this order from the interlayer film 57 side. The first electrode film 65 covers the interlayer film 57 in a film shape as a barrier electrode. The first electrode film 65 is electrically connected to the plurality of pad via electrodes 94 on the interlayer film 57.

The first electrode film 65 is connected to the first electrode 60 of the plurality of pad via electrodes 94. As a matter of course, the first electrode film 65 may cover the first electrode 60 of the plurality of pad via electrodes 94. The first electrode film 65 is connected to the first electrode film 65 of the anode wiring 75 on the interlayer film 57.

The second electrode film 66 has a thickness larger than the thickness of the first electrode film 65, and covers the first electrode film 65 in a film shape. As a matter of course, the second electrode film 66 covers the second electrode 61 of the plurality of pad via electrodes 94 in a film shape. The second electrode film 66 is connected to the second electrode film 66 of the anode wiring 75 on the first electrode film 65.

Referring again to FIGS. 1 and 3, similar to the anode capacitor structure CA, the monitor capacitor structure CM includes a plurality of capacitor structures 85, a plurality of first capacitor electrode films 90, a main surface insulating film 48, a side wall dielectric film 91, a plurality of second capacitor electrode films 92, an interlayer film 57, a plurality of pad openings 93, a plurality of pad via electrodes 94, and a pad electrode 95.

Similar to the plurality of capacitor structures 85 for the anode capacitor structure CA, the plurality of capacitor structures 85 for the monitor capacitor structure CM are led out from the active region 6 (in this embodiment, third active region 6C) adjacent thereto in the first direction X, to the monitor pad region 11M.

As a matter of course, one or a plurality of capacitor structures 85 for the monitor capacitor structure CM may have one or a plurality of lead-out portions 85a extending in the second direction Y, and may be connected to one or a plurality of emitter structures 30 of the active region 6 (for example, third active region 6C) adjacent thereto in the second direction Y.

The configuration of the plurality of first capacitor electrode films 90, the main surface insulating film 48, the side wall dielectric film 91, the plurality of second capacitor electrode films 92, the interlayer film 57, the plurality of pad openings 93, and the plurality of pad via electrodes 94 in the monitor region 7 is similar to the layout of the anode pad region 11A.

The pad electrode 95 in the monitor region 7 constitutes the above-described monitor pad MP. The monitor pad MP is a terminal to which a monitor potential is to be applied from outside. The monitor pad MP may also be referred to as a “monitor pad electrode,” “monitor terminal electrode,” “monitor external terminal,” or the like.

The monitor pad MP is arranged on a portion of the interlayer film 57 covering the plurality of first capacitor electrode films 90 (plurality of capacitor structures 85) and the plurality of second capacitor electrode films 92. The monitor pad MP is electrically insulated from the plurality of first capacitor electrode films 90 (plurality of capacitor structures 85) by the interlayer film 57, and is electrically connected to the plurality of second capacitor electrode films 92 through the plurality of pad openings 93.

Specifically, the monitor pad MP is mechanically and electrically connected to the plurality of pad via electrodes 94 on the interlayer film 57, and is electrically connected to the plurality of second capacitor electrode films 92 through the plurality of pad via electrodes 94. Therefore, the monitor potential applied to the monitor pad MP is to be applied to the plurality of second capacitor electrode films 92.

The monitor pad MP has a peripheral edge positioned outside the peripheral edges of the plurality of first capacitor electrode films 90 (plurality of capacitor structures 85) and the peripheral edges of the plurality of second capacitor electrode films 92 in plan view, and collectively covers the plurality of first capacitor electrode films 90 (plurality of capacitor structures 85) and the plurality of second capacitor electrode films 92.

In this embodiment, the monitor pad MP is formed in a polygonal shape having four sides parallel to the peripheral edge of the chip 2 in plan view (in this embodiment, quadrangular shape). The monitor pad MP may be formed in a hexagonal shape or a circular shape in plan view.

The monitor pad MP may be arranged on the first side surface 5A side relative to the monitor electrode 67, and may have a lead-out portion led out toward the monitor electrode 67. The lead-out portion extends in a band shape in the second direction Y and is mechanically and electrically connected to the monitor electrode 67.

Therefore, the monitor potential applied to the monitor pad MP is to be applied to the plurality of emitter structures 30, the plurality of emitter connection structures 35, the plurality of emitter regions 40, and the plurality of contact regions 41 through the monitor electrode 67, the plurality of first emitter via electrodes 59, and the plurality of second emitter via electrodes 63.

The monitor pad MP may have a thickness larger than the thickness of the interlayer film 57. The thickness of the monitor pad MP is preferably larger than the thicknesses of the plurality of first capacitor electrode films 90 and the plurality of second capacitor electrode films 92. The thickness range of the monitor pad MP is similar to the thickness range of the anode pad AP (0.5 μm or more and 10 μm or less).

Similar to the emitter pad EP, the monitor pad MP may have a laminated structure including the first electrode film 65 and the second electrode film 66 laminated in this order from the interlayer film 57 side. The first electrode film 65 covers the interlayer film 57 in a film shape as a barrier electrode. The first electrode film 65 is electrically connected to the plurality of pad via electrodes 94 on the interlayer film 57.

The first electrode film 65 is connected to the first electrode 60 of the plurality of pad via electrodes 94. As a matter of course, the first electrode film 65 may cover the first electrode 60 of the plurality of pad via electrodes 94. The first electrode film 65 is connected to the first electrode film 65 of the monitor electrode 67 on the interlayer film 57.

The second electrode film 66 has a thickness larger than the thickness of the first electrode film 65, and covers the first electrode film 65 in a film shape. As a matter of course, the second electrode film 66 covers the second electrode 61 of the plurality of pad via electrodes 94 in a film shape. The second electrode film 66 is connected to the second electrode film 66 of the monitor electrode 67 on the first electrode film 65.

Similar to the anode capacitor structure CA, the cathode capacitor structure CC includes a plurality of capacitor structures 85, a plurality of first capacitor electrode films 90, a main surface insulating film 48, a side wall dielectric film 91, a plurality of second capacitor electrode films 92, an interlayer film 57, a plurality of pad openings 93, a plurality of pad via electrodes 94, and a pad electrode 95.

Similar to the plurality of capacitor structures 85 for the anode capacitor structure CA, the plurality of capacitor structures 85 for the cathode capacitor structure CC are led out from the active region 6 (in this embodiment, first active region 6A) adjacent thereto in the first direction X, to the cathode pad region 11C.

In this embodiment, the plurality of capacitor structures 85 for the cathode capacitor structure CC are connected to the plurality of capacitor structures 85 for the anode capacitor structure CA through the plurality of lead-out portions 85a.

That is, the plurality of capacitor structures 85 for the cathode capacitor structure CC are connected to the plurality of emitter structures 30 of the active region 6 (in this embodiment, first active region 6A) through the plurality of capacitor structures 85 for the anode capacitor structure CA.

As a matter of course, one or a plurality of capacitor structures 85 for the cathode capacitor structure CC may have one or a plurality of lead-out portions 85a extending in the second direction Y, and may be connected to one or a plurality of emitter structures 30 of the active region 6 (for example, second active region 6B) adjacent thereto in the second direction Y.

The pad electrode 95 in the cathode pad region 11C constitutes the above-described cathode pad CaP. The cathode pad CaP is a terminal to which a cathode potential is to be applied from outside. The cathode pad CaP may also be referred to as a “cathode pad electrode,” “cathode terminal electrode,” “cathode external terminal,” or the like.

The cathode pad CaP is arranged on a portion of the interlayer film 57 covering the plurality of first capacitor electrode films 90 (plurality of capacitor structures 85) and the plurality of second capacitor electrode films 92.

The cathode pad CaP is electrically insulated from the plurality of first capacitor electrode films 90 (plurality of capacitor structures 85) by the interlayer film 57, and is electrically connected to the plurality of second capacitor electrode films 92 through the plurality of pad openings 93.

Specifically, the cathode pad CaP is mechanically and electrically connected to the plurality of pad via electrodes 94 on the interlayer film 57, and is electrically connected to the plurality of second capacitor electrode films 92 through the plurality of pad via electrodes 94. Therefore, the cathode potential applied to the cathode pad CaP is to be applied to the plurality of second capacitor electrode films 92.

The cathode pad CaP has a peripheral edge positioned outside the peripheral edges of the plurality of first capacitor electrode films 90 (plurality of capacitor structures 85) and the peripheral edges of the plurality of second capacitor electrode films 92 in plan view, and collectively covers the plurality of first capacitor electrode films 90 (plurality of capacitor structures 85) and the plurality of second capacitor electrode films 92.

In this embodiment, the cathode pad CaP is formed in a polygonal shape having four sides parallel to the peripheral edge of the chip 2 in plan view (in this embodiment, quadrangular shape). The cathode pad CaP may be formed in a hexagonal shape or a circular shape in plan view.

The cathode pad CaP is connected to the cathode wiring 76 on the interlayer film 57. Therefore, the cathode potential applied to the cathode pad CaP is to be applied to the temperature-sensitive diode structure D through the cathode wiring 76.

The cathode pad CaP may have a thickness larger than the thickness of the interlayer film 57. The thickness of the cathode pad CaP is preferably larger than the thicknesses of the plurality of first capacitor electrode films 90 and the plurality of second capacitor electrode films 92. The thickness range of the cathode pad CaP is similar to the thickness range of the anode pad AP (0.5 μm or more and 10 μm or less).

Similar to the emitter pad EP, the cathode pad CaP may have a laminated structure including the first electrode film 65 and the second electrode film 66 laminated in this order from the interlayer film 57 side. The first electrode film 65 covers the interlayer film 57 in a film shape as a barrier electrode. The first electrode film 65 is electrically connected to the plurality of pad via electrodes 94 on the interlayer film 57.

The first electrode film 65 is connected to the first electrode 60 of the plurality of pad via electrodes 94. As a matter of course, the first electrode film 65 may cover the first electrode 60 of the plurality of pad via electrodes 94. The first electrode film 65 is connected to the first electrode film 65 of the cathode wiring 76 on the interlayer film 57.

The second electrode film 66 has a thickness larger than the thickness of the first electrode film 65, and covers the first electrode film 65 in a film shape. As a matter of course, the second electrode film 66 covers the second electrode 61 of the plurality of pad via electrodes 94 in a film shape. The second electrode film 66 is connected to the second electrode film 66 of the cathode wiring 76 on the first electrode film 65.

The semiconductor device 1A does not have the plurality of capacitor structures 85, the plurality of first capacitor electrode films 90, the side wall dielectric film 91, the plurality of second capacitor electrode films 92, the plurality of pad openings 93, and the plurality of pad via electrodes 94 in the gate pad region 11G. That is, the gate pad region 11G does not have the pad capacitor structure 84. This is because the capacitance value is secured by the plurality of gate structures 20 arranged in the plurality of active regions 6.

The semiconductor device 1A includes the pad electrode 95 arranged on the interlayer film 57 in the gate pad region 11G. The pad electrode 95 of the gate pad region 11G constitutes the above-described gate pad GP. The gate pad GP is a terminal to which a gate potential is to be applied from an exterior. The gate pad GP may be referred to as a “gate pad electrode,” a “gate terminal electrode,” a “gate external terminal,” or the like.

The gate pad GP opposes the pad well region 80 with the main surface insulating film 48 and the interlayer film 57 interposed therebetween. The entire region of the gate pad GP preferably opposes the pad well region 80. The gate pad GP is connected to the plurality of gate fingers 70 on the interlayer film 57. As a result, the gate potential applied to the gate pad GP is to be applied to the plurality of gate structures 20 via the plurality of gate wirings 56 and the plurality of gate fingers 70.

In this embodiment, the gate pad GP is formed in a polygonal shape (in this embodiment, a quadrangular shape) having four sides parallel to the peripheral edge of the chip 2 in plan view. The gate pad GP may be formed in a hexagonal shape or a circular shape in plan view.

The gate pad GP may have a thickness larger than the thickness of the interlayer film 57. The thickness of the gate pad GP is preferably larger than the thickness of the plurality of first capacitor electrode films 90 and the thickness of the plurality of second capacitor electrode films 92. The thickness range of the gate pad GP is similar to the thickness range (0.5 μm or more and 10 μm or less) of the anode pad AP.

Similarly to the emitter pad EP, the gate pad GP may have a laminated structure including the first electrode film 65 and the second electrode film 66 laminated in this order from the interlayer film 57 side. The first electrode film 65 covers the interlayer film 57 in a film shape as a barrier electrode. The first electrode film 65 is connected to the first electrode films 65 of the plurality of gate fingers 70 on the interlayer film 57.

The second electrode film 66 has a thickness larger than the thickness of the first electrode film 65, and covers the first electrode film 65 in a film shape. The second electrode film 66 is connected to the second electrode films 66 of the plurality of gate fingers 70 on the first electrode film 65.

The semiconductor device 1A includes the collector pad CoP covering the second main surface 4. The collector pad CoP is a terminal to which a collector potential is to be applied from an exterior. The collector pad CoP may be referred to as a “collector pad electrode,” a “collector terminal electrode,” a “collector external terminal,” or the like. The collector pad CoP is formed in a film shape along the second main surface 4 and is electrically connected to the collector region 14.

The collector pad CoP covers the plurality of active regions 6, the monitor region 7, the outer peripheral region 8, the plurality of street regions 9, the plurality of temperature detection regions 10, and the plurality of pad regions 11 from the second main surface 4 side. The collector pad CoP may cover the entire region of the second main surface 4. As a matter of course, the collector pad CoP may be formed at an interval inward from the peripheral edge (first to fourth side surfaces 5A to 5D) of the second main surface 4, and expose the peripheral edge portion (collector region 14) of the second main surface 4.

The breakdown voltage that can be applied between the emitter pad EP and the collector pad CoP (between the first main surface 3 and the second main surface 4) may be 500 V or more and 3000 V or less. The breakdown voltage may have a value belonging to at least one of the ranges of 500 V or more and 750 V or less, 750 V or more and 1000 V or less, 1000 V or more and 1250 V or less, 1250 V or more and 1500 V or less, 1500 V or more and 1750 V or less, 1750 V or more and 2000 V or less, 2000 V or more and 2250 V or less, 2250 V or more and 2500 V or less, 2500 V or more and 2750 V or less, and 2750 V or more and 3000 V or less.

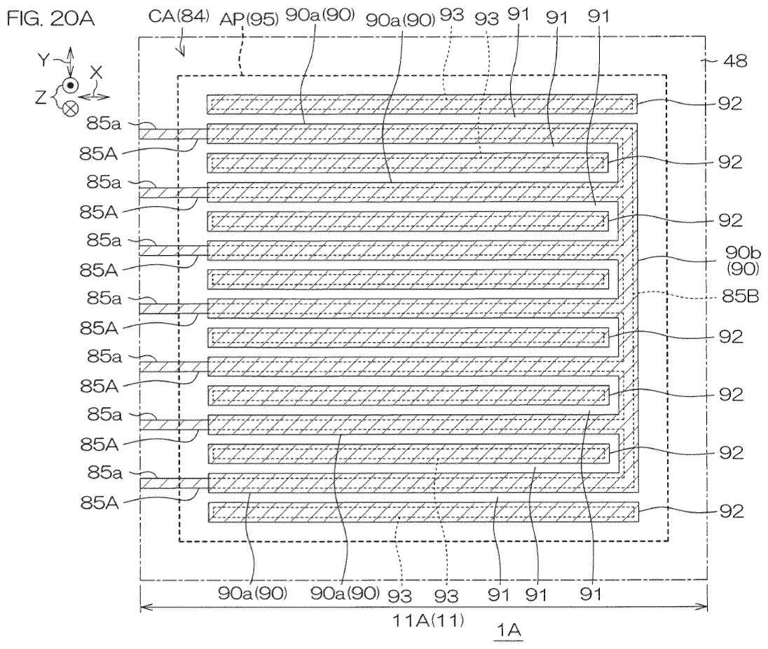

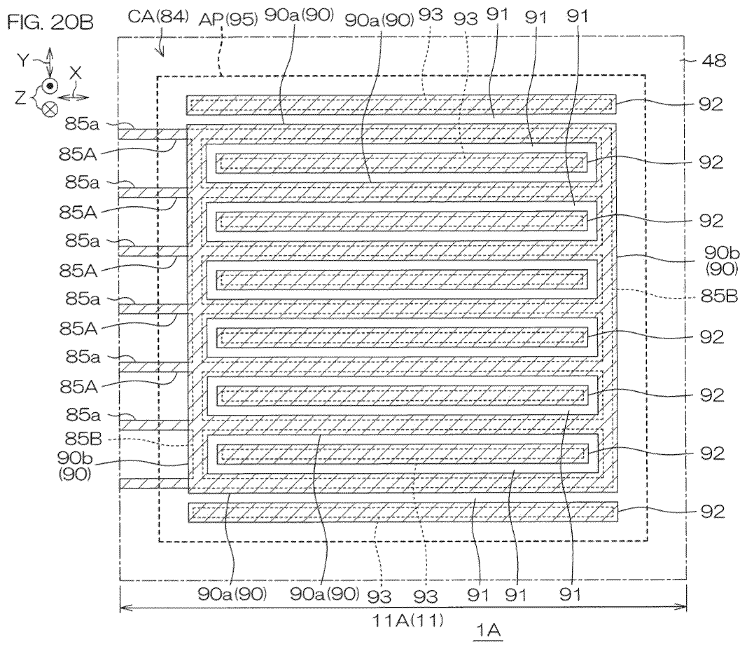

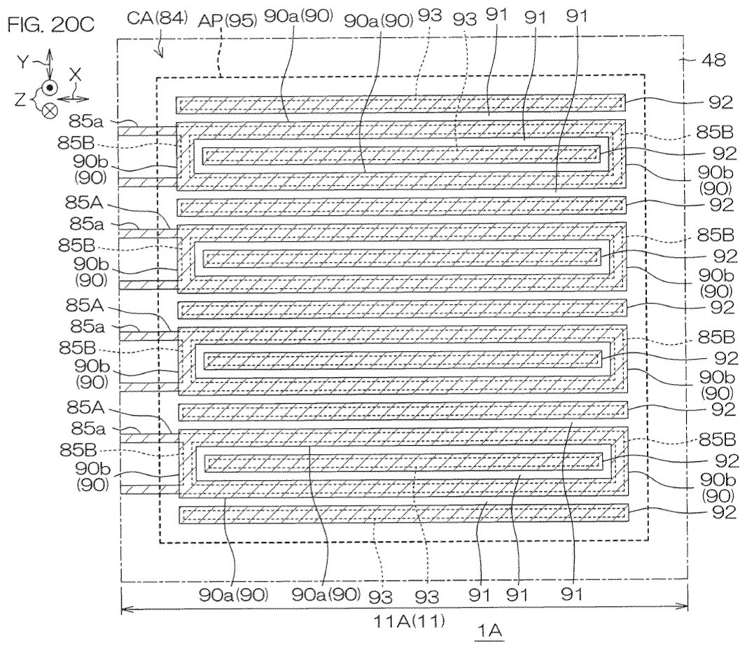

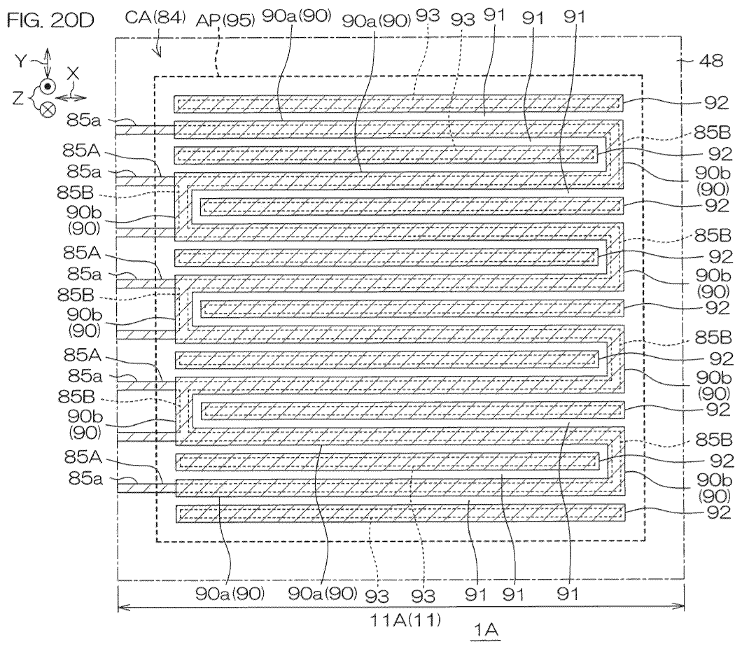

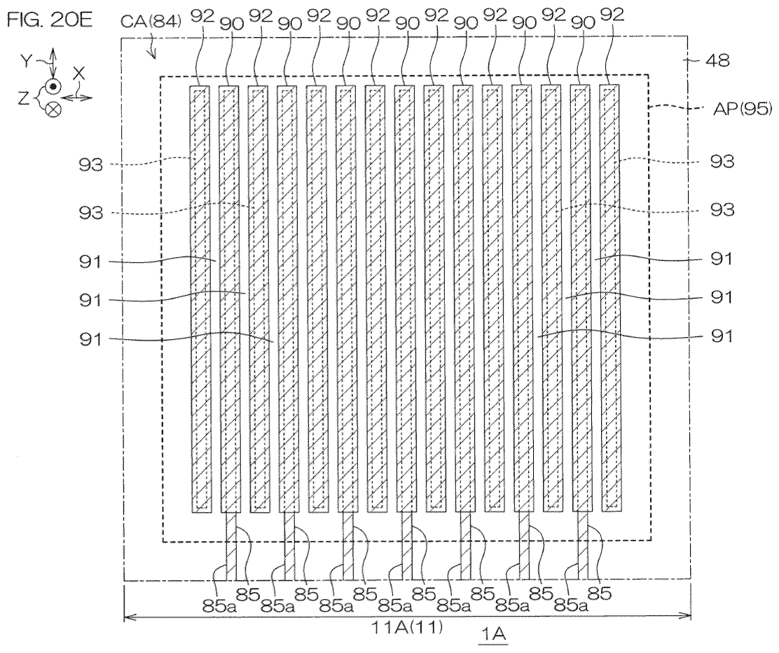

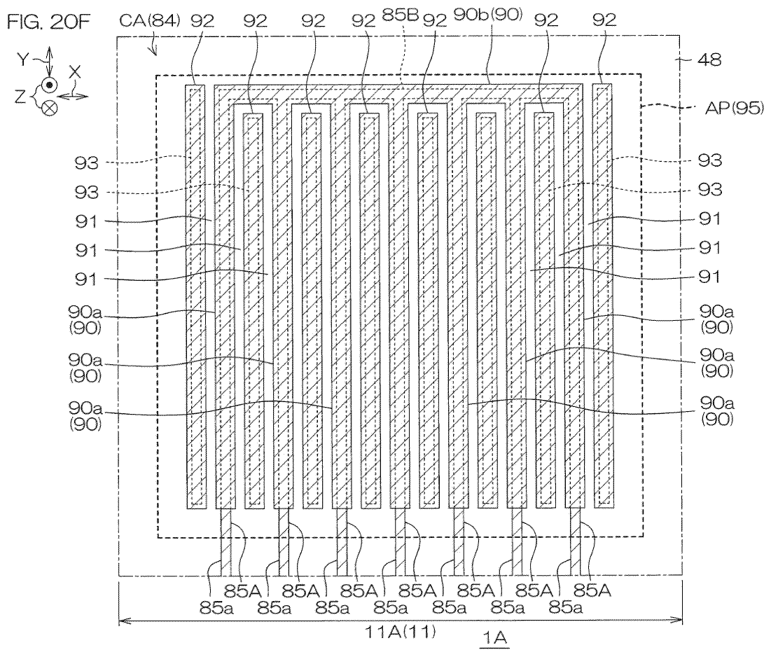

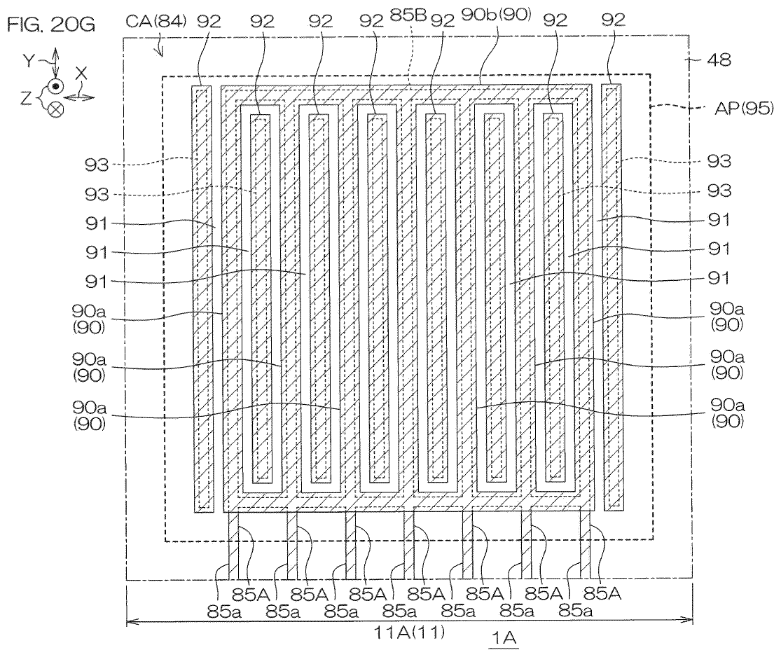

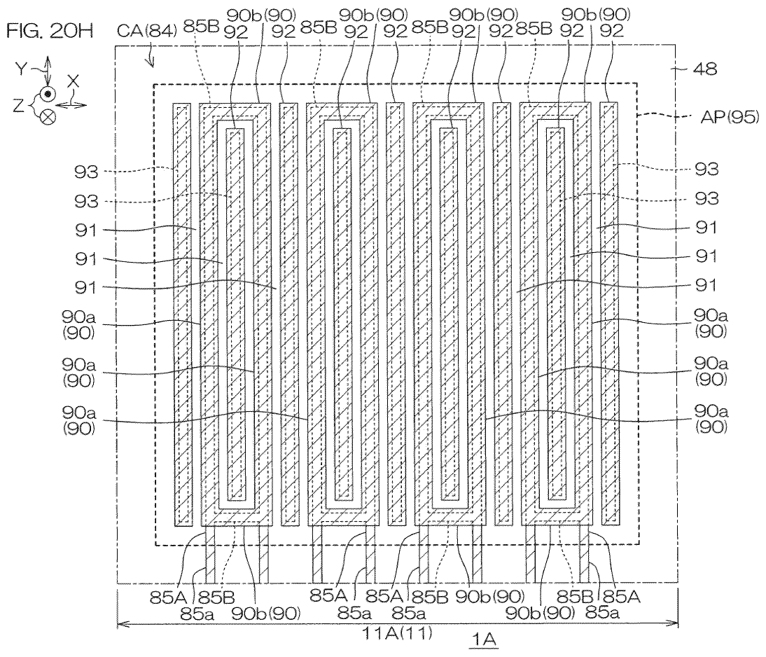

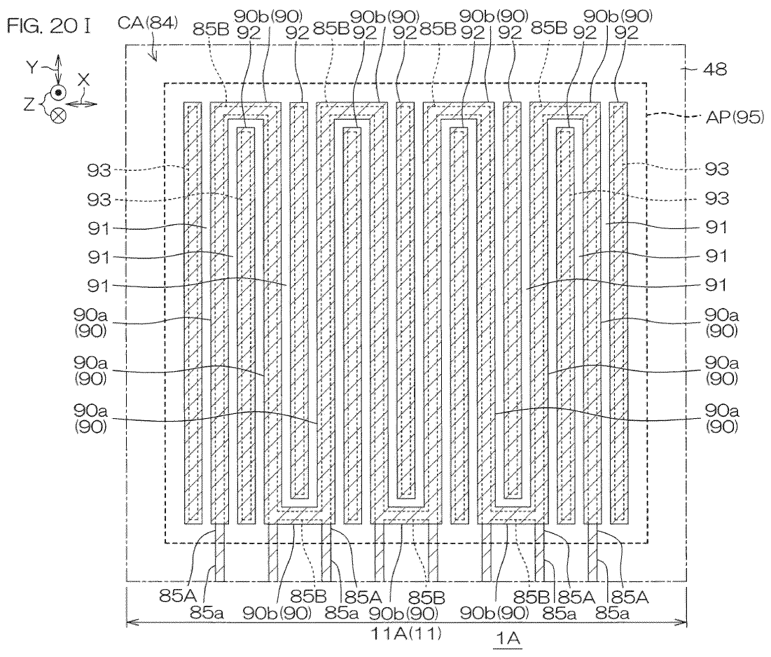

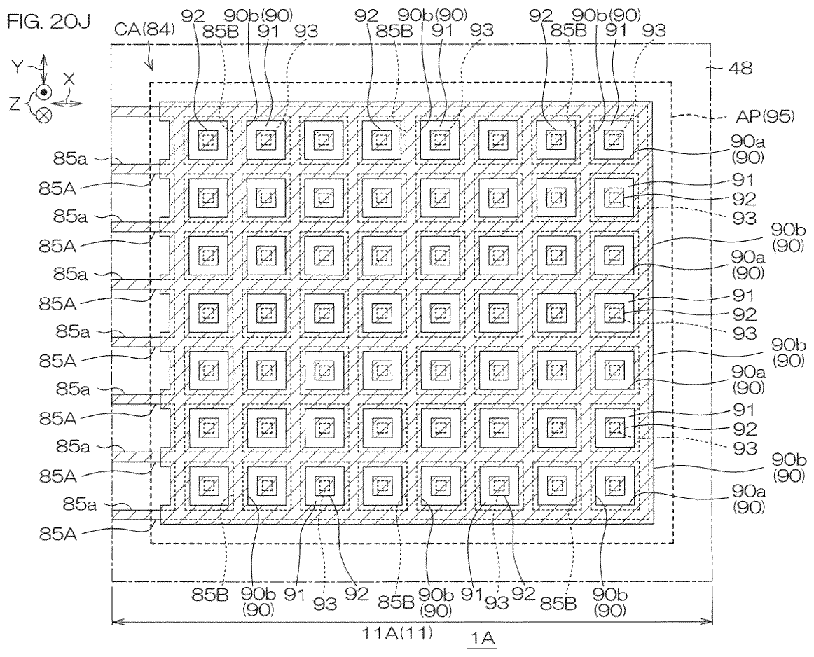

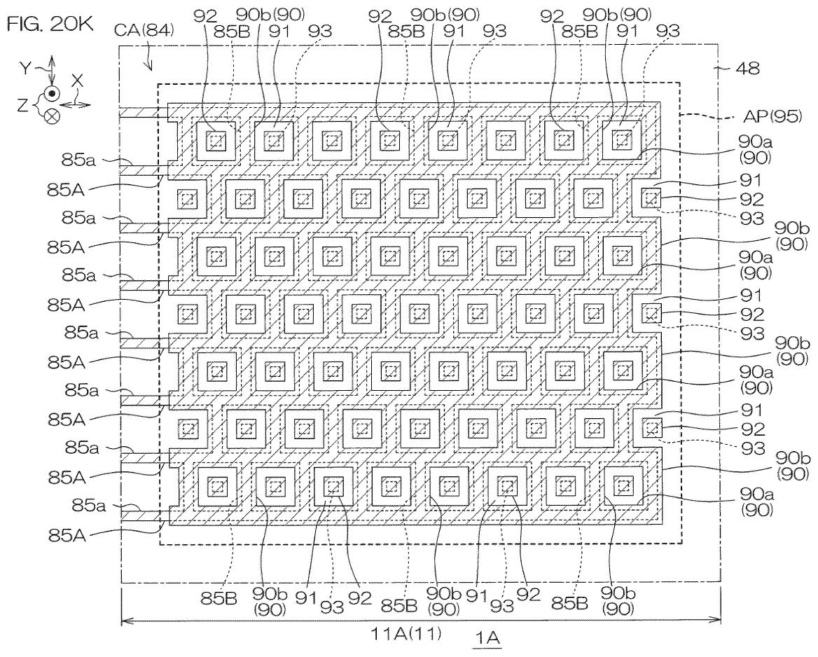

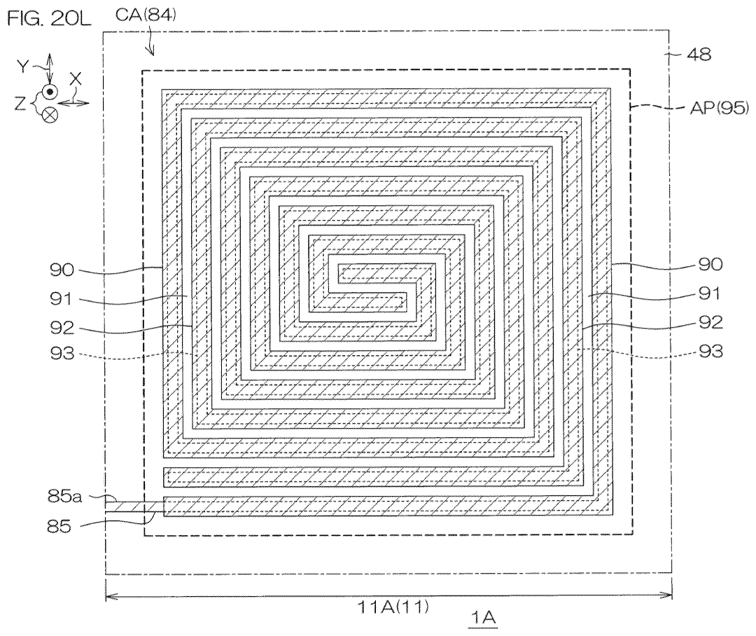

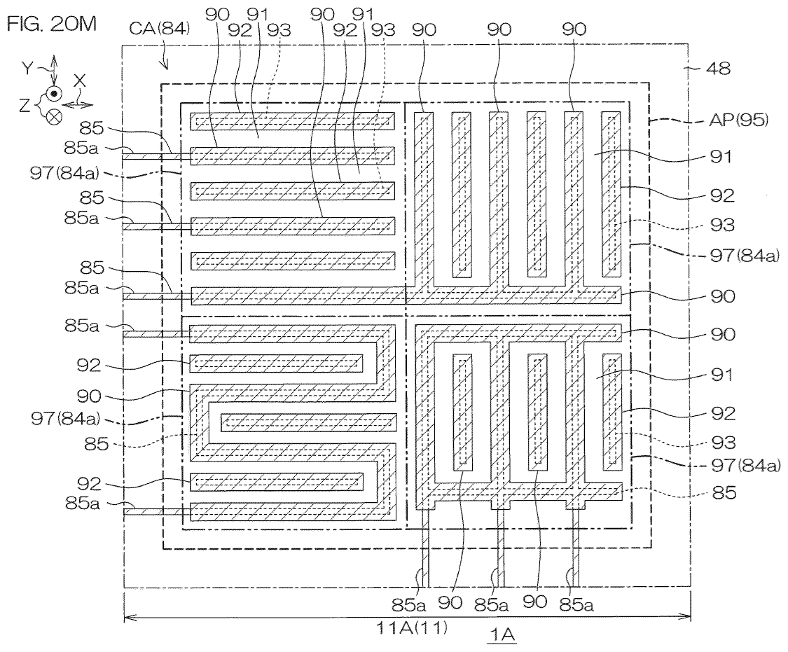

Hereinafter, another layout example of the capacitor structure 85 will be described. FIGS. 20A to 20M are plan views showing the pad capacitor structures 84 according to the second to fourteenth layout examples. The plurality of pad capacitor structures 84 may each include at least one of the pad capacitor structures 84 according to the second to fourteenth layout examples instead of or in addition to the pad capacitor structure 84 according to the first layout example.

That is, the monitor capacitor structure CM may include at least one of the pad capacitor structures 84 according to the first to fourteenth layout examples in the monitor pad region 11M. The anode capacitor structure CA may include at least one of the pad capacitor structures 84 according to the first to fourteenth layout examples in the anode pad region 11A.

The cathode capacitor structure CC may include at least one of the pad capacitor structures 84 according to the first to fourteenth layout examples in the cathode pad region 11C. The monitor capacitor structure CM, the anode capacitor structure CA, and the cathode capacitor structure CC do not necessarily have the pad capacitor structures 84 according to the same layout example, and may have the pad capacitor structures 84 according to the layout examples different from each other.

With reference to FIG. 20A (second layout example), similarly to the case of the first layout example, the pad capacitor structure 84 includes the plurality of capacitor structures 85. In this embodiment, the plurality of capacitor structures 85 include a plurality of first capacitor structures 85A extending in a stripe shape in the first direction X and one second capacitor structure 85B extending in the second direction Y. In this embodiment, the plurality of first capacitor structures 85A include the plurality of lead-out portions 85a.

The plurality of first capacitor structures 85A each have proximal end portions on one side (third side surface 5C side) in the longitudinal direction (first direction X) and distal end portions on the other side (fourth side surface 5D side) in the longitudinal direction (first direction X). The proximal end portions of the plurality of first capacitor structures 85A are boundary portions between the plurality of lead-out portions 85a and the pad electrode 95 (anode pad AP).

The second capacitor structure 85B extends in a band shape in the second direction Y and is connected to the distal end portions of the plurality of first capacitor structures 85A. That is, the plurality of capacitor structures 85 constitute a single comb teeth-shaped capacitor structure 85 in plan view. As a matter of course, the second capacitor structure 85B may be connected to regions on the proximal end portion side of the plurality of first capacitor structures 85A.

The pad capacitor structure 84 includes a plurality of first capacitor electrode films 90 as in the first layout example. In this embodiment, the plurality of first capacitor electrode films 90 include a plurality of first electrode films 90a connected to the plurality of first capacitor structures 85A and a second electrode film 90b connected to the second capacitor structure 85B.

The plurality of first electrode films 90a extend in a stripe shape in the first direction X in conformance to the layout of the plurality of first capacitor structures 85A. The second electrode film 90b extends in a band shape in the second direction Y in conformance to the layout of the second capacitor structure 85B and is connected to the plurality of first electrode films 90a. Therefore, the plurality of first capacitor electrode films 90 constitute one first capacitor electrode film 90 having a comb teeth shape in plan view.

The pad capacitor structure 84 includes a plurality of side wall dielectric films 91 as in the first layout example. The plurality of side wall dielectric films 91 cover side walls of the plurality of first electrode films 90a and the second electrode film 90b, respectively. The side wall dielectric film 91 on the second electrode film 90b side is connected to the plurality of side wall dielectric films 91 on the plurality of first electrode film 90a side at connection portions between the plurality of first electrode films 90a and the second electrode film 90b.

The pad capacitor structure 84 includes a plurality of second capacitor electrode films 92 as in the first layout example. The plurality of second capacitor electrode films 92 are aligned in a stripe shape extending along the first direction X as in the first layout example. In this embodiment, the plurality of second capacitor electrode films 92 are alternately aligned in the second direction Y with the plurality of first electrode films 90a.

The plurality of second capacitor electrode films 92 include a plurality of inner second capacitor electrode films 92 and a plurality of outer second capacitor electrode films 92. The plurality of inner second capacitor electrode films 92 are arranged in regions defined by the plurality of first electrode films 90a and the second electrode film 90b, respectively.

The plurality of inner second capacitor electrode films 92 face the plurality of first electrode films 90a in the second direction Y, and have portions that form a capacitive coupling with the plurality of first electrode films 90a through the plurality of side wall dielectric films 91. The plurality of inner second capacitor electrode films 92 face the second electrode film 90b in the first direction X, and have portions that form a capacitive coupling with the second electrode film 90b through the side wall dielectric films 91.

The plurality of outer second capacitor electrode films 92 are arranged on both sides of the plurality of first capacitor electrode films 90 in the second direction Y, respectively. The plurality of outer second capacitor electrode films 92 face the first electrode films 90a in the second direction Y, respectively, and have portions that form a capacitive coupling with the first electrode films 90a through the side wall dielectric films 91, respectively.

The plurality of outer second capacitor electrode films 92 may face the second electrode film 90b in the second direction Y, respectively, and may have portions that form a capacitive coupling with the second electrode film 90b through the side wall dielectric films 91, respectively. The plurality of outer second capacitor electrode films 92 may be formed at an interval from the second electrode film 90b in the first direction X, and may form no capacitive coupling with the second electrode film 90b.

With reference to FIG. 20B (third layout example), similarly to the case of the first layout example, the pad capacitor structure 84 includes the plurality of capacitor structures 85. In this embodiment, the plurality of capacitor structures 85 include the plurality of first capacitor structures 85A extending in a stripe shape in the first direction X and the plurality of second capacitor structures 85B extending in the second direction Y. In this embodiment, the plurality of first capacitor structures 85A include the plurality of lead-out portions 85a.

The plurality of first capacitor structures 85A each have proximal end portions on one side (third side surface 5C side) in the longitudinal direction (first direction X) and distal end portions on the other side (fourth side surface 5D side) in the longitudinal direction (first direction X). The proximal end portions of the plurality of first capacitor structures 85A are boundary portions between the plurality of lead-out portions 85a and the pad electrode 95 (anode pad AP).

The plurality of second capacitor structures 85B are respectively arranged in regions on the distal end portion side and regions on the proximal end portion side of the plurality of first capacitor structures 85A in the first direction X. One second capacitor structure 85B extends in a band shape in the second direction Y and is connected to the distal end portions of the plurality of first capacitor structures 85A.

The other second capacitor structure 85B extends in a band shape in the second direction Y and is connected to the region on the proximal end portion side of the plurality of first capacitor structures 85A. That is, the plurality of capacitor structures 85 constitute one ladder-shaped capacitor structure 85 in plan view.

The pad capacitor structure 84 includes a plurality of first capacitor electrode films 90 as in the first layout example. In this embodiment, the plurality of first capacitor electrode films 90 include a plurality of first electrode films 90a connected to the plurality of first capacitor structures 85A and a plurality of second electrode films 90b connected to the plurality of second capacitor structures 85B.

The plurality of first electrode films 90a extend in a stripe shape in the first direction X in conformance to the layout of the plurality of first capacitor structures 85A. The plurality of second electrode films 90b extend in a band shape in the second direction Y in conformance to the layout of the plurality of second capacitor structures 85B, respectively, and are connected to the plurality of first electrode films 90a.

The plurality of second electrode films 90b define a plurality of space regions respectively extending in the first direction X with the plurality of first electrode films 90a. Therefore, the plurality of first capacitor electrode films 90 constitute one first capacitor electrode film 90 having a ladder shape in plan view.

The pad capacitor structure 84 includes a plurality of side wall dielectric films 91 as in the first layout example. The plurality of side wall dielectric films 91 cover side walls of the plurality of first electrode films 90a and the plurality of second electrode films 90b, respectively. The plurality of side wall dielectric films 91 on the plurality of second electrode film 90b side are connected to the plurality of side wall dielectric films 91 on the plurality of first electrode film 90a side at connection portions between the plurality of first electrode films 90a and the plurality of second electrode films 90b.

The pad capacitor structure 84 includes a plurality of second capacitor electrode films 92 as in the first layout example. The plurality of second capacitor electrode films 92 are aligned in a stripe shape extending along the first direction X as in the first layout example. In this embodiment, the plurality of second capacitor electrode films 92 are alternately aligned in the second direction Y with the plurality of first electrode films 90a.

The plurality of second capacitor electrode films 92 include a plurality of inner second capacitor electrode films 92 and a plurality of outer second capacitor electrode films 92. The plurality of inner second capacitor electrode films 92 are arranged in a plurality of space regions defined by the plurality of first electrode films 90a and the plurality of second electrode films 90b, respectively.

The plurality of inner second capacitor electrode films 92 face the plurality of first electrode films 90a in the second direction Y, and have portions that form a capacitive coupling with the plurality of first electrode films 90a through the plurality of side wall dielectric films 91. The plurality of inner second capacitor electrode films 92 face the plurality of second electrode films 90b in the first direction X, and have portions that form a capacitive coupling with the plurality of second electrode films 90b through the plurality of side wall dielectric films 91.

The plurality of outer second capacitor electrode films 92 are arranged on both sides of the plurality of first capacitor electrode films 90 in the second direction Y, respectively. The plurality of outer second capacitor electrode films 92 face the first electrode films 90a in the second direction Y, respectively, and have portions that form a capacitive coupling with the first electrode films 90a through the side wall dielectric films 91, respectively.

The plurality of outer second capacitor electrode films 92 may face the second electrode film 90b in the second direction Y, respectively, and may have portions that form a capacitive coupling with the second electrode film 90b through the side wall dielectric films 91, respectively. The plurality of outer second capacitor electrode films 92 may be formed at intervals from the plurality of second electrode films 90b in the first direction X, and may form no capacitive coupling with the plurality of second electrode films 90b.

With reference to FIG. 20C (fourth layout example), similarly to the case of the first layout example, the pad capacitor structure 84 includes the plurality of capacitor structures 85. In this embodiment, the plurality of capacitor structures 85 include the plurality of first capacitor structures 85A extending in a stripe shape in the first direction X and the plurality of second capacitor structures 85B extending in the second direction Y. In this embodiment, the plurality of first capacitor structures 85A include the plurality of lead-out portions 85a.

The plurality of first capacitor structures 85A each have proximal end portions on one side (third side surface 5C side) in the longitudinal direction (first direction X) and distal end portions on the other side (fourth side surface 5D side) in the longitudinal direction (first direction X). The proximal end portions of the plurality of first capacitor structures 85A are boundary portions between the plurality of lead-out portions 85a and the pad electrode 95 (anode pad AP).

The plurality of second capacitor structures 85B are respectively arranged in regions on the distal end portion side and regions on the proximal end portion side of the plurality of first capacitor structures 85A in the first direction X. The one plurality of second capacitor structures 85B are formed at an interval in the second direction Y, and are respectively connected to the distal end portions of the plurality of (in this embodiment, two) first capacitor structures 85A adjacent to each other in the second direction Y.

The other plurality of second capacitor structures 85B are formed at an interval in the second direction Y to oppose the one plurality of second capacitor structures 85B in the first direction X in a one-to-one correspondence, and are respectively connected to the regions on the proximal end portion side of the plurality of (in this embodiment, two) first capacitor structures 85A adjacent to each other in the second direction Y. That is, the plurality of capacitor structures 85 constitute a plurality of annular (square annular) capacitor structures 85 extending in the first direction X in plan view.

The pad capacitor structure 84 includes a plurality of first capacitor electrode films 90 as in the first layout example. In this embodiment, the plurality of first capacitor electrode films 90 include a plurality of first electrode films 90a connected to the plurality of first capacitor structures 85A and a plurality of second electrode films 90b connected to the plurality of second capacitor structures 85B.

The plurality of first electrode films 90a extend in a stripe shape in the first direction X in conformance to the layout of the plurality of first capacitor structures 85A. The plurality of second electrode films 90b extend in a band shape in the second direction Y in conformance to the layout of the plurality of second capacitor structures 85B, respectively, and are connected to the plurality of first electrode films 90a.

The plurality of second electrode films 90b define a plurality of space regions respectively extending in the first direction X with the plurality of first electrode films 90a. Therefore, the plurality of first capacitor electrode films 90 constitute a plurality of first capacitor electrode films 90 each having an annular shape (rectangular annular shape) respectively extending in the first direction X in plan view.

The pad capacitor structure 84 includes a plurality of side wall dielectric films 91 as in the first layout example. The plurality of side wall dielectric films 91 cover side walls of the plurality of first electrode films 90a and the plurality of second electrode films 90b, respectively. The plurality of side wall dielectric films 91 on the plurality of second electrode film 90b side are connected to the plurality of side wall dielectric films 91 on the plurality of first electrode film 90a side at connection portions between the plurality of first electrode films 90a and the plurality of second electrode films 90b.

The pad capacitor structure 84 includes a plurality of second capacitor electrode films 92 as in the first layout example. The plurality of second capacitor electrode films 92 are aligned in a stripe shape extending along the first direction X as in the first layout example. In this embodiment, the plurality of second capacitor electrode films 92 are alternately aligned in the second direction Y with the plurality of first electrode films 90a.

The plurality of second capacitor electrode films 92 include a plurality of inner second capacitor electrode films 92 and a plurality of outer second capacitor electrode films 92. The plurality of inner second capacitor electrode films 92 are arranged in space regions defined by the plurality of first electrode films 90a and the plurality of second electrode films 90b, respectively.

The plurality of inner second capacitor electrode films 92 face the plurality of first electrode films 90a in the second direction Y, and have portions that form a capacitive coupling with the plurality of first electrode films 90a through the plurality of side wall dielectric films 91. The plurality of inner second capacitor electrode films 92 face the plurality of second electrode films 90b in the first direction X, and have portions that form a capacitive coupling with the plurality of second electrode films 90b through the plurality of side wall dielectric films 91.

The plurality of outer second capacitor electrode films 92 are arranged in regions between a plurality of space regions adjacent to one another in the second direction Y, respectively. The plurality of outer second capacitor electrode films 92 face the plurality of first electrode films 90a in the second direction Y, respectively, and have portions that form a capacitive coupling with the plurality of first electrode films 90a through the plurality of side wall dielectric films 91, respectively.

The plurality of outer second capacitor electrode films 92 may face the plurality of second electrode films 90b in the second direction Y, respectively, and may have portions that form a capacitive coupling with the plurality of second electrode films 90b through the plurality of side wall dielectric films 91, respectively. The plurality of outer second capacitor electrode films 92 may be formed at intervals from the plurality of second electrode films 90b in the first direction X, and may form no capacitive coupling with the plurality of second electrode films 90b.

The second capacitor electrode films 92 may include a plurality of outer second capacitor electrode films 92 arranged on both sides of the plurality of first capacitor electrode films 90 in the second direction Y. The plurality of outer second capacitor electrode films 92 may face the first electrode films 90a in the second direction Y, respectively, and may have portions that form a capacitive coupling with the first electrode films 90a through the side wall dielectric films 91, respectively.

The plurality of outer second capacitor electrode films 92 may face the second electrode film 90b in the second direction Y, respectively, and may have portions that form a capacitive coupling with the second electrode film 90b through the side wall dielectric films 91, respectively. The plurality of outer second capacitor electrode films 92 may be formed at intervals from the plurality of second electrode films 90b in the first direction X, and may form no capacitive coupling with the plurality of second electrode films 90b.

With reference to FIG. 20D (fifth layout example), similarly to the case of the first layout example, the pad capacitor structure 84 includes the plurality of capacitor structures 85. In this embodiment, the plurality of capacitor structures 85 include the plurality of first capacitor structures 85A extending in a stripe shape in the first direction X and the plurality of second capacitor structures 85B extending in the second direction Y. In this embodiment, the plurality of first capacitor structures 85A include the plurality of lead-out portions 85a.

The plurality of first capacitor structures 85A each have proximal end portions on one side (third side surface 5C side) in the longitudinal direction (first direction X) and distal end portions on the other side (fourth side surface 5D side) in the longitudinal direction (first direction X). The proximal end portions of the plurality of first capacitor structures 85A are boundary portions between the plurality of lead-out portions 85a and the pad electrode 95 (anode pad AP).

The plurality of second capacitor structures 85B are respectively arranged in regions on the distal end portion side and regions on the proximal end portion side of the plurality of first capacitor structures 85A in the first direction X. The one plurality of second capacitor structures 85B are formed at an interval in the second direction Y, and are respectively connected to the distal end portions of the plurality of (in this embodiment, two) first capacitor structures 85A adjacent to each other in the second direction Y.

The other plurality of second capacitor structures 85B are arranged to be shifted in the second direction Y with respect to the one plurality of second capacitor structures 85B to oppose the one two second capacitor structures 85B in the first direction X. The other plurality of second capacitor structures 85B are formed at an interval in the second direction Y, and are respectively connected to the regions on the proximal end portion side of the plurality of (in this embodiment, two) first capacitor structures 85A adjacent to each other in the second direction Y.

That is, the plurality of capacitor structures 85 constitute one zigzag-shaped capacitor structure 85 having portions extending in the first direction X and portions extending in the second direction Y in plan view.

One end portion of the zigzag-shaped capacitor structure 85 is electrically connected to the one or a plurality of emitter structures 30 via the lead-out portion 85a. The other end portion of the zigzag-shaped capacitor structure 85 is electrically connected to the one or a plurality of emitter structures 30 via the lead-out portion 85a.

The pad capacitor structure 84 includes a plurality of first capacitor electrode films 90 as in the first layout example. In this embodiment, the plurality of first capacitor electrode films 90 include a plurality of first electrode films 90a connected to the plurality of first capacitor structures 85A and a plurality of second electrode films 90b connected to the plurality of second capacitor structures 85B.

The plurality of first electrode films 90a extend in a stripe shape in the first direction X in conformance to the layout of the plurality of first capacitor structures 85A. The plurality of second electrode films 90b extend in a band shape in the second direction Y in conformance to the layout of the plurality of second capacitor structures 85B, respectively, and are connected to the plurality of first electrode films 90a.

Therefore, the plurality of first capacitor electrode films 90 constitute one first capacitor electrode film 90 having a zigzag shape and having a portion extending in the first direction X and a portion extending in the second direction Y in plan view.

The pad capacitor structure 84 includes a plurality of side wall dielectric films 91 as in the first layout example. The plurality of side wall dielectric films 91 cover side walls of the plurality of first electrode films 90a and the plurality of second electrode films 90b, respectively. The plurality of side wall dielectric films 91 on the plurality of second electrode film 90b side are connected to the plurality of side wall dielectric films 91 on the plurality of first electrode film 90a side at connection portions between the plurality of first electrode films 90a and the plurality of second electrode films 90b.

The pad capacitor structure 84 includes a plurality of second capacitor electrode films 92 as in the first layout example. The plurality of second capacitor electrode films 92 are aligned in a stripe shape extending along the first direction X as in the first layout example. In this embodiment, the plurality of second capacitor electrode films 92 are alternately aligned in the second direction Y with the plurality of first electrode films 90a.

The plurality of second capacitor electrode films 92 include a first plurality of second capacitor electrode films 92 and a second plurality of second capacitor electrode films 92. The first plurality of second capacitor electrode films 92 are arranged in regions defined by the plurality of first electrode films 90a and one of the second electrode films 90b, respectively.

The first plurality of second capacitor electrode films 92 face the plurality of first electrode films 90a in the second direction Y, and have portions that form a capacitive coupling with the plurality of first electrode films 90a through the plurality of side wall dielectric films 91. The first plurality of second capacitor electrode films 92 face one of the second electrode films 90b in the first direction X, and have portions that form a capacitive coupling with the one of the second electrode films 90b through the side wall dielectric films 91.

The second plurality of second capacitor electrode films 92 are arranged in regions defined by the plurality of first electrode films 90a and the other second electrode film 90b, respectively. The second plurality of second capacitor electrode films 92 face the plurality of first electrode films 90a in the second direction Y, and have portions that form a capacitive coupling with the plurality of first electrode films 90a through the plurality of side wall dielectric films 91.

The second plurality of second capacitor electrode films 92 face the other second electrode film 90b in the first direction X, and have portions that form a capacitive coupling with the other second electrode film 90b through the side wall dielectric films 91.

The second capacitor electrode films 92 may include a plurality of outer second capacitor electrode films 92 arranged on both sides of the plurality of first capacitor electrode films 90 in the second direction Y. The plurality of outer second capacitor electrode films 92 may face the first electrode films 90a in the second direction Y, respectively, and may have portions that form a capacitive coupling with the first electrode films 90a through the side wall dielectric films 91, respectively.

The plurality of outer second capacitor electrode films 92 may face the second electrode film 90b in the second direction Y, respectively, and may have portions that form a capacitive coupling with the second electrode film 90b through the side wall dielectric films 91, respectively. The plurality of outer second capacitor electrode films 92 may be formed at intervals from the plurality of second electrode films 90b in the first direction X, and may form no capacitive coupling with the plurality of second electrode films 90b.

With reference to FIG. 20E (sixth layout example), similarly to the case of the first layout example, the pad capacitor structure 84 includes the plurality of capacitor structures 85. The plurality of capacitor structures 85 have a layout in which the extension direction of the pad capacitor structure 84 according to the first layout example is changed from the first direction X to the second direction Y.

That is, the plurality of capacitor structures 85 extend in a stripe shape in the second direction Y. In this embodiment, the extension direction of the plurality of capacitor structures 85 is a direction intersecting (specifically, orthogonal to) the extension direction of the plurality of gate structures 20 (the plurality of emitter structures 30).

In this embodiment, the lead-out portions 85a of the plurality of capacitor structures 85 extend in the second direction Y and are led out from the anode pad region 11A to one or the plurality of active regions 6. The plurality of lead-out portions 85a are respectively connected to the plurality of emitter structures 30 in one or the plurality of active regions 6.

The plurality of lead-out portions 85a may be connected to the plurality of emitter connection structures 35 in the one or the plurality of active regions 6. The plurality of lead-out portions 85a may have portions extending in the first direction X in a region outside the anode pad region 11A.

The pad capacitor structure 84 includes a plurality of first capacitor electrode films 90 as in the first layout example. In this embodiment, the plurality of first capacitor electrode films 90 extend in a stripe shape in the second direction Y in conformance to the layout of the plurality of capacitor structures 85.

The pad capacitor structure 84 includes a plurality of second capacitor electrode films 92 as in the first layout example. The plurality of second capacitor electrode films 92 are aligned in a stripe shape extending along the second direction Y in conformance to the layout of the plurality of first capacitor electrode films 90. In this embodiment, the plurality of second capacitor electrode films 92 are alternately aligned in the first direction X with the plurality of first capacitor electrode films 90.

The plurality of second capacitor electrode films 92 face one or a plurality of first capacitor electrode films 90 in the first direction X, and form a capacitive coupling with the one or a plurality of first capacitor electrode films 90 through one or a plurality of side wall dielectric films 91.

With reference to FIG. 20F (seventh layout example), similarly to the case of the first layout example, the pad capacitor structure 84 includes the plurality of capacitor structures 85. In this embodiment, similarly to the case of the sixth layout example, the plurality of capacitor structures 85 include a plurality of first capacitor structures 85A extending in a stripe shape in the second direction Y and one second capacitor structure 85B extending in the first direction X. In this embodiment, the plurality of first capacitor structures 85A include the plurality of lead-out portions 85a.

The plurality of first capacitor structures 85A each have distal end portions on one side (first side surface 5A side) in the longitudinal direction (second direction Y) and proximal end portions on the other side (second side surface 5B side) in the longitudinal direction (second direction Y). The proximal end portions of the plurality of first capacitor structures 85A are boundary portions between the plurality of lead-out portions 85a and the pad electrode 95 (anode pad AP).

The second capacitor structure 85B extends in a band shape in the first direction X and is connected to the distal end portions of the plurality of first capacitor structures 85A. That is, the plurality of capacitor structures 85 constitute a single comb teeth-shaped capacitor structure 85 in plan view. As a matter of course, the second capacitor structure 85B may be connected to regions on the proximal end portion side of the plurality of second capacitor structures 85B.

The pad capacitor structure 84 includes a plurality of first capacitor electrode films 90 as in the first layout example. In this embodiment, the plurality of first capacitor electrode films 90 include a plurality of first electrode films 90a connected to the plurality of first capacitor structures 85A and a second electrode film 90b connected to the second capacitor structure 85B.

The plurality of first electrode films 90a extend in a stripe shape in the second direction Y in conformance to the layout of the plurality of first capacitor structures 85A. The second electrode film 90b extends in a band shape in the first direction X in conformance to the layout of the second capacitor structure 85B and is connected to the plurality of first electrode films 90a. Therefore, the plurality of first capacitor electrode films 90 constitute one first capacitor electrode film 90 having a comb teeth shape in plan view.

The pad capacitor structure 84 includes a plurality of side wall dielectric films 91 as in the first layout example. The plurality of side wall dielectric films 91 cover side walls of the plurality of first electrode films 90a and the second electrode film 90b, respectively. The side wall dielectric film 91 on the second electrode film 90b side is connected to the plurality of side wall dielectric films 91 on the plurality of first electrode film 90a side at connection portions between the plurality of first electrode films 90a and the second electrode film 90b.

The pad capacitor structure 84 includes a plurality of second capacitor electrode films 92 as in the first layout example. In this embodiment, the plurality of second capacitor electrode films 92 are aligned in a stripe shape extending along the second direction Y. In this embodiment, the plurality of second capacitor electrode films 92 are alternately aligned in the first direction X with the plurality of first electrode films 90a.

The plurality of second capacitor electrode films 92 include a plurality of inner second capacitor electrode films 92 and a plurality of outer second capacitor electrode films 92. The plurality of inner second capacitor electrode films 92 are arranged in regions defined by the plurality of first electrode films 90a and the second electrode film 90b, respectively.

The plurality of inner second capacitor electrode films 92 face the plurality of first electrode films 90a in the first direction X, and have portions that form a capacitive coupling with the plurality of first electrode films 90a through the plurality of side wall dielectric films 91. The plurality of inner second capacitor electrode films 92 face the second electrode film 90b in the second direction Y, and have portions that form a capacitive coupling with the second electrode film 90b through the side wall dielectric films 91.

The plurality of outer second capacitor electrode films 92 are arranged on both sides of the plurality of first capacitor electrode films 90 in the first direction X, respectively. The plurality of outer second capacitor electrode films 92 face the first electrode films 90a in the first direction X, respectively, and have portions that form a capacitive coupling with the first electrode films 90a through the side wall dielectric films 91, respectively.

The plurality of outer second capacitor electrode films 92 may face the second electrode film 90b in the first direction X, respectively, and may have portions that form a capacitive coupling with the second electrode film 90b through the side wall dielectric films 91, respectively. The plurality of outer second capacitor electrode films 92 may be formed at an interval from the second electrode film 90b in the second direction Y, and may form no capacitive coupling with the second electrode film 90b.

With reference to FIG. 20G (eighth layout example), similarly to the case of the first layout example, the pad capacitor structure 84 includes the plurality of capacitor structures 85. In this embodiment, similarly to the case of the sixth layout example, the plurality of capacitor structures 85 include the plurality of first capacitor structures 85A extending in a stripe shape in the second direction Y and the plurality of second capacitor structures 85B extending in the first direction X. In this embodiment, the plurality of first capacitor structures 85A include the plurality of lead-out portions 85a.

The plurality of first capacitor structures 85A each have distal end portions on one side (first side surface 5A side) in the longitudinal direction (second direction Y) and proximal end portions on the other side (second side surface 5B side) in the longitudinal direction (second direction Y). The proximal end portions of the plurality of first capacitor structures 85A are boundary portions between the plurality of lead-out portions 85a and the pad electrode 95 (anode pad AP).

The plurality of second capacitor structures 85B are respectively arranged in regions on the distal end portion side and regions on the proximal end portion side of the plurality of first capacitor structures 85A in the second direction Y. One second capacitor structure 85B extends in a band shape in the second direction Y and is connected to the distal end portions of the plurality of first capacitor structures 85A.

The other second capacitor structure 85B extends in a band shape in the second direction Y and is connected to the region on the proximal end portion side of the plurality of first capacitor structures 85A. That is, the plurality of capacitor structures 85 constitute one ladder-shaped capacitor structure 85 in plan view.

The pad capacitor structure 84 includes a plurality of first capacitor electrode films 90 as in the first layout example. In this embodiment, the plurality of first capacitor electrode films 90 include a plurality of first electrode films 90a connected to the plurality of first capacitor structures 85A and a plurality of second electrode films 90b connected to the plurality of second capacitor structures 85B.

The plurality of first electrode films 90a extend in a stripe shape in the second direction Y in conformance to the layout of the plurality of first capacitor structures 85A. The plurality of second electrode films 90b extend in a band shape in the first direction X in conformance to the layout of the plurality of second capacitor structures 85B, respectively, and are connected to the plurality of first electrode films 90a.

The plurality of second electrode films 90b define a plurality of space regions respectively extending in the first direction X with the plurality of first electrode films 90a. Therefore, the plurality of first capacitor electrode films 90 constitute one first capacitor electrode film 90 having a ladder shape in plan view.

The pad capacitor structure 84 includes a plurality of side wall dielectric films 91 as in the first layout example. The plurality of side wall dielectric films 91 cover side walls of the plurality of first electrode films 90a and the plurality of second electrode films 90b, respectively. The plurality of side wall dielectric films 91 on the plurality of second electrode film 90b side are connected to the plurality of side wall dielectric films 91 on the plurality of first electrode film 90a side at connection portions between the plurality of first electrode films 90a and the plurality of second electrode films 90b.

The pad capacitor structure 84 includes a plurality of second capacitor electrode films 92 as in the first layout example. In this embodiment, the plurality of second capacitor electrode films 92 are aligned in a stripe shape extending along the second direction Y. In this embodiment, the plurality of second capacitor electrode films 92 are alternately aligned in the first direction X with the plurality of first electrode films 90a.

The plurality of second capacitor electrode films 92 include a plurality of inner second capacitor electrode films 92 and a plurality of outer second capacitor electrode films 92. The plurality of inner second capacitor electrode films 92 are arranged in a plurality of space regions defined by the plurality of first electrode films 90a and the plurality of second electrode films 90b, respectively.

The plurality of inner second capacitor electrode films 92 face the plurality of first electrode films 90a in the first direction X, and have portions that form a capacitive coupling with the plurality of first electrode films 90a through the plurality of side wall dielectric films 91. The plurality of inner second capacitor electrode films 92 face the plurality of second electrode films 90b in the second direction Y, and have portions that form a capacitive coupling with the plurality of second electrode films 90b through the plurality of side wall dielectric films 91.

The plurality of outer second capacitor electrode films 92 are arranged on both sides of the plurality of first capacitor electrode films 90 in the first direction X, respectively. The plurality of outer second capacitor electrode films 92 face the first electrode films 90a in the first direction X, respectively, and have portions that form a capacitive coupling with the first electrode films 90a through the side wall dielectric films 91, respectively.

The plurality of outer second capacitor electrode films 92 may face the second electrode film 90b in the first direction X, respectively, and may have portions that form a capacitive coupling with the second electrode film 90b through the side wall dielectric films 91, respectively. The plurality of outer second capacitor electrode films 92 may be formed at intervals from the plurality of second electrode films 90b in the second direction Y, and may form no capacitive coupling with the plurality of second electrode films 90b.

With reference to FIG. 20H (ninth layout example), similarly to the case of the first layout example, the pad capacitor structure 84 includes the plurality of capacitor structures 85. In this embodiment, similarly to the case of the sixth layout example, the plurality of capacitor structures 85 include the plurality of first capacitor structures 85A extending in a stripe shape in the second direction Y and the plurality of second capacitor structures 85B extending in the first direction X. In this embodiment, the plurality of first capacitor structures 85A include the plurality of lead-out portions 85a.

The plurality of first capacitor structures 85A each have distal end portions on one side (first side surface 5A side) in the longitudinal direction (second direction Y) and proximal end portions on the other side (second side surface 5B side) in the longitudinal direction (second direction Y). The proximal end portions of the plurality of first capacitor structures 85A are boundary portions between the plurality of lead-out portions 85a and the pad electrode 95 (anode pad AP).

The plurality of second capacitor structures 85B are respectively arranged in regions on the distal end portion side and regions on the proximal end portion side of the plurality of first capacitor structures 85A in the second direction Y. The one plurality of second capacitor structures 85B are formed at an interval in the first direction X, and are respectively connected to the distal end portions of the plurality of (in this embodiment, two) first capacitor structures 85A adjacent to each other in the first direction X.

The other plurality of second capacitor structures 85B are formed at an interval in the first direction X to oppose the one plurality of first capacitor structures 85A in the second direction Y in a one-to-one correspondence, and are respectively connected to the regions on the proximal end portion side of the plurality of (in this embodiment, two) first capacitor structures 85A adjacent to each other in the first direction X. That is, the plurality of capacitor structures 85 constitute a plurality of annular (square annular) capacitor structures 85 extending in the second direction Y in plan view.

The pad capacitor structure 84 includes a plurality of first capacitor electrode films 90 as in the first layout example. In this embodiment, the plurality of first capacitor electrode films 90 include a plurality of first electrode films 90a connected to the plurality of first capacitor structures 85A and a plurality of second electrode films 90b connected to the plurality of second capacitor structures 85B.

The plurality of first electrode films 90a extend in a stripe shape in the second direction Y in conformance to the layout of the plurality of first capacitor structures 85A. The plurality of second electrode films 90b extend in a band shape in the first direction X in conformance to the layout of the plurality of second capacitor structures 85B, and are connected to the plurality of first electrode films 90a.

The plurality of second electrode films 90b define a plurality of space regions respectively extending in the second direction Y with the plurality of first electrode films 90a. Therefore, the plurality of first capacitor electrode films 90 constitute a plurality of first capacitor electrode films 90 having an annular shape (rectangular annular shape) extending in the second direction Y in plan view.

The pad capacitor structure 84 includes a plurality of side wall dielectric films 91 as in the first layout example. The plurality of side wall dielectric films 91 cover side walls of the plurality of first electrode films 90a and the plurality of second electrode films 90b, respectively. The plurality of side wall dielectric films 91 on the plurality of second electrode film 90b side are connected to the plurality of side wall dielectric films 91 on the plurality of first electrode film 90a side at connection portions between the plurality of first electrode films 90a and the plurality of second electrode films 90b.

The pad capacitor structure 84 includes a plurality of second capacitor electrode films 92 as in the first layout example. In this embodiment, the plurality of second capacitor electrode films 92 are aligned in a stripe shape extending along the second direction Y. In this embodiment, the plurality of second capacitor electrode films 92 are alternately aligned in the first direction X with the plurality of first electrode films 90a.

The plurality of second capacitor electrode films 92 include a plurality of inner second capacitor electrode films 92 and a plurality of outer second capacitor electrode films 92. The plurality of inner second capacitor electrode films 92 are arranged in a plurality of space regions defined by the plurality of first electrode films 90a and the plurality of second electrode films 90b, respectively.

The plurality of inner second capacitor electrode films 92 face the plurality of first electrode films 90a in the first direction X, and have portions that form a capacitive coupling with the plurality of first electrode films 90a through the plurality of side wall dielectric films 91. The plurality of inner second capacitor electrode films 92 face the plurality of second electrode films 90b in the second direction Y, and have portions that form a capacitive coupling with the plurality of second electrode films 90b through the plurality of side wall dielectric films 91.

The plurality of outer second capacitor electrode films 92 are arranged in regions between a plurality of space regions adjacent to one another in the first direction X, respectively. The plurality of outer second capacitor electrode films 92 face the plurality of first electrode films 90a in the first direction X, respectively, and have portions that form a capacitive coupling with the plurality of first electrode films 90a through the plurality of side wall dielectric films 91, respectively. The second capacitor electrode films 92 may include a plurality of second capacitor electrode films 92 arranged on both sides of the plurality of first capacitor electrode films 90 in the first direction X.

The plurality of outer second capacitor electrode films 92 may face the plurality of second electrode films 90b in the first direction X, respectively, and may have portions that form a capacitive coupling with the plurality of second electrode films 90b through the plurality of side wall dielectric films 91, respectively. The plurality of outer second capacitor electrode films 92 may be formed at intervals from the plurality of second electrode films 90b in the second direction Y, and may form no capacitive coupling with the plurality of second electrode films 90b.

The second capacitor electrode films 92 may include a plurality of outer second capacitor electrode films 92 arranged on both sides of the plurality of first capacitor electrode films 90 in the first direction X. The plurality of outer second capacitor electrode films 92 may face the first electrode films 90a in the first direction X, respectively, and may have portions that form a capacitive coupling with the first electrode films 90a through the side wall dielectric films 91, respectively.

The plurality of outer second capacitor electrode films 92 may face the second electrode film 90b in the first direction X, respectively, and may have portions that form a capacitive coupling with the second electrode film 90b through the side wall dielectric films 91, respectively. The plurality of outer second capacitor electrode films 92 may be formed at intervals from the plurality of second electrode films 90b in the second direction Y, and may form no capacitive coupling with the plurality of second electrode films 90b.

With reference to FIG. 20I (tenth layout example), similarly to the case of the first layout example, the pad capacitor structure 84 includes the plurality of capacitor structures 85. In this embodiment, similarly to the case of the sixth layout example, the plurality of capacitor structures 85 include the plurality of first capacitor structures 85A extending in a stripe shape in the second direction Y and the plurality of second capacitor structures 85B extending in the first direction X. In this embodiment, the plurality of first capacitor structures 85A include the plurality of lead-out portions 85a.

The plurality of first capacitor structures 85A each have distal end portions on one side (first side surface 5A side) in the longitudinal direction (second direction Y) and proximal end portions on the other side (second side surface 5B side) in the longitudinal direction (second direction Y). The proximal end portions of the plurality of first capacitor structures 85A are boundary portions between the plurality of lead-out portions 85a and the pad electrode 95 (anode pad AP).

The plurality of second capacitor structures 85B are respectively arranged in regions on the distal end portion side and regions on the proximal end portion side of the plurality of first capacitor structures 85A in the second direction Y. The one plurality of second capacitor structures 85B are formed at an interval in the first direction X, and are respectively connected to the distal end portions of the plurality of (in this embodiment, two) first capacitor structures 85A adjacent to each other in the first direction X.

The other plurality of second capacitor structures 85B are arranged to be shifted in the first direction X with respect to the plurality of second capacitor structures 85B to oppose the one two second capacitor structures 85B in the second direction Y. The other plurality of second capacitor structures 85B are formed at an interval in the first direction X, and are respectively connected to the regions on the proximal end portion side of the plurality of (in this embodiment, two) first capacitor structures 85A adjacent to each other in the first direction X.

That is, the plurality of capacitor structures 85 constitute one zigzag-shaped capacitor structure 85 having portions extending in the first direction X and portions extending in the second direction Y in plan view. One end portion of the zigzag-shaped capacitor structure 85 is electrically connected to the one or a plurality of emitter structures 30 via the lead-out portion 85a. The other end portion of the zigzag-shaped capacitor structure 85 is electrically connected to the one or a plurality of emitter structures 30 via the lead-out portion 85a.

The pad capacitor structure 84 includes a plurality of first capacitor electrode films 90 as in the first layout example. In this embodiment, the plurality of first capacitor electrode films 90 include a plurality of first electrode films 90a connected to the plurality of first capacitor structures 85A and a plurality of second electrode films 90b connected to the plurality of second capacitor structures 85B.

The plurality of first electrode films 90a extend in a stripe shape in the second direction Y in conformance to the layout of the plurality of first capacitor structures 85A. The plurality of second electrode films 90b extend in a band shape in the first direction X in conformance to the layout of the plurality of second capacitor structures 85B, and are connected to the plurality of first electrode films 90a.

Therefore, the plurality of first capacitor electrode films 90 constitute one first capacitor electrode film 90 having a zigzag shape and having a portion extending in the first direction X and a portion extending in the second direction Y in plan view.

The pad capacitor structure 84 includes a plurality of side wall dielectric films 91 as in the first layout example. The plurality of side wall dielectric films 91 cover side walls of the plurality of first electrode films 90a and the plurality of second electrode films 90b, respectively. The plurality of side wall dielectric films 91 on the plurality of second electrode film 90b side are connected to the plurality of side wall dielectric films 91 on the plurality of first electrode film 90a side at connection portions between the plurality of first electrode films 90a and the plurality of second electrode films 90b.

The pad capacitor structure 84 includes a plurality of second capacitor electrode films 92 as in the first layout example. In this embodiment, the plurality of second capacitor electrode films 92 are aligned in a stripe shape extending along the second direction Y. In this embodiment, the plurality of second capacitor electrode films 92 are alternately aligned in the first direction X with the plurality of first electrode films 90a.

The plurality of second capacitor electrode films 92 include a first plurality of second capacitor electrode films 92 and a second plurality of second capacitor electrode films 92. The first plurality of second capacitor electrode films 92 are arranged in regions defined by the plurality of first electrode films 90a and one of the second electrode films 90b, respectively.

The first plurality of second capacitor electrode films 92 face the plurality of first electrode films 90a in the first direction X, and have portions that form a capacitive coupling with the plurality of first electrode films 90a through the plurality of side wall dielectric films 91. The first plurality of second capacitor electrode films 92 face one of the second electrode films 90b in the second direction Y, and have portions that form a capacitive coupling with the one of the second electrode films 90b through the side wall dielectric films 91.

The second plurality of second capacitor electrode films 92 are arranged in regions defined by the plurality of first electrode films 90a and the other second electrode film 90b, respectively. The second plurality of second capacitor electrode films 92 face the plurality of first electrode films 90a in the first direction X, and have portions that form a capacitive coupling with the plurality of first electrode films 90a through the plurality of side wall dielectric films 91.

The second plurality of second capacitor electrode films 92 face the other second electrode film 90b in the second direction Y, and have portions that form a capacitive coupling with the other second electrode film 90b through the side wall dielectric films 91.

The second capacitor electrode films 92 may include a plurality of outer second capacitor electrode films 92 arranged on both sides of the plurality of first capacitor electrode films 90 in the first direction X. The plurality of outer second capacitor electrode films 92 may face the first electrode films 90a in the first direction X, respectively, and may have portions that form a capacitive coupling with the first electrode films 90a through the side wall dielectric films 91, respectively.

The plurality of outer second capacitor electrode films 92 may face the second electrode film 90b in the first direction X, respectively, and may have portions that form a capacitive coupling with the second electrode film 90b through the side wall dielectric films 91, respectively. The plurality of outer second capacitor electrode films 92 may be formed at intervals from the plurality of second electrode films 90b in the second direction Y, and may form no capacitive coupling with the plurality of second electrode films 90b.

With reference to FIG. 20J (eleventh layout example), similarly to the case of the first layout example, the pad capacitor structure 84 includes the plurality of capacitor structures 85. The plurality of capacitor structures 85 include the plurality of first capacitor structures 85A extending in a stripe shape in the first direction X and the plurality of second capacitor structures 85B extending in the second direction Y.

In this embodiment, the plurality of first capacitor structures 85A include the plurality of lead-out portions 85a. As a matter of course, the plurality of second capacitor structures 85B may include the plurality of lead-out portions 85a.

The plurality of second capacitor structures 85B are respectively arranged in regions between the plurality of first capacitor structures 85A adjacent to each other in the second direction Y, and are arranged at an interval in the first direction X. The plurality of second capacitor structures 85B arranged on one side in the second direction Y with respect to one first capacitor structure 85A each oppose the plurality of second capacitor structures 85B arranged on the other side in the second direction Y with respect to the one first capacitor structure 85A in a one-to-one correspondence.

The plurality of second capacitor structures 85B form a plurality of intersections with the plurality of first capacitor structures 85A, and define a plurality of mesa portions arranged in a matrix in the first direction X and the second direction Y. That is, the plurality of capacitor structures 85 constitute one capacitor structure 85 extending in a lattice (mesh shape) along the first direction X and the second direction Y in plan view.

The pad capacitor structure 84 includes a plurality of first capacitor electrode films 90 as in the first layout example. In this embodiment, the plurality of first capacitor electrode films 90 include a plurality of first electrode films 90a connected to the plurality of first capacitor structures 85A and a plurality of second electrode films 90b connected to the plurality of second capacitor structures 85B.

The plurality of first electrode films 90a extend in a stripe shape in the second direction Y in conformance to the layout of the plurality of first capacitor structures 85A. The plurality of second electrode films 90b extend in a stripe shape in the second direction Y in conformance to the layout of the plurality of second capacitor structures 85B, and are connected to the plurality of first electrode films 90a.

The plurality of second electrode films 90b form a plurality of intersections with the plurality of first electrode films 90a, and define a plurality of space regions aligned in a matrix in the first direction X and the second direction Y. That is, the plurality of first capacitor electrode films 90 constitute one first capacitor electrode film 90 extending in a lattice (mesh pattern) along the first direction X and the second direction Y in plan view.

The pad capacitor structure 84 includes a plurality of side wall dielectric films 91 as in the first layout example. The plurality of side wall dielectric films 91 cover side walls of the plurality of first electrode films 90a and the plurality of second electrode films 90b, respectively. The plurality of side wall dielectric films 91 on the plurality of second electrode film 90b side are connected to the plurality of side wall dielectric films 91 on the plurality of first electrode film 90a side at connection portions between the plurality of first electrode films 90a and the plurality of second electrode films 90b.

The pad capacitor structure 84 includes a plurality of second capacitor electrode films 92 as in the first layout example. In this embodiment, the plurality of second capacitor electrode films 92 are arranged in a plurality of space regions defined by the plurality of first electrode films 90a and the plurality of second electrode films 90b, respectively. That is, the plurality of second capacitor electrode films 92 are aligned in a matrix at intervals in the first direction X and the second direction Y in plan view.

The plurality of second capacitor electrode films 92 face the plurality of first electrode films 90a in the second direction Y, and have portions that form a capacitive coupling with the plurality of first electrode films 90a through the plurality of side wall dielectric films 91, respectively. The plurality of second capacitor electrode films 92 face the plurality of second electrode films 90b in the first direction X, and have portions that form a capacitive coupling with the plurality of second electrode films 90b through the plurality of side wall dielectric films 91, respectively.

With reference to FIG. 20K (twelfth layout example), similarly to the case of the first layout example, the pad capacitor structure 84 includes the plurality of capacitor structures 85. The plurality of capacitor structures 85 include the plurality of first capacitor structures 85A extending in a stripe shape in the first direction X and the plurality of second capacitor structures 85B extending in the second direction Y.

In this embodiment, the plurality of first capacitor structures 85A include the plurality of lead-out portions 85a. As a matter of course, the plurality of second capacitor structures 85B may include the plurality of lead-out portions 85a.

The plurality of second capacitor structures 85B are respectively arranged in regions between the plurality of first capacitor structures 85A adjacent to each other in the second direction Y, and are arranged at an interval in the first direction X. The plurality of second capacitor structures 85B arranged on one side in the second direction Y with respect to one first capacitor structure 85A each oppose the regions between the plurality of second capacitor structures 85B arranged on the other side in the second direction Y with respect to one first capacitor structure 85A in a one-to-one correspondence.

The plurality of second capacitor structures 85B form a plurality of T-shaped paths with the plurality of first capacitor structures 85A, and define a plurality of mesa portions arranged in a staggered manner in the first direction X and the second direction Y. That is, the plurality of capacitor structures 85 constitute one capacitor structure 85 extending in a staggered manner (mesh pattern) along the first direction X and the second direction Y in plan view.

The pad capacitor structure 84 includes a plurality of first capacitor electrode films 90 as in the first layout example. In this embodiment, the plurality of first capacitor electrode films 90 include a plurality of first electrode films 90a connected to the plurality of first capacitor structures 85A and a plurality of second electrode films 90b connected to the plurality of second capacitor structures 85B.

The plurality of first electrode films 90a extend in a stripe shape in the second direction Y in conformance to the layout of the plurality of first capacitor structures 85A. The plurality of second electrode films 90b are arranged in regions between the plurality of first electrode films 90a adjacent to one another in the second direction Y in conformance to the layout of the plurality of second capacitor structures 85B, respectively, and are aligned at intervals in the first direction X.

The plurality of second electrode films 90b arranged on one side of one first electrode film 90a in the second direction Y face the regions between the plurality of second electrode films 90b arranged on the other side of one first electrode film 90a in the second direction Y in one-to-one correspondence.

The plurality of second electrode films 90b form a plurality of T-shaped paths with the plurality of first electrode films 90a, and define a plurality of space regions aligned in a staggered manner in the first direction X and the second direction Y. That is, the plurality of first capacitor electrode films 90 constitute one first capacitor electrode film 90 extending in a staggered manner (mesh pattern) along the first direction X and the second direction Y in plan view.

The pad capacitor structure 84 includes a plurality of side wall dielectric films 91 as in the first layout example. The plurality of side wall dielectric films 91 cover side walls of the plurality of first electrode films 90a and the plurality of second electrode films 90b, respectively. The plurality of side wall dielectric films 91 on the plurality of second electrode film 90b side are connected to the plurality of side wall dielectric films 91 on the plurality of first electrode film 90a side at connection portions between the plurality of first electrode films 90a and the plurality of second electrode films 90b.

The pad capacitor structure 84 includes a plurality of second capacitor electrode films 92 as in the first layout example. In this embodiment, the plurality of second capacitor electrode films 92 are arranged in a plurality of space regions defined by the plurality of first electrode films 90a and the plurality of second electrode films 90b, respectively. That is, the plurality of second capacitor electrode films 92 are aligned in a staggered manner at intervals in the first direction X and the second direction Y in plan view.

The plurality of second capacitor electrode films 92 face the plurality of first electrode films 90a in the second direction Y, and have portions that form a capacitive coupling with the plurality of first electrode films 90a through the plurality of side wall dielectric films 91, respectively. The plurality of second capacitor electrode films 92 face the plurality of second electrode films 90b in the first direction X, and have portions that form a capacitive coupling with the plurality of second electrode films 90b through the plurality of side wall dielectric films 91, respectively.

Referring to FIG. 20L (thirteenth layout example), the pad capacitor structure 84 includes a single capacitor structure 85 formed in a spiral shape in plan view. In this embodiment, the capacitor structure 85 is formed in a polygonal spiral shape (in this embodiment, rectangular spiral shape), and has a plurality of portions extending in the first direction X and a plurality of portions extending in the second direction Y. The capacitor structure 85 may be formed in a hexagonal spiral shape, a circular spiral shape, or the like.

The capacitor structure 85 defines a mesa portion extending in a spiral shape on the first main surface 3. An outer end portion of the capacitor structure 85 having a spiral shape is electrically connected to one or a plurality of emitter structures 30 via the lead-out portion 85a. The lead-out portion 85a may be led out in the first direction X or in the second direction Y.

In this embodiment, the pad capacitor structure 84 includes a single first capacitor electrode film 90 formed in a spiral shape in plan view. The first capacitor electrode film 90 extends in a spiral shape in conformance to the extension direction (spiral direction) of the capacitor structure 85, and is connected to the entire region of the capacitor structure 85.

The first capacitor electrode film 90 defines a space region extending in a spiral shape in conformance to the mesa portion on the first main surface 3 (main surface insulating film 48). The first capacitor electrode film 90 has a plurality of portions extending in the first direction X and a plurality of portions extending in the second direction Y.

In this embodiment, the pad capacitor structure 84 includes a single side wall dielectric film 91. The side wall dielectric film 91 covers a side wall of the first capacitor electrode film 90 along the spiral direction. That is, the side wall dielectric film 91 has a plurality of portions extending in the first direction X and a plurality of portions extending in the second direction Y.

In this embodiment, the pad capacitor structure 84 includes a single second capacitor electrode film 92 formed in a spiral shape in plan view. The second capacitor electrode film 92 is arranged in a space region defined by the first capacitor electrode film 90. The second capacitor electrode film 92 extends in a spiral shape along the space region. The second capacitor electrode film 92 has a plurality of portions extending in the first direction X and a plurality of portions extending in the second direction Y.

The second capacitor electrode film 92 faces the first capacitor electrode film 90 in the second direction Y in a portion extending in the first direction X, and has a portion that forms a capacitive coupling with the first capacitor electrode film 90 through the side wall dielectric film 91. The second capacitor electrode film 92 faces the first capacitor electrode film 90 in the first direction X in a portion extending in the second direction Y, and has a portion that forms a capacitive coupling with the first capacitor electrode film 90 through the side wall dielectric film 91.

Referring to FIG. 20M (fourteenth layout example), the pad capacitor structure 84 may include two or more layout regions 97. For example, the number of layout regions 97 may be 10 or less. In this embodiment, the pad capacitor structure 84 includes four layout regions 97, for example.

The plurality of layout regions 97 may be aligned in a line in the first direction X. The plurality of layout regions 97 may be aligned in a line in the second direction Y. The plurality of layout regions 97 may be aligned in a matrix along the first direction X and the second direction Y. The plurality of layout regions 97 may have substantially equal plane areas, or may have different plane areas.

The pad capacitor structure 84 includes pad capacitor portions 84a formed respectively in the plurality of layout regions 97 at intervals from one another. Each of the plurality of pad capacitor portions 84a includes a capacitor structure 85, a first capacitor electrode film 90, a main surface insulating film 48, a side wall dielectric film 91, a second capacitor electrode film 92, an interlayer film 57, a pad opening 93, and a pad via electrode 94.

The plurality of pad capacitor portions 84a may have the same layout or different layouts. Each of the plurality of pad capacitor portions 84a may have a layout similar to that of the pad capacitor structure 84 according to the first to thirteenth layout examples.

The first capacitor electrode films 90, the side wall dielectric films 91, the second capacitor electrode films 92, the pad openings 93, and the pad via electrodes 94 formed in the plurality of adjacent layout regions 97 may be connected to each other.

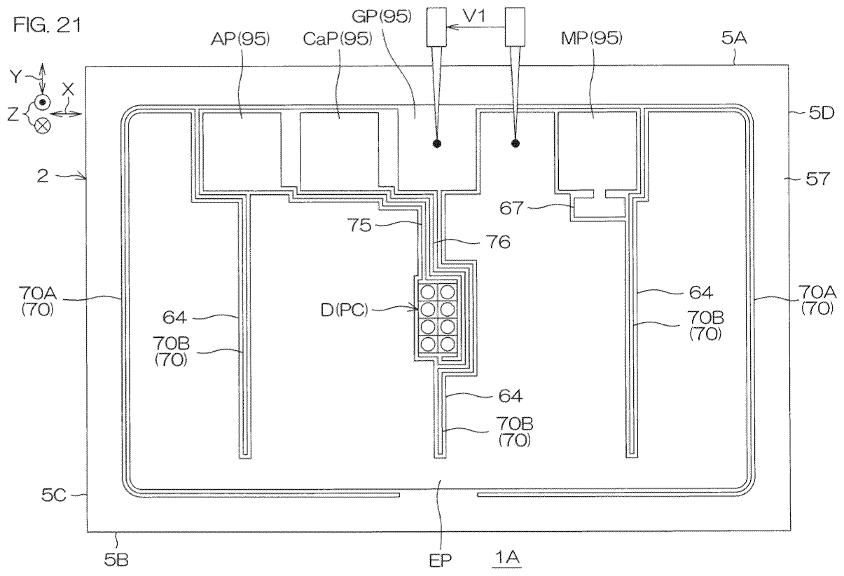

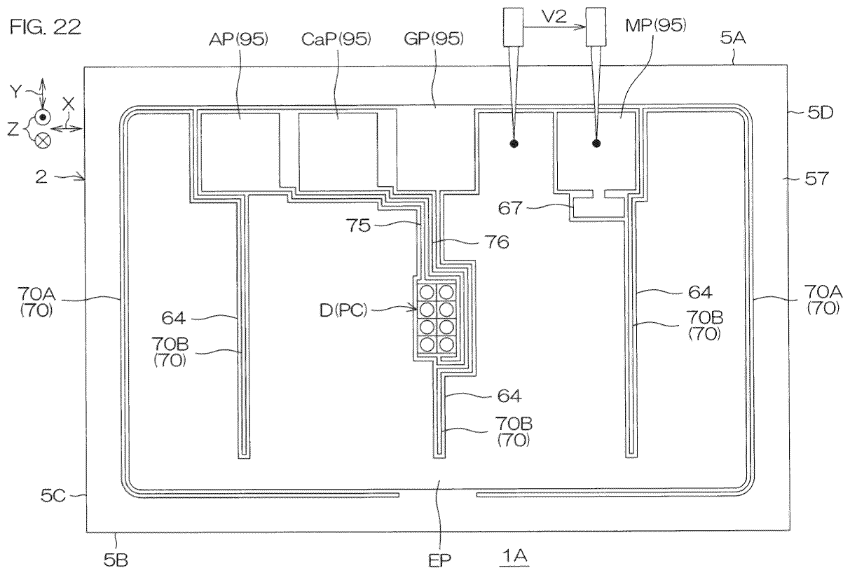

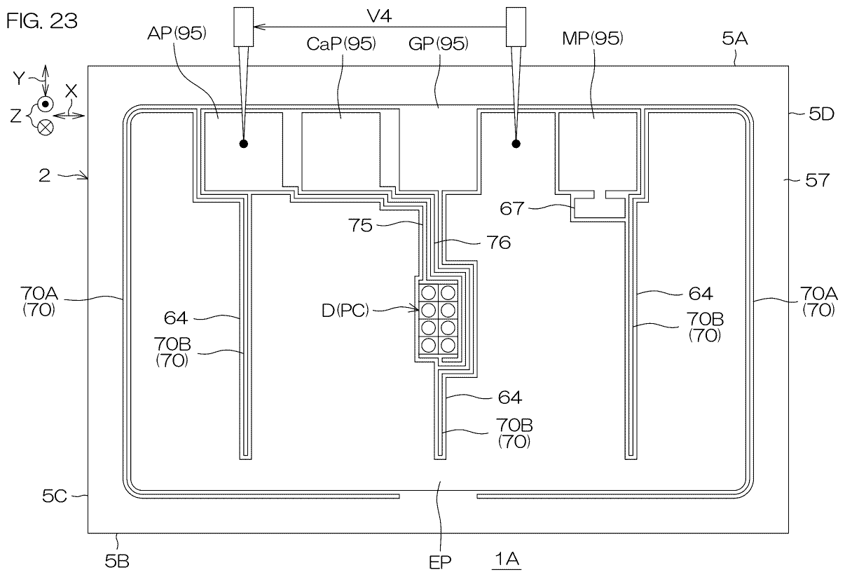

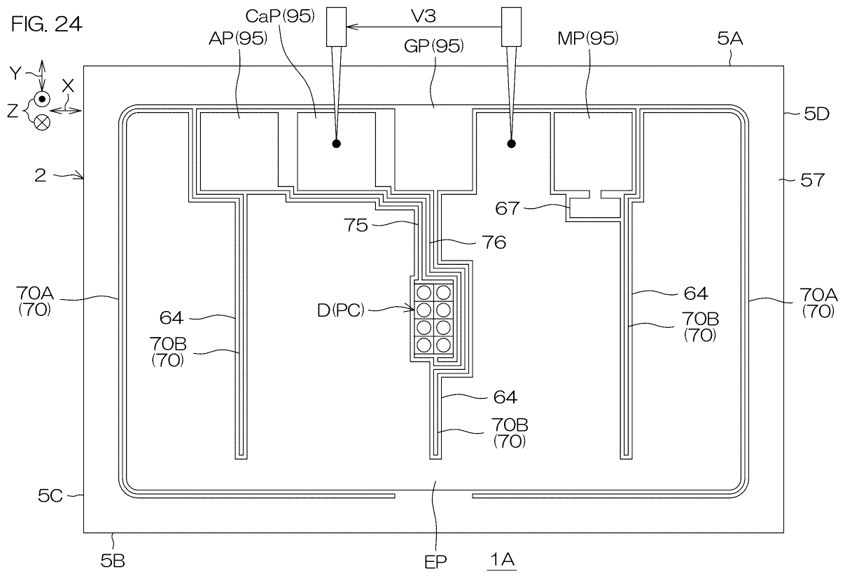

Hereinafter, an example of an electric test performed in the semiconductor device 1A will be described. FIG. 21 is a plan view for describing an electric test on the gate pad GP side. FIG. 22 is a plan view for describing an electric test on the monitor pad MP side. FIG. 23 is a plan view for describing an electric test on the anode pad AP side. FIG. 24 is a plan view for describing an electric test on the cathode pad CaP side.

The electrical test is an electro static discharge (ESD) tolerance measurement test of a human body model (HBM) with respect to the semiconductor device 1A (the plurality of pad electrodes 95). HBM is a model assuming that ESD occurs between the human body and the plurality of pad electrodes 95.

With reference to FIG. 21, in the test on the gate pad GP side, a predetermined first test voltage V1 is to be applied between the emitter pad EP and the gate pad GP. As the first test voltage V1, various values are adopted according to the specification of the semiconductor device 1A. The first test voltage V1 is typically 500 V or more and 8000 V or less.

When the first test voltage V1 is applied, a predetermined test current is generated at the emitter pad EP and the gate pad GP, and the ESD tolerance between the emitter pad EP and the gate pad GP is measured. Since a relatively high capacitance value is secured between the emitter pad EP and the gate pad GP by the plurality of gate structures 20, a relatively high ESD tolerance is achieved.

With reference to FIG. 22, in the test on the monitor pad MP side, a predetermined second test voltage V2 is to be applied between the emitter pad EP and the monitor pad MP. The second test voltage V2 may be applied between the gate pad GP and the monitor pad MP. As the second test voltage V2, various values are adopted according to the specification of the semiconductor device 1A. The second test voltage V2 is typically 500 V or more and 8000 V or less.

When the second test voltage V2 is applied, a predetermined test current is generated at the emitter pad EP and the monitor pad MP, and the ESD tolerance between the emitter pad EP and the monitor pad MP is measured.

In the monitor region 7, fewer gate structures 20 than the number of the gate structures 20 according to the plurality of the active regions 6 are formed. That is, the capacitance values associated with the plurality of gate structures 20 in the monitor region 7 are lower than the capacitance values associated with the plurality of gate structures 20 in the plurality of active regions 6. Therefore, the ESD tolerance between the emitter pad EP and the monitor pad MP will be less than the ESD tolerance between the emitter pad EP and the gate pad GP.

In this regard, in the semiconductor device 1A, the monitor capacitor structure CM (capacitor C) is formed in the monitor pad region 11M, and the capacitance value between the emitter pad EP and the monitor pad MP is complemented by the monitor capacitor structure CM. As a result, the ESD tolerance is enhanced as compared with the case where the monitor capacitor structure CM does not exist in the monitor pad region 11M.

With reference to FIG. 23, in the test on the anode pad AP side, a predetermined third test voltage V3 is to be applied between the emitter pad EP and the anode pad AP. The third test voltage V3 may be applied between the gate pad GP and the anode pad AP. As the third test voltage V3, various values are adopted according to the specification of the semiconductor device 1A. The third test voltage V3 is typically 500 V or more and 8000 V or less.

When the third test voltage V3 is applied, a predetermined test current is generated at the emitter pad EP and the anode pad AP, and the ESD tolerance between the emitter pad EP and the anode pad AP is measured.

The gate structure 20 is not electrically interposed in a region between the emitter pad EP and the anode pad AP. Therefore, the ESD tolerance between the emitter pad EP and the anode pad AP will be less than the ESD tolerance between the emitter pad EP and the gate pad GP.

In this regard, in the semiconductor device 1A, the anode capacitor structure CA (capacitor C) is formed in the anode pad region 11A, and the capacitance value between the emitter pad EP and the anode pad AP is complemented by the anode capacitor structure CA. As a result, the ESD tolerance is enhanced as compared with a case where the anode capacitor structure CA does not exist in the anode pad region 11A.

With reference to FIG. 24, in the test on the cathode pad CaP side, a predetermined fourth test voltage V4 is to be applied between the emitter pad EP and the cathode pad CaP. The fourth test voltage V4 may be applied between the gate pad GP and the cathode pad CaP. As the fourth test voltage V4, various values are adopted according to the specification of the semiconductor device 1A. The fourth test voltage V4 is typically 500 V or more and 8000 V or less.

When the fourth test voltage V4 is applied, a predetermined test current is generated at the emitter pad EP and the cathode pad CaP, and the ESD tolerance between the emitter pad EP and the cathode pad CaP is measured.

The gate structure 20 is not electrically interposed in a region between the emitter pad EP and the cathode pad CaP. Therefore, the ESD tolerance between the emitter pad EP and the cathode pad CaP will be less than the ESD tolerance between the emitter pad EP and the gate pad GP.

In this regard, in the semiconductor device 1A, the cathode capacitor structure CC (capacitor C) is formed in the cathode pad region 11C, and the capacitance value between the emitter pad EP and the cathode pad CaP is complemented by the cathode capacitor structure CC. As a result, the ESD tolerance is enhanced as compared with a case where the cathode capacitor structure CC does not exist in the cathode pad CaP.

As described above, the semiconductor device 1A may include the chip 2, the pad region 11, the first capacitor electrode film 90 (first electrode), the side wall dielectric film 91, and the second capacitor electrode film 92 (second electrode). The chip 2 may have the first main surface 3. The pad region 11 may be provided in the first main surface 3. The first capacitor electrode film 90 may be arranged on the first main surface 3 of the pad region 11. A first potential may be applied to the first capacitor electrode film 90.

The side wall dielectric film 91 may cover a side wall of the first capacitor electrode film 90 in the pad region 11. The second capacitor electrode film 92 may be arranged on the first main surface 3 so as to form a capacitive coupling with the first capacitor electrode film 90 through the side wall dielectric film 91 in the pad region 11. A second potential different from the first potential may be applied to the second capacitor electrode film 92.

According to this configuration, the semiconductor device 1A capable of improving electrical characteristics is provided. Specifically, the semiconductor device 1A has the pad capacitor structure 84 including the first capacitor electrode film 90, the side wall dielectric film 91, and the second capacitor electrode film 92. According to this configuration, the capacitance value of the pad region 11 is increased by the pad capacitor structure 84, and as a result, the ESD tolerance is improved.

The first potential may be a potential other than the gate potential. According to this configuration, the capacitance value of the pad region 11 can be improved by the first capacitor electrode film 90 to which a potential other than the gate potential is to be applied.

The first potential may be a reference potential serving as a reference of circuit operation. According to this configuration, the capacitance value of the pad region 11 can be improved by the first capacitor electrode film 90 to which a reference potential is to be applied. The first potential may be an emitter potential. According to this configuration, the capacitance value of the pad region 11 can be improved by the first capacitor electrode film 90 to which an emitter potential is to be applied.

The second potential may be a potential other than the gate potential. According to this configuration, the capacitance value of the pad region 11 can be improved by the second capacitor electrode film 92 to which a potential other than the gate potential is to be applied.

The second potential may be a potential other than a reference potential serving as a reference of circuit operation. According to this configuration, the capacitance value of the pad region 11 can be improved by the second capacitor electrode film 92 to which a potential other than the reference potential is to be applied. The second potential may be a potential other than the emitter potential. According to this configuration, the capacitance value of the pad region 11 can be improved by the second capacitor electrode film 92 to which a potential other than the emitter potential is to be applied.

The semiconductor device 1A may include the pad electrode 95. The pad electrode 95 may be arranged on the first capacitor electrode film 90 and the second capacitor electrode film 92 in the pad region 11.

The pad electrode 95 may be electrically separated from the first capacitor electrode film 90, and may be electrically connected to the second capacitor electrode film 92. The second potential may be applied to the pad electrode 95.

According to this configuration, the capacitance value associated with the pad electrode 95 can be improved by the pad capacitor structure 84 including the first capacitor electrode film 90, the side wall dielectric film 91, and the second capacitor electrode film 92.

In this case, the semiconductor device 1A may include the insulating interlayer film 57 and the pad opening 93. The interlayer film 57 may cover the first capacitor electrode film 90 and the second capacitor electrode film 92 in the pad region 11. The pad opening 93 may be formed in the interlayer film 57 and may expose the second capacitor electrode film 92.

In this case, the pad electrode 95 may be arranged on the interlayer film 57 and electrically connected to the second capacitor electrode film 92 through the pad opening 93. According to this configuration, the pad electrode 95 can be appropriately electrically connected to the second capacitor electrode film 92 while preventing the pad electrode 95 from contacting the first capacitor electrode film 90.

The semiconductor device 1A may include the pad via electrode 94 embedded in the pad opening 93. In this case, the pad electrode 95 may be mechanically and electrically connected to the pad via electrode 94 on the interlayer film 57, and may be electrically connected to the second capacitor electrode film 92 through the pad via electrode 94.

According to this configuration, the pad electrode 95 can be appropriately connected to the second capacitor electrode film 92. Therefore, the electrical stability of the capacitance value associated with the pad electrode 95 can be improved.

The semiconductor device 1A may include the trench electrode-type capacitor structure 85. The capacitor structure 85 may be formed in the first main surface 3. In this case, the first capacitor electrode film 90 may be connected to the capacitor structure 85. The second capacitor electrode film 92 may be formed at an interval from the capacitor structure 85.

According to this configuration, the second capacitor electrode film 92 forms a capacitive coupling with the capacitor structure 85 and the first capacitor electrode film 90 through the side wall dielectric film 91. Therefore, the capacitance value of the pad region 11 can be improved by the first capacitor electrode film 90 connected to the capacitor structure 85.

The second potential may be applied to the capacitor structure 85. In this case, the first capacitor electrode film 90 may be arranged such that the second potential is to be applied from the capacitor structure 85. According to this configuration, the second potential applied to the capacitor structure 85 can be transmitted to the first capacitor electrode film 90 through the capacitor structure 85.

The capacitor structure 85 may include the capacitor trench 86, the capacitor insulating film 87, and the capacitor embedded electrode 88. The capacitor trench 86 may be formed in the first main surface 3. The capacitor insulating film 87 may cover wall surfaces of the capacitor trench 86. The capacitor embedded electrode 88 may be embedded in the capacitor trench 86 with the capacitor insulating film 87 interposed therebetween.

In this case, the first capacitor electrode film 90 may be formed integrally with the capacitor embedded electrode 88 as a projecting portion projecting above the height position of the first main surface 3 from the capacitor embedded electrode 88.

The semiconductor device 1A may include the main surface insulating film 48 as a dielectric film. The main surface insulating film 48 may cover the first main surface 3. In this case, the second capacitor electrode film 92 may be arranged on the main surface insulating film 48, and may form a capacitive coupling with the chip 2 through the main surface insulating film 48.

That is, the second capacitor electrode film 92 may have a portion that forms a capacitive coupling with the chip 2 through the main surface insulating film 48, and a portion that forms a capacitive coupling with the first capacitor electrode film 90 through the side wall dielectric film 91. According to this configuration, the capacitance value of the pad region 11 can be improved by the second capacitor electrode film 92 having a portion that forms a capacitive coupling with the chip 2.

The semiconductor device 1A may include the n-type drift region 12 (semiconductor region), the p-type pad well region 80, and the main surface insulating film 48. The drift region 12 may be formed in the chip 2. The pad well region 80 may be formed on the surface layer portion of the first main surface 3 in the pad region 11, and may be electrically connected to the drift region 12. The main surface insulating film 48 may cover the pad well region 80 on the first main surface 3 in the pad region 11.

In this case, the second capacitor electrode film 92 may form a capacitive coupling with the pad well region 80 through the main surface insulating film 48. According to this configuration, the capacitance value of the pad region 11 can be improved by the second capacitor electrode film 92 having a portion that forms a capacitive coupling with the pad well region 80.

Also, according to this configuration, a depletion layer extends from the pn-junction portion between the drift region 12 and the pad well region 80. Therefore, a withstand voltage can be improved in the pad region 11.

The semiconductor device 1A may include the active region 6 and the transistor structure T3. The active region 6 may be provided in the first main surface 3. The transistor structure T3 may be formed in the active region 6. In this case, the pad region 11 may be provided in a region outside the active region 6 in the first main surface 3. According to this configuration, the capacitance value of the pad region 11 can be improved outside the active region 6.

The transistor structure T3 may include the trench electrode-type gate structure 20 to which a gate potential is to be applied. The first capacitor electrode film 90 may be electrically disconnected from the gate structure 20. According to this configuration, the capacitance value of the pad region 11 can be improved by the first capacitor electrode film 90 electrically disconnected from the gate structure 20.

The capacitor structure 85 may have a depth equal to the depth of the gate structure 20. According to this configuration, the capacitance value of the pad region 11 can be increased by the capacitor structure 85 having a depth equal to the depth of the gate structure 20. In this case, the capacitor structure 85 can be produced simultaneously with the gate structure 20.

The transistor structure T3 may include the trench electrode-type emitter structure 30 to which an emitter potential is to be applied. The first capacitor electrode film 90 may be electrically connected to the emitter structure 30. According to this configuration, the capacitance value of the pad region 11 can be improved by the first capacitor electrode film 90 electrically connected to the emitter structure 30.

The capacitor structure 85 may have a depth equal to the depth of the emitter structure 30. According to this configuration, the capacitance value of the pad region 11 can be increased by the capacitor structure 85 having a depth equal to the depth of the emitter structure 30. In this case, the capacitor structure 85 can be produced simultaneously with the emitter structure 30.

The capacitor structure 85 may be led out from the pad region 11 to the active region 6, and may be connected to the emitter structure 30 in the active region 6. According to this configuration, the potential applied to the emitter structure 30 can be transmitted to the first capacitor electrode film 90 through the capacitor structure 85.

Therefore, the potential applied to the emitter structure 30 can be transmitted to the first capacitor electrode film 90 through the capacitor structure 85 as a wiring structure positioned below the height position of the first main surface 3. Also, the capacitance value of the pad region 11 can be appropriately improved by the capacitor structure 85 and the first capacitor electrode film 90.

The semiconductor device 1A may include the temperature detection region 10 as a diode region and the temperature-sensitive diode structure D as a diode structure. The temperature detection region 10 may be provided in a region outside the active region 6 in the first main surface 3. The temperature-sensitive diode structure D may be formed in the temperature detection region 10.

In this case, the pad region 11 may be provided in a region outside the temperature detection region 10 in the first main surface 3. According to this configuration, the capacitance value of the pad region 11 can be improved outside the temperature detection region 10.

A potential other than the potential for the temperature-sensitive diode structure D may be applied to the first capacitor electrode film 90. According to this configuration, the capacitance value of the pad region 11 can be improved by the first capacitor electrode film 90 to which a potential other than the potential for the temperature-sensitive diode structure D is to be applied.

A potential for the temperature-sensitive diode structure D may be applied to the second capacitor electrode film 92. According to this configuration, the capacitance value of the pad region 11 can be improved by the second capacitor electrode film 92 to which a potential for the temperature-sensitive diode structure D is to be applied.

The semiconductor device 1A may include the anode wiring 75. The anode wiring 75 may be electrically connected to the temperature-sensitive diode structure D on the first main surface 3. In this case, the second capacitor electrode film 92 may be electrically connected to the anode wiring 75. According to this configuration, the capacitance value of the pad region 11 can be improved by the second capacitor electrode film 92 to which an anode potential is to be applied.

The semiconductor device 1A may include the cathode wiring 76. The cathode wiring 76 may be electrically connected to the temperature-sensitive diode structure D on the first main surface 3. In this case, the second capacitor electrode film 92 may be electrically connected to the cathode wiring 76. According to this configuration, the capacitance value of the pad region 11 can be improved by the second capacitor electrode film 92 to which a cathode potential is to be applied.

The semiconductor device 1A may include the monitor region 7 and the monitor transistor structure T2 for current monitoring. The monitor region 7 may be provided in a region outside the active region 6 in the first main surface 3. The monitor transistor structure T2 may be formed in the monitor region 7.

In this case, the pad region 11 may be provided in a region outside the monitor region 7 in the first main surface 3. According to this configuration, the capacitance value of the pad region 11 can be improved outside the monitor region 7.

A potential other than the potential for the monitor transistor structure T2 may be applied to the first capacitor electrode film 90. According to this configuration, the capacitance value of the pad region 11 can be improved by the first capacitor electrode film 90 to which a potential other than the potential for the monitor transistor structure T2 is to be applied.

A potential for the monitor transistor structure T2 may be applied to the second capacitor electrode film 92. According to this configuration, the capacitance value of the pad region 11 can be improved by the second capacitor electrode film 92 to which a potential for the monitor transistor structure T2 is to be applied.

The semiconductor device 1A may include the monitor electrode 67. The monitor electrode 67 may be electrically connected to the monitor transistor structure T2 on the first main surface 3 of the monitor region 7. In this case, the second capacitor electrode film 92 may be electrically connected to the monitor electrode 67. According to this configuration, the capacitance value of the pad region 11 can be improved by the second capacitor electrode film 92 to which a monitor potential is to be applied.

The semiconductor device 1A may include the p-type base region 15. The base region 15 may be formed on the surface layer portion of the first main surface 3 in the active region 6, and may be electrically connected to the drift region 12.

In this case, the pad well region 80 may be formed deeper than the base region 15. According to this configuration, the capacitance value of the pad region 11 can be increased by the second capacitor electrode film 92 that forms a capacitive coupling with the pad well region 80 formed deeper than the base region 15.

From another point of view, the semiconductor device 1A may include the chip 2, the first capacitor electrode film 90 (first electrode), the main surface insulating film 48 as a first dielectric film, the side wall dielectric film 91 as a second dielectric film, and the second capacitor electrode film 92 (second electrode). The chip 2 may have the first main surface 3. The first capacitor electrode film 90 may be arranged on the first main surface 3. A first potential may be applied to the first capacitor electrode film 90.

The main surface insulating film 48 may cover the first main surface 3. The side wall dielectric film 91 may cover a side wall of the first capacitor electrode film 90. The second capacitor electrode film 92 may be arranged on the main surface insulating film 48 so as to form a capacitive coupling with the chip 2 through the main surface insulating film 48 and to form a capacitive coupling with the first capacitor electrode film 90 through the side wall dielectric film 91. A second potential different from the first potential may be applied to the second capacitor electrode film 92.

According to this configuration, the semiconductor device 1A capable of improving electrical characteristics is provided. Specifically, the semiconductor device 1A has the pad capacitor structure 84 including the first capacitor electrode film 90, the main surface insulating film 48, the side wall dielectric film 91, and the second capacitor electrode film 92. According to this configuration, the capacitance value of the pad region 11 is increased by the pad capacitor structure 84, and as a result, the ESD tolerance is improved.

The side wall dielectric film 91 may have a portion connected to the main surface insulating film 48. According to this configuration, the capacitance value of the pad region 11 can be increased by the side wall dielectric film 91 having a portion connected to the main surface insulating film 48. The side wall dielectric film 91 may have a thickness larger than the thickness of the main surface insulating film 48. According to this configuration, insulation properties between the first capacitor electrode film 90 and the second capacitor electrode film 92 can be increased.

The semiconductor device 1A may include the pad electrode 95. The pad electrode 95 may be arranged on the first capacitor electrode film 90 and the second capacitor electrode film 92. The pad electrode 95 may be electrically separated from the first capacitor electrode film 90, and may be electrically connected to the second capacitor electrode film 92. The second potential may be applied to the pad electrode 95. According to this configuration, the capacitance value associated with the pad electrode 95 can be improved by the pad capacitor structure 84.

The semiconductor device 1A may include the n-type drift region 12 (semiconductor region), the p-type pad well region 80, and the main surface insulating film 48. The drift region 12 may be formed in the chip 2. The pad well region 80 may be formed on the surface layer portion of the first main surface 3 in the pad region 11, and may be electrically connected to the drift region 12. The main surface insulating film 48 may cover the pad well region 80 on the first main surface 3 in the pad region 11.

In this case, the second capacitor electrode film 92 may form a capacitive coupling with the pad well region 80 through the main surface insulating film 48. According to this configuration, the capacitance value of the pad region 11 can be improved by the second capacitor electrode film 92 having a portion that forms a capacitive coupling with the pad well region 80.

Also, according to this configuration, a depletion layer extends from the pn-junction portion between the drift region 12 and the pad well region 80. Therefore, a withstand voltage can be improved in the pad region 11.

The semiconductor device 1A may include the trench electrode-type capacitor structure 85. The capacitor structure 85 may be formed in the first main surface 3. In this case, the first capacitor electrode film 90 may be connected to the capacitor structure 85. The second capacitor electrode film 92 may be formed at an interval from the capacitor structure 85.

According to this configuration, the second capacitor electrode film 92 forms a capacitive coupling with the capacitor structure 85 and the first capacitor electrode film 90 through the side wall dielectric film 91. Therefore, the capacitance value of the pad region 11 can be improved by the first capacitor electrode film 90 connected to the capacitor structure 85.

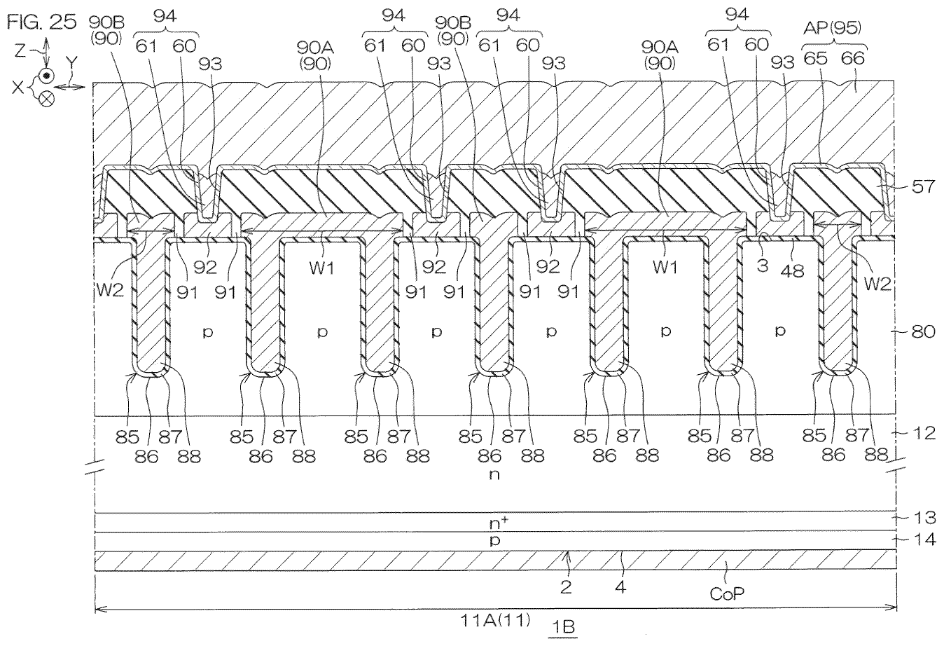

FIG. 25 is a cross-sectional view showing a main portion of a semiconductor device 1B according to a second embodiment. Similar to the semiconductor device 1A, the semiconductor device 1B includes a plurality of pad well regions 80 and a plurality of pad capacitor structures 84 formed in a plurality of pad regions 11, respectively.

Similar to the semiconductor device 1A, the pad capacitor structure 84 includes a plurality of capacitor structures 85, a plurality of first capacitor electrode films 90, a main surface insulating film 48, a plurality of side wall dielectric films 91, a plurality of second capacitor electrode films 92, an interlayer film 57, a plurality of pad openings 93, a plurality of pad via electrodes 94, and a pad electrode 95. The semiconductor device 1B may include at least one of the plurality of capacitor structures 85 (see FIGS. 14 and 20A to 20M) according to the first to fourteenth layout examples.

Similar to the semiconductor device 1A, the pad capacitor structure 84 includes a plurality of first capacitor electrode films 90. In this embodiment, the pad capacitor structure 84 includes one or a plurality of (in this embodiment, a plurality of) first capacitor electrode films 90A on one side and one or a plurality of (in this embodiment, a plurality of) first capacitor electrode films 90B on the other side.

Each of the plurality of first capacitor electrode films 90A on one side has a relatively large first width W1 in cross-sectional view, and the plurality of first capacitor electrode films 90A are arranged at intervals on a first main surface 3. The plurality of first capacitor electrode films 90A sandwich one or a plurality of (in this embodiment, one) capacitor structures 85 in cross-sectional view.

For example, the number of capacitor structures 85 interposed in the regions between the plurality of first capacitor electrode films 90A may be 1, 2, 3, 4, 5, 6, 7, 8, 9, or 10 (in this embodiment, 1).

The plurality of first capacitor electrode films 90A cover the plurality of capacitor structures 85 in one-to-many correspondence in cross-sectional view. That is, the plurality of first capacitor electrode films 90A respectively cover the plurality of adjacent capacitor structures 85 in cross-sectional view.

For example, the plurality of first capacitor electrode films 90A may cover two, three, four, five, six, seven, eight, nine, or ten capacitor structures 85 (in this embodiment, two). As a matter of course, the plurality of first capacitor electrode films 90A may cover different numbers (two or more) of capacitor structures 85, respectively.

The plurality of first capacitor electrode films 90A have portions covering capacitor embedded electrodes 88 of the corresponding plurality of capacitor structures 85 and portions covering the main surface insulating film 48. In this embodiment, the plurality of first capacitor electrode films 90A are formed integrally with the corresponding plurality of capacitor embedded electrodes 88 as projecting portions projecting above the height position of the first main surface 3 from the corresponding plurality of capacitor embedded electrodes 88.

The plurality of first capacitor electrode films 90A face the first main surface 3 (pad well region 80) with the main surface insulating film 48 interposed therebetween. That is, the plurality of first capacitor electrode films 90A extend over the plurality of adjacent capacitor structures 85, and cover the chip 2 (pad well region 80) with the main surface insulating film 48 interposed therebetween in the region between the plurality of adjacent capacitor structures 85.

Each of the plurality of first capacitor electrode films 90B on the other side has a second width W2 that is smaller than the first width W1 in cross-sectional view, and the plurality of first capacitor electrode films 90B are arranged at intervals on the first main surface 3. The plurality of first capacitor electrode films 90B cover the plurality of capacitor structures 85 other than the plurality of capacitor structures 85 connected to the plurality of first capacitor electrode films 90A in one-to-one correspondence.

The plurality of first capacitor electrode films 90B have portions covering capacitor embedded electrodes 88 of the corresponding capacitor structures 85 and portions covering the main surface insulating film 48. The plurality of first capacitor electrode films 90B are formed integrally with the corresponding capacitor embedded electrodes 88 as projecting portions projecting above the height position of the first main surface 3 from the corresponding capacitor embedded electrodes 88.

The plurality of first capacitor electrode films 90B face the first main surface 3 (pad well region 80) with the main surface insulating film 48 interposed therebetween. The facing area of the first capacitor electrode film 90B with respect to the first main surface 3 is smaller than the facing area of the first capacitor electrode film 90A with respect to the first main surface 3.

A width ratio W2/W1 of the second width W2 to the first width W1 may be 0.1 or more and less than 1. The width ratio W2/W1 may have a value belonging to at least one of the following ranges, 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, 0.7 or more and 0.8 or less, 0.8 or more and 0.9 or less, and 0.9 or more and less than 1.

Similar to the semiconductor device 1A, the pad capacitor structure 84 includes a plurality of second capacitor electrode films 92. In this embodiment, the plurality of second capacitor electrode films 92 have substantially equal widths.

As a matter of course, the plurality of second capacitor electrode films 92 may have different widths. The plurality of second capacitor electrode films 92 are respectively arranged in regions between the plurality of first capacitor electrode films 90A and the plurality of first capacitor electrode films 90B adjacent to one another on the main surface insulating film 48.

The plurality of second capacitor electrode films 92 face the first capacitor electrode film 90A through the side wall dielectric film 91 in one direction in the horizontal direction (first direction X), and form a capacitive coupling with the first capacitor electrode film 90A through the side wall dielectric film 91. The plurality of second capacitor electrode films 92 face the first capacitor electrode film 90B through the side wall dielectric film 91 in the other direction in the horizontal direction (first direction X), and form a capacitive coupling with the first capacitor electrode film 90B through the side wall dielectric film 91.

Similar to the semiconductor device 1A, the pad electrode 95 is arranged on the interlayer film 57, and is electrically connected to the plurality of second capacitor electrode films 92 through the plurality of pad via electrodes 94. In addition, the configuration of the semiconductor device 1B is similar to the configuration of the semiconductor device 1A. In the semiconductor device 1B, the capacitance value of the pad region 11 is appropriately adjusted by appropriately adjusting the number of first capacitor electrode films 90A, the number of first capacitor electrode films 90B, the first width W1, the second width W2, and the like.

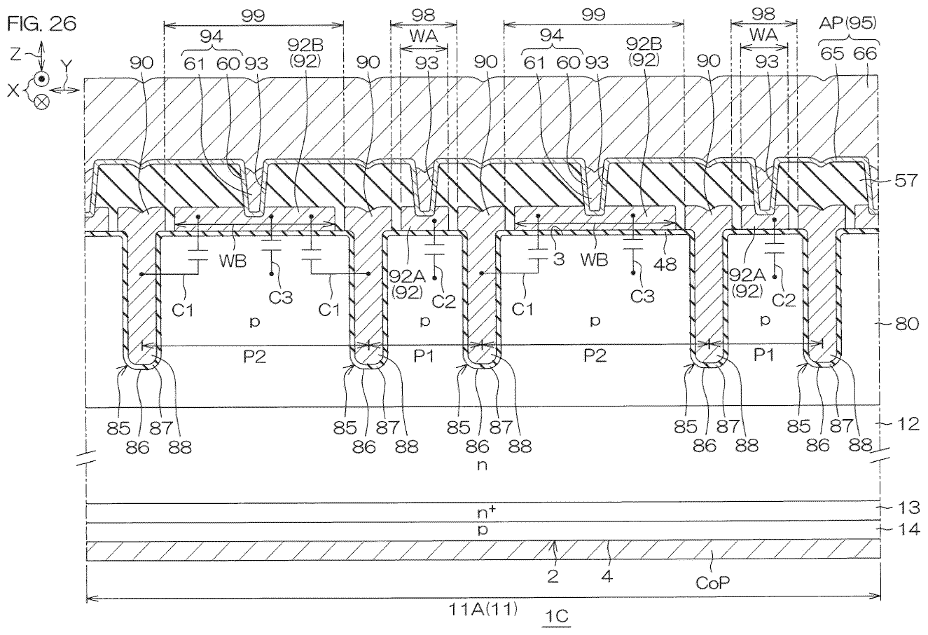

FIG. 26 is a cross-sectional view showing a main portion of a semiconductor device 1C according to a third embodiment. The configuration of the semiconductor device 1C is also applicable to the semiconductor device 1B. Similar to the semiconductor device 1A, the semiconductor device 1C includes a plurality of pad well regions 80 and a plurality of pad capacitor structures 84 formed in a plurality of pad regions 11, respectively.

Similar to the semiconductor device 1A, the pad capacitor structure 84 includes a plurality of capacitor structures 85, a plurality of first capacitor electrode films 90, a main surface insulating film 48, a plurality of side wall dielectric films 91, a plurality of second capacitor electrode films 92, an interlayer film 57, a plurality of pad openings 93, a plurality of pad via electrodes 94, and a pad electrode 95. The semiconductor device 1C may include at least one of the plurality of capacitor structures 85 (see FIGS. 14 and 20A to 20M) according to the first to fourteenth layout examples.

In this embodiment, the pad capacitor structure 84 includes a plurality of capacitor structures 85 aligned at different pitches from one another in cross-sectional view. The pitch is a distance in the horizontal direction between central portions of the plurality of adjacent capacitor structures 85 in cross-sectional view.

In this embodiment, the pad capacitor structure 84 includes a plurality of capacitor structures 85 adjacent to each other at a first pitch P1 in cross-sectional view, and a plurality of capacitor structures 85 adjacent to each other at a second pitch P2 larger than the first pitch P1 in cross-sectional view. The plurality of capacitor structures 85 adjacent to each other at the second pitch P2 are adjacent to the plurality of capacitor structures 85 adjacent to each other at the first pitch P1 in the second direction Y.

In this embodiment, the plurality of capacitor structures 85 adjacent to each other at the second pitch P2 are alternately aligned in the second direction Y with the plurality of capacitor structures 85 adjacent to each other at the first pitch P1. As a matter of course, the pad capacitor structure 84 may include any one or both of a region in which three or more capacitor structures 85 are aligned at the first pitch P1 and a region in which three or more capacitor structures 85 are aligned at the second pitch P2.

The first pitch P1 may be 1 μm or more and 5 μm or less. The first pitch P1 may have a value belonging to at least one of the following ranges, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less. The first pitch P1 is preferably 1.5 μm or more and 3.5 μm or less.

A pitch ratio P2/P1 of the second pitch P2 to the first pitch P1 may be more than 1 and not more than 5. The pitch ratio P2/P1 may have a value belonging to at least one of the following ranges, more than 1 and not more than 1.5, 1.5 or more and 2 or less, 2 or more and 2.5 or less, 2.5 or more and 3 or less, 3 or more and 3.5 or less, 3.5 or more and 4 or less, 4 or more and 4.5 or less, and 4.5 or more and 5 or less.

Similar to the semiconductor device 1A, the semiconductor device 1C includes a plurality of first capacitor electrode films 90. The semiconductor device 1C includes a plurality of first capacitor electrode films 90 adjacent to each other at the first pitch P1 in cross-sectional view, and a plurality of first capacitor electrode films 90 adjacent to each other at the second pitch P2 in cross-sectional view according to the layout of the plurality of capacitor structures 85.

The plurality of first capacitor electrode films 90 adjacent to each other at the first pitch P1 define a first region 98 having a relatively narrow width. The plurality of first capacitor electrode films 90 adjacent to each other at the second pitch P2 define a second region 99 that is wider than the first region 98.

Similar to the semiconductor device 1A, the pad capacitor structure 84 includes a plurality of second capacitor electrode films 92. In this embodiment, the pad capacitor structure 84 includes one or a plurality of (in this embodiment, a plurality of) second capacitor electrode films 92A on one side and one or a plurality of (in this embodiment, a plurality of) second capacitor electrode films 92B on the other side.

Each of the plurality of second capacitor electrode films 92A on one side has a relatively small first width WA, and the plurality of second capacitor electrode films 92A are arranged in a plurality of the first regions 98, respectively. The plurality of second capacitor electrode films 92A face the plurality of first capacitor electrode films 90 through the plurality of side wall dielectric films 91, and form a capacitive coupling with the plurality of first capacitor electrode films 90 through the plurality of side wall dielectric films 91. The plurality of second capacitor electrode films 92A form a first capacitor C1 with the plurality of first capacitor electrode films 90.

The plurality of second capacitor electrode films 92A face the chip 2 (pad well region 80) with the main surface insulating film 48 interposed therebetween, and form a capacitive coupling with the chip 2 (pad well region 80) through the main surface insulating film 48. The plurality of second capacitor electrode films 92A form a second capacitor C2 with the chip 2 (pad well region 80).

Each of the plurality of second capacitor electrode films 92B has a second width WB larger than the first width WA, and the plurality of second capacitor electrode films 92B are arranged in a plurality of the second regions 99, respectively. The plurality of second capacitor electrode films 92B face the plurality of first capacitor electrode films 90 through the plurality of side wall dielectric films 91, and form a capacitive coupling with the plurality of first capacitor electrode films 90 through the plurality of side wall dielectric films 91. The plurality of second capacitor electrode films 92B form a first capacitor C1 with the plurality of first capacitor electrode films 90.

The second width WB may be larger than the first pitch P1 and equal to or smaller than the second pitch P2. A width ratio WB/WA of the second width WB to the first width WA may be more than 1 and not more than 5. The width ratio WB/WA may have a value belonging to at least one of the following ranges, more than 1 and not more than 1.5, 1.5 or more and 2 or less, 2 or more and 2.5 or less, 2.5 or more and 3 or less, 3 or more and 3.5 or less, 3.5 or more and 4 or less, 4 or more and 4.5 or less, and 4.5 or more and 5 or less.

The plurality of second capacitor electrode films 92B face the chip 2 (pad well region 80) with the main surface insulating film 48 interposed therebetween, and form a capacitive coupling with the chip 2 (pad well region 80) through the main surface insulating film 48.

The facing area of the second capacitor electrode film 92B with respect to the chip 2 (pad well region 80) is larger than the facing area of the second capacitor electrode film 92A with respect to the chip 2 (pad well region 80).

The plurality of second capacitor electrode films 92A form a third capacitor C3 with the chip 2 (pad well region 80). The third capacitor C3 has a capacitance value larger than the capacitance value of the second capacitor C2.

A capacitance value ratio C3/C2 of the capacitance value of the third capacitor C3 to the capacitance value of the second capacitor C2 may be more than 1 and not more than 5. The capacitance value ratio C3/C2 may have a value belonging to at least one of the following ranges, more than 1 and not more than 1.5, 1.5 or more and 2 or less, 2 or more and 2.5 or less, 2.5 or more and 3 or less, 3 or more and 3.5 or less, 3.5 or more and 4 or less, 4 or more and 4.5 or less, and 4.5 or more and 5 or less.

Similar to the semiconductor device 1A, the pad electrode 95 is arranged on the interlayer film 57, and is electrically connected to the plurality of second capacitor electrode films 92 through the plurality of pad via electrodes 94. In addition, the configuration of the semiconductor device 1C is similar to the configuration of the semiconductor device 1A. In the semiconductor device 1C, the capacitance value of the pad region 11 is appropriately adjusted by appropriately adjusting the first pitch P1, the second pitch P2, the first width WA, the second width WB, and the like.

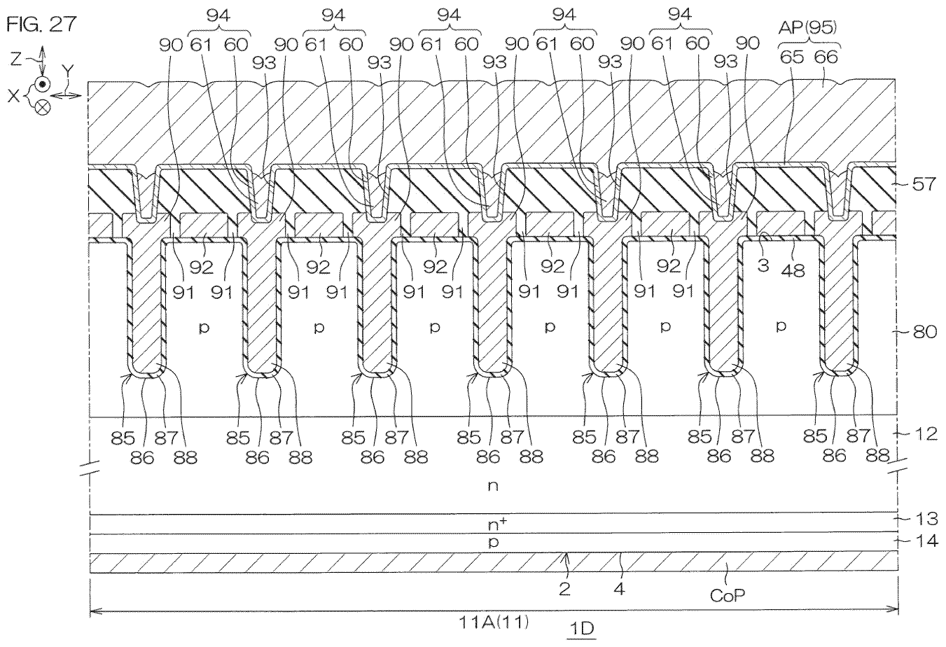

FIG. 27 is a cross-sectional view showing a main portion of a semiconductor device 1D according to a fourth embodiment. Similar to the semiconductor device 1A, the semiconductor device 1D includes a plurality of pad well regions 80 and a plurality of pad capacitor structures 84 formed in a plurality of pad regions 11, respectively.

Similar to the semiconductor device 1A, the pad capacitor structure 84 includes a plurality of capacitor structures 85, a plurality of first capacitor electrode films 90, a main surface insulating film 48, a plurality of side wall dielectric films 91, a plurality of second capacitor electrode films 92, an interlayer film 57, a plurality of pad openings 93, a plurality of pad via electrodes 94, and a pad electrode 95. The semiconductor device 1D may include at least one of the plurality of capacitor structures 85 (see FIGS. 14 and 20A to 20M) according to the first to fourteenth layout examples.

In this embodiment, a potential other than the emitter potential is to be applied to the plurality of capacitor structures 85. That is, a potential different from the potential applied to the emitter structure 30 (emitter connection structure 35) and the pad well region 80 is to be applied to the plurality of capacitor structures 85. In this embodiment, the plurality of capacitor structures 85 have no lead-out portion 85a and are formed at intervals from the plurality of emitter structures 30 and the plurality of emitter connection structures 35.

That is, the plurality of capacitor structures 85 are electrically separated from the plurality of emitter structures 30 and the plurality of emitter connection structures 35. The plurality of capacitor structures 85 are formed with ends in the pad region 11. The plurality of capacitor structures 85 may be formed only in the pad region 11.

In this embodiment, the plurality of capacitor structures 85 form a capacitive coupling with a chip 2. Specifically, the plurality of capacitor structures 85 form a capacitive coupling with the pad well region 80. Specifically, capacitor embedded electrodes 88 of the plurality of capacitor structures 85 form a capacitive coupling with the chip 2 through a capacitor insulating film 87 as a dielectric film.

More specifically, the capacitor embedded electrode 88 forms a capacitive coupling with the pad well region 80 through the capacitor insulating film 87. In this embodiment, the capacitor embedded electrode 88 forms a capacitive coupling with the pad well region 80 on the side wall and the bottom wall of the capacitor trench 86. The plurality of capacitor structures 85 constitute a plurality of first capacitors C1 with the chip 2 (pad well region 80).

Similar to the semiconductor device 1A, the plurality of first capacitor electrode films 90 cover the plurality of capacitor structures 85 in one-to-one correspondence, and are electrically connected to the corresponding capacitor structures 85, respectively. In this embodiment, the plurality of first capacitor electrode films 90 cover the entire region of the corresponding capacitor structures 85.

In this embodiment, each of the plurality of first capacitor electrode films 90 has a portion covering the corresponding capacitor structure 85 and a portion covering the main surface insulating film 48, respectively. The plurality of first capacitor electrode films 90 face a first main surface 3 with the main surface insulating film 48 interposed therebetween, and form a capacitive coupling with the chip 2 through the main surface insulating film 48.

Specifically, the plurality of first capacitor electrode films 90 form a capacitive coupling with the pad well region 80 through the main surface insulating film 48. That is, the plurality of first capacitor electrode films 90 constitute the chip 2 (pad well region 80) and the plurality of first capacitors C1 with the plurality of capacitor structures 85.

In this embodiment, the plurality of side wall dielectric films 91 cover the entire periphery of the side walls of the corresponding first capacitor electrode films 90, and surround the corresponding first capacitor electrode films 90 (capacitor structures 85).

Similar to the semiconductor device 1A, the plurality of second capacitor electrode films 92 are arranged in regions between the plurality of first capacitor electrode films 90, respectively. A potential different from the potential applied to the plurality of first capacitor electrode films 90 is to be applied to the plurality of second capacitor electrode films 92.

In this embodiment, an emitter potential is to be applied to the plurality of second capacitor electrode films 92. The plurality of second capacitor electrode films 92 do not form a voltage drop with the pad well region 80 due to the potential applied from outside, except for a voltage drop due to the electric field distribution formed in the chip 2.

In this embodiment, each of the plurality of second capacitor electrode films 92 has a lead-out portion led out from the pad region 11 to the active region 6, and is electrically connected to at least one of the emitter structure 30, the emitter connection structure 35, and the emitter wiring 55 in the active region 6.

Therefore, an emitter potential is to be applied to the plurality of second capacitor electrode films 92. For example, the plurality of second capacitor electrode films 92 may be led out to the active region 6 through an open portion of the gate connection structure 25 where the gate connection structure 25 does not exist.

The plurality of second capacitor electrode films 92 form a capacitive coupling with the corresponding first capacitor electrode films 90 through the corresponding side wall dielectric films 91. The plurality of second capacitor electrode films 92 constitute a plurality of second capacitors C2 with the plurality of first capacitor electrode films 90. The plurality of second capacitors C2 are connected in parallel to the plurality of first capacitors C1.

In this embodiment, the plurality of pad openings 93 selectively expose parts of the plurality of first capacitor electrode films 90. Specifically, the plurality of pad openings 93 expose parts of the plurality of first capacitor electrode films 90 at intervals from the plurality of second capacitor electrode films 92, respectively.

In this embodiment, the plurality of pad openings 93 are formed in one-to-one correspondence with the plurality of first capacitor electrode films 90, and face the plurality of capacitor structures 85 in one-to-one correspondence in the thickness direction.

In this embodiment, the plurality of pad openings 93 extend in a band shape in the first direction X in conformance to the extension direction of the corresponding first capacitor electrode films 90, respectively. The plurality of pad openings 93 expose inner portions of the corresponding first capacitor electrode films 90 at intervals from the peripheral edges of the corresponding first capacitor electrode films 90.

In this embodiment, the plurality of pad openings 93 have a bottom wall that is formed deeper from the main electrode surface of the corresponding first capacitor electrode film 90 toward the chip 2 (in this embodiment, bottom wall of the capacitor trench 86) side and is positioned in the corresponding first capacitor electrode film 90.

The bottom walls of the plurality of pad openings 93 are preferably formed at intervals from the height position of the first main surface 3 to the main electrode surface side of the corresponding first capacitor electrode film 90. The bottom walls of the plurality of pad openings 93 are preferably formed at intervals from a thickness position of an intermediate portion of the corresponding first capacitor electrode film 90 to the main electrode surface side of the corresponding first capacitor electrode film 90.

As a matter of course, the bottom walls of the plurality of pad openings 93 may be positioned on the first main surface 3 (main surface insulating film 48) side relative to the thickness position of the intermediate portion of the corresponding first capacitor electrode film 90. In this case, the bottom walls of the plurality of pad openings 93 may be positioned on the bottom wall side of the capacitor trench 86 relative to the height position of the first main surface 3. The plurality of pad openings 93 may be formed in a tapered shape toward the bottom wall. As a matter of course, the plurality of pad openings 93 may be formed substantially perpendicular to the first main surface 3.

The plurality of pad openings 93 may be formed in one-to-many correspondence with one corresponding first capacitor electrode film 90. In this case, the plurality of pad openings 93 may be formed at intervals in conformance to the extension direction of the corresponding first capacitor electrode film 90. The plurality of pad openings 93 may be formed in a polygonal shape, a circular shape, or the like in plan view. The plurality of pad openings 93 may be formed in a quadrangular shape, a hexagonal shape, or the like in plan view.

In this embodiment, the plurality of pad via electrodes 94 are mechanically and electrically connected to the corresponding first capacitor electrode films 90 in the corresponding pad openings 93. Therefore, the plurality of pad via electrodes 94 are electrically connected to the corresponding capacitor embedded electrodes 88 through the corresponding first capacitor electrode films 90.

Similar to the first emitter via electrode 59, the pad via electrode 94 may have a laminated structure including the first electrode 60 and the second electrode 61 laminated in this order from the wall surface side of the pad opening 93.

The first electrode 60 is formed in a film shape on the wall surface of the pad opening 93, and is mechanically and electrically connected to the corresponding first capacitor electrode film 90 in the pad opening 93. The second electrode 61 is embedded in the pad opening 93 with the first electrode 60 interposed therebetween, and is electrically connected to the corresponding first capacitor electrode film 90 through the first electrode 60.

In this embodiment, the pad electrode 95 is electrically insulated from the plurality of second capacitor electrode films 92 by the interlayer film 57, and is electrically connected to the plurality of first capacitor electrode films 90 (plurality of capacitor structures 85) through the plurality of pad openings 93.

Specifically, the anode pad AP is mechanically and electrically connected to the plurality of pad via electrodes 94 on the interlayer film 57, and is electrically connected to the plurality of first capacitor electrode films 90 through the plurality of pad via electrodes 94. Therefore, the potential applied to the pad electrode 95 is to be applied to the plurality of capacitor structures 85 (capacitor embedded electrodes 88) through the plurality of first capacitor electrode films 90.

Similar to the emitter pad EP, the pad electrode 95 may have a laminated structure including the first electrode film 65 and the second electrode film 66 laminated in this order from the interlayer film 57 side. The first electrode film 65 covers the interlayer film 57 in a film shape as a barrier electrode. The first electrode film 65 is electrically connected to the plurality of pad via electrodes 94 on the interlayer film 57.

The first electrode film 65 is connected to the first electrode 60 of the plurality of pad via electrodes 94. As a matter of course, the first electrode film 65 may cover the first electrode 60 of the plurality of pad via electrodes 94. The second electrode film 66 has a thickness larger than the thickness of the first electrode film 65, and covers the first electrode film 65 in a film shape. As a matter of course, the second electrode film 66 covers the second electrode 61 of the plurality of pad via electrodes 94 in a film shape.

As described above, the semiconductor device 1D may include the chip 2, the pad region 11, the trench electrode-type capacitor structure 85, the first capacitor electrode film 90 (first electrode), the side wall dielectric film 91, and the second capacitor electrode film 92 (second electrode). The chip 2 may have the first main surface 3. The pad region 11 may be provided in the first main surface 3. The capacitor structure 85 may be formed in the first main surface 3 in the pad region 11, and may form a capacitive coupling with the chip 2. A first potential may be applied to the capacitor structure 85.

The first capacitor electrode film 90 may be connected to the capacitor structure 85 on the first main surface 3 in the pad region 11. The side wall dielectric film 91 may cover a side wall of the first capacitor electrode film 90 on the first main surface 3 in the pad region 11. The second capacitor electrode film 92 may be arranged on the first main surface 3 in the pad region 11, and may form a capacitive coupling with the first capacitor electrode film 90 through the side wall dielectric film 91. A second potential different from the first potential may be applied to the second capacitor electrode film 92.

According to this configuration, the semiconductor device 1D capable of improving electrical characteristics is provided. Specifically, the semiconductor device 1D has the pad capacitor structure 84 including the capacitor structure 85, the first capacitor electrode film 90, the side wall dielectric film 91, and the second capacitor electrode film 92. According to this configuration, the capacitance value of the pad region 11 is increased by the pad capacitor structure 84, and as a result, the ESD tolerance is improved.

The first potential may be a potential other than the gate potential. According to this configuration, the capacitance value of the pad region 11 can be improved by the first capacitor electrode film 90 to which a potential other than the gate potential is to be applied.

The first potential may be a potential other than a reference potential serving as a reference of circuit operation. According to this configuration, the capacitance value of the pad region 11 can be improved by the first capacitor electrode film 90 to which a potential other than the reference potential is to be applied. The first potential may be a potential other than the emitter potential. According to this configuration, the capacitance value of the pad region 11 can be improved by the first capacitor electrode film 90 to which a potential other than the emitter potential is to be applied.

The second potential may be a potential other than the gate potential. According to this configuration, the capacitance value of the pad region 11 can be improved by the second capacitor electrode film 92 to which a potential other than the gate potential is to be applied.

The second potential may be a reference potential serving as a reference of circuit operation. According to this configuration, the capacitance value of the pad region 11 can be improved by the second capacitor electrode film 92 to which a reference potential is to be applied. The second potential may be an emitter potential. According to this configuration, the capacitance value of the pad region 11 can be improved by the second capacitor electrode film 92 to which an emitter potential is to be applied.

The semiconductor device 1D may include the pad electrode 95. The pad electrode 95 may be arranged on the first capacitor electrode film 90 and the second capacitor electrode film 92 in the pad region 11. The pad electrode 95 may be electrically connected to the first capacitor electrode film 90, and may be electrically separated from the second capacitor electrode film 92.

The first potential may be applied to the pad electrode 95. According to this configuration, the capacitance value associated with the pad electrode 95 can be improved by the pad capacitor structure 84 including the capacitor structure 85, the first capacitor electrode film 90, the side wall dielectric film 91, and the second capacitor electrode film 92.

In this case, the semiconductor device 1D may include the insulating interlayer film 57 and the pad opening 93. The interlayer film 57 may cover the first capacitor electrode film 90 and the second capacitor electrode film 92 in the pad region 11. The pad opening 93 may be formed in the interlayer film 57 and may expose the first capacitor electrode film 90.

In this case, the pad electrode 95 may be arranged on the interlayer film 57 and electrically connected to the first capacitor electrode film 90 through the pad opening 93. According to this configuration, the pad electrode 95 can be appropriately electrically connected to the first capacitor electrode film 90 while preventing the pad electrode 95 from contacting the second capacitor electrode film 92.

The semiconductor device 1D may include the pad via electrode 94 embedded in the pad opening 93. In this case, the pad electrode 95 may be mechanically and electrically connected to the pad via electrode 94 on the interlayer film 57, and may be electrically connected to the first capacitor electrode film 90 through the pad via electrode 94.

According to this configuration, the pad electrode 95 can be appropriately connected to the first capacitor electrode film 90. Therefore, the electrical stability of the capacitance value associated with the pad electrode 95 can be improved.

The capacitor structure 85 may include the capacitor trench 86, the capacitor insulating film 87 (dielectric film), and the capacitor embedded electrode 88. The capacitor trench 86 may be formed in the first main surface 3. The capacitor insulating film 87 may cover wall surfaces of the capacitor trench 86. The capacitor embedded electrode 88 may form a capacitive coupling with the chip 2 through the capacitor insulating film 87 in the capacitor trench 86. According to this structure, the capacitance value of the capacitor structure 85 can be adjusted by the film thickness of the capacitor insulating film 87.

In this case, the first capacitor electrode film 90 may be formed integrally with the capacitor embedded electrode 88 as a projecting portion projecting above the height position of the first main surface 3 from the capacitor embedded electrode 88.

The semiconductor device 1D may include the main surface insulating film 48. The main surface insulating film 48 may cover the first main surface 3. In this case, the first capacitor electrode film 90 may have a portion covering the first main surface 3 with the main surface insulating film 48 interposed therebetween, and may form a capacitive coupling with the chip 2 through the main surface insulating film 48.

According to this configuration, the capacitance value of the pad region 11 can be improved by the first capacitor electrode film 90 that forms a capacitive coupling with the chip 2. In this case, the second capacitor electrode film 92 may be arranged on the main surface insulating film 48.

The semiconductor device 1D may include the n-type drift region 12 (semiconductor region), the p-type pad well region 80, and the main surface insulating film 48. The drift region 12 may be formed in the chip 2. The pad well region 80 may be formed on the surface layer portion of the first main surface 3 in the pad region 11, and may be electrically connected to the drift region 12. The main surface insulating film 48 may cover the pad well region 80 on the first main surface 3 in the pad region 11.

In this case, the capacitor structure 85 may be arranged in the pad well region 80 and may form a capacitive coupling with the pad well region 80. According to this configuration, the capacitance value of the pad region 11 can be increased by the capacitor structure 85 that forms a capacitive coupling with the pad well region 80.

Also, according to this configuration, a depletion layer extends from the pn-junction portion between the drift region 12 and the pad well region 80. Therefore, a withstand voltage can be improved in the pad region 11. In this case, the first capacitor electrode film 90 may form a capacitive coupling with the pad well region 80 through the main surface insulating film 48. The second capacitor electrode film 92 may cover the pad well region 80 with the main surface insulating film 48 interposed therebetween.

The semiconductor device 1D may include the active region 6 and the transistor structure T3. The active region 6 may be provided in the first main surface 3. The transistor structure T3 may be formed in the active region 6. In this case, the pad region 11 may be provided in a region outside the active region 6 in the first main surface 3. According to this configuration, the capacitance value of the pad region 11 can be improved outside the active region 6.

The transistor structure T3 may include the trench electrode-type gate structure 20 to which a gate potential is to be applied. The capacitor structure 85 and the first capacitor electrode film 90 may be electrically disconnected from the gate structure 20. According to this configuration, the capacitance value of the pad region 11 can be improved by the capacitor structure 85 and the first capacitor electrode film 90 electrically disconnected from the gate structure 20.

The capacitor structure 85 may have a depth equal to the depth of the gate structure 20. According to this configuration, the capacitance value of the pad region 11 can be increased by the capacitor structure 85 having a depth equal to the depth of the gate structure 20. In this case, the capacitor structure 85 can be produced simultaneously with the gate structure 20.

The transistor structure T3 may include the trench electrode-type emitter structure 30 to which an emitter potential is to be applied. The capacitor structure 85 and the first capacitor electrode film 90 may be electrically disconnected from the emitter structure 30. According to this configuration, the capacitance value of the pad region 11 can be improved by the capacitor structure 85 and the first capacitor electrode film 90 electrically disconnected from the emitter structure 30.

The capacitor structure 85 may have a depth equal to the depth of the emitter structure 30. According to this configuration, the capacitance value of the pad region 11 can be increased by the capacitor structure 85 having a depth equal to the depth of the emitter structure 30. In this case, the capacitor structure 85 can be produced simultaneously with the emitter structure 30.

The second capacitor electrode film 92 may be led out from the pad region 11 to the active region 6, and may be electrically connected to the emitter structure 30 in the active region 6. According to this configuration, the capacitance value of the pad region 11 can be improved by the second capacitor electrode film 92 to which an emitter potential is to be applied.

The semiconductor device 1D may include the temperature detection region 10 as a diode region and the temperature-sensitive diode structure D as a diode structure. The temperature detection region 10 may be provided in a region outside the active region 6 in the first main surface 3. The temperature-sensitive diode structure D may be formed in the temperature detection region 10.

In this case, the pad region 11 may be provided in a region outside the temperature detection region 10 in the first main surface 3. According to this configuration, the capacitance value of the pad region 11 can be improved outside the temperature detection region 10.

A potential for the temperature-sensitive diode structure D may be applied to the first capacitor electrode film 90. According to this configuration, the capacitance value of the pad region 11 can be improved by the first capacitor electrode film 90 to which a potential for the temperature-sensitive diode structure D is to be applied.

A potential other than the potential for the temperature-sensitive diode structure D may be applied to the second capacitor electrode film 92. According to this configuration, the capacitance value of the pad region 11 can be improved by the second capacitor electrode film 92 to which a potential other than the potential for the temperature-sensitive diode structure D is to be applied.

The semiconductor device 1D may include the anode wiring 75. The anode wiring 75 may be electrically connected to the temperature-sensitive diode structure D on the first main surface 3. In this case, the first capacitor electrode film 90 may be electrically connected to the anode wiring 75. According to this configuration, the capacitance value of the pad region 11 can be improved by the first capacitor electrode film 90 to which an anode potential is to be applied.

The semiconductor device 1D may include the cathode wiring 76. The cathode wiring 76 may be electrically connected to the temperature-sensitive diode structure D on the first main surface 3. In this case, the first capacitor electrode film 90 may be electrically connected to the cathode wiring 76. According to this configuration, the capacitance value of the pad region 11 can be improved by the first capacitor electrode film 90 to which a cathode potential is to be applied.

The semiconductor device 1D may include the monitor region 7 and the monitor transistor structure T2 for current monitoring. The monitor region 7 may be provided in a region outside the active region 6 in the first main surface 3. The monitor transistor structure T2 may be formed in the monitor region 7.

In this case, the pad region 11 may be provided in a region outside the monitor region 7 in the first main surface 3. According to this configuration, the capacitance value of the pad region 11 can be improved outside the monitor region 7.

A potential for the monitor transistor structure T2 may be applied to the first capacitor electrode film 90. According to this configuration, the capacitance value of the pad region 11 can be improved by the first capacitor electrode film 90 to which a potential for the monitor transistor structure T2 is to be applied.

A potential other than the potential for the monitor transistor structure T2 may be applied to the second capacitor electrode film 92. According to this configuration, the capacitance value of the pad region 11 can be improved by the second capacitor electrode film 92 to which a potential other than the potential for the monitor transistor structure T2 is to be applied.

The semiconductor device 1D may include the monitor electrode 67. The monitor electrode 67 may be electrically connected to the monitor transistor structure T2 on the first main surface 3 of the monitor region 7. In this case, the first capacitor electrode film 90 may be electrically connected to the monitor electrode 67. According to this configuration, the capacitance value of the pad region 11 can be improved by the second capacitor electrode film 92 to which a monitor potential is to be applied.

The semiconductor device 1D may include the p-type base region 15. The base region 15 may be formed on the surface layer portion of the first main surface 3 in the active region 6, and may be electrically connected to the drift region 12.

In this case, the pad well region 80 may be formed deeper than the base region 15. According to this configuration, the capacitance value of the pad region 11 can be increased by the capacitor structure 85 that forms a capacitive coupling with the pad well region 80 formed deeper than the base region 15.

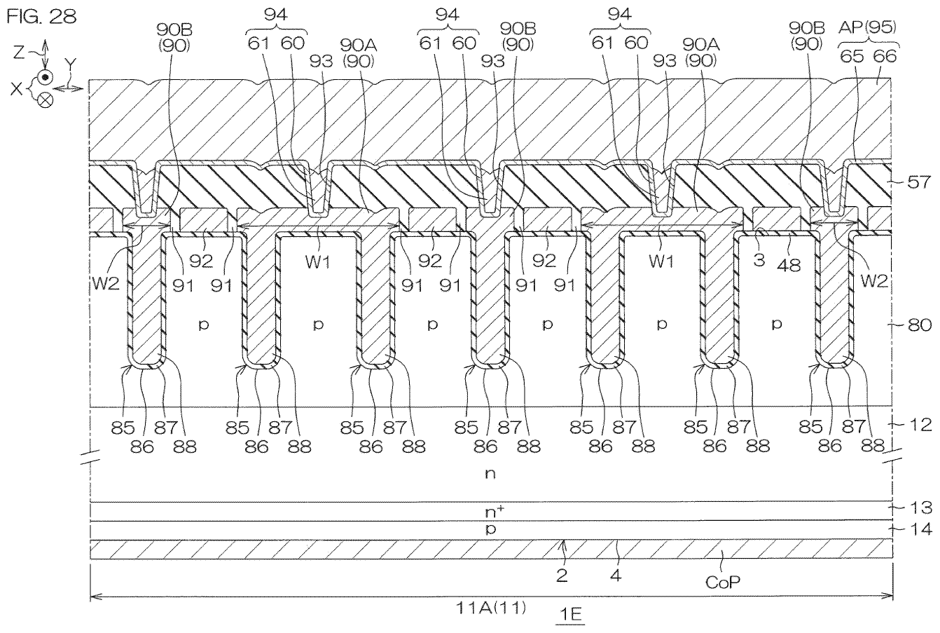

FIG. 28 is a cross-sectional view showing a main portion of a semiconductor device 1E according to a fifth embodiment. The semiconductor device 1E has a form in which the technical idea of the semiconductor device 1B is combined with the configuration of the semiconductor device 1D. Similar to the semiconductor device 1D, the semiconductor device 1E includes a plurality of pad well regions 80 and a plurality of pad capacitor structures 84 formed in a plurality of pad regions 11, respectively.

Similar to the semiconductor device 1D, the pad capacitor structure 84 includes a plurality of capacitor structures 85, a plurality of first capacitor electrode films 90, a main surface insulating film 48, a plurality of side wall dielectric films 91, a plurality of second capacitor electrode films 92, an interlayer film 57, a plurality of pad openings 93, a plurality of pad via electrodes 94, and a pad electrode 95. The semiconductor device 1B may include at least one of the plurality of capacitor structures 85 (see FIGS. 14 and 20A to 20M) according to the first to fourteenth layout examples.

Similar to the semiconductor device 1A, the pad capacitor structure 84 includes a plurality of first capacitor electrode films 90. In this embodiment, the pad capacitor structure 84 includes one or a plurality of (in this embodiment, a plurality of) first capacitor electrode films 90A on one side and one or a plurality of (in this embodiment, a plurality of) first capacitor electrode films 90B on the other side.

Each of the plurality of first capacitor electrode films 90A on one side has a relatively large first width W1 in cross-sectional view, and the plurality of first capacitor electrode films 90A are arranged at intervals on a first main surface 3. The plurality of first capacitor electrode films 90A sandwich one or a plurality of (in this embodiment, one) capacitor structures 85 in cross-sectional view.

For example, the number of capacitor structures 85 interposed in the regions between the plurality of first capacitor electrode films 90A may be 1, 2, 3, 4, 5, 6, 7, 8, 9, or 10 (in this embodiment, 1).

The plurality of first capacitor electrode films 90A cover the plurality of capacitor structures 85 in one-to-many correspondence in cross-sectional view. That is, the plurality of first capacitor electrode films 90A respectively cover the plurality of adjacent capacitor structures 85 in cross-sectional view.

For example, the plurality of first capacitor electrode films 90A may cover two, three, four, five, six, seven, eight, nine, or ten capacitor structures 85 (in this embodiment, two). As a matter of course, the plurality of first capacitor electrode films 90A may cover different numbers (two or more) of capacitor structures 85, respectively.

The plurality of first capacitor electrode films 90A have portions covering capacitor embedded electrodes 88 of the corresponding plurality of capacitor structures 85 and portions covering the main surface insulating film 48. In this embodiment, the plurality of first capacitor electrode films 90A are formed integrally with the corresponding plurality of capacitor embedded electrodes 88 as projecting portions projecting above the height position of the first main surface 3 from the corresponding plurality of capacitor embedded electrodes 88.

The plurality of first capacitor electrode films 90A face the first main surface 3 (pad well region 80) with the main surface insulating film 48 interposed therebetween. That is, the plurality of first capacitor electrode films 90A extend over the plurality of adjacent capacitor structures 85, and form a capacitive coupling with the chip 2 (pad well region 80) through the main surface insulating film 48 in the region between the plurality of adjacent capacitor structures 85.

Each of the plurality of first capacitor electrode films 90B on the other side has a second width W2 that is smaller than the first width W1 in cross-sectional view, and the plurality of first capacitor electrode films 90B are arranged at intervals on the first main surface 3. The plurality of first capacitor electrode films 90B cover the plurality of capacitor structures 85 other than the plurality of capacitor structures 85 connected to the plurality of first capacitor electrode films 90A in one-to-one correspondence.

The plurality of first capacitor electrode films 90B have portions covering capacitor embedded electrodes 88 of the corresponding capacitor structures 85 and portions covering the main surface insulating film 48. The plurality of first capacitor electrode films 90B are formed integrally with the corresponding capacitor embedded electrodes 88 as projecting portions projecting above the height position of the first main surface 3 from the corresponding capacitor embedded electrodes 88.

The plurality of first capacitor electrode films 90B face the first main surface 3 (pad well region 80) with the main surface insulating film 48 interposed therebetween. The facing area of the first capacitor electrode film 90B with respect to the first main surface 3 is smaller than the facing area of the first capacitor electrode film 90A with respect to the first main surface 3. The plurality of first capacitor electrode films 90B form a capacitive coupling with the chip 2 (pad well region 80) through the main surface insulating film 48.

A width ratio W2/W1 of the second width W2 to the first width W1 may be 0.1 or more and less than 1. The width ratio W2/W1 may have a value belonging to at least one of the following ranges, 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, 0.7 or more and 0.8 or less, 0.8 or more and 0.9 or less, and 0.9 or more and less than 1.

Similar to the semiconductor device 1D, the pad capacitor structure 84 includes a plurality of second capacitor electrode films 92. In this embodiment, the plurality of second capacitor electrode films 92 have substantially equal widths.

As a matter of course, the plurality of second capacitor electrode films 92 may have different widths. The plurality of second capacitor electrode films 92 are respectively arranged in regions between the plurality of first capacitor electrode films 90A and the plurality of first capacitor electrode films 90B adjacent to one another on the main surface insulating film 48.

The plurality of second capacitor electrode films 92 face the first capacitor electrode film 90A through the side wall dielectric film 91 in one direction in the horizontal direction (first direction X), and form a capacitive coupling with the first capacitor electrode film 90A through the side wall dielectric film 91. The plurality of second capacitor electrode films 92 face the first capacitor electrode film 90B through the side wall dielectric film 91 in the other direction in the horizontal direction (first direction X), and form a capacitive coupling with the first capacitor electrode film 90B through the side wall dielectric film 91.

Similar to the semiconductor device 1D, the pad electrode 95 is arranged on the interlayer film 57, and is electrically connected to the plurality of second capacitor electrode films 92 through the plurality of pad via electrodes 94. In addition, the configuration of the semiconductor device 1E is similar to the configuration of the semiconductor device 1D. In the semiconductor device 1E, the capacitance value of the pad region 11 is appropriately adjusted by appropriately adjusting the number of first capacitor electrode films 90A, the number of first capacitor electrode films 90B, the first width W1, the second width W2, and the like.

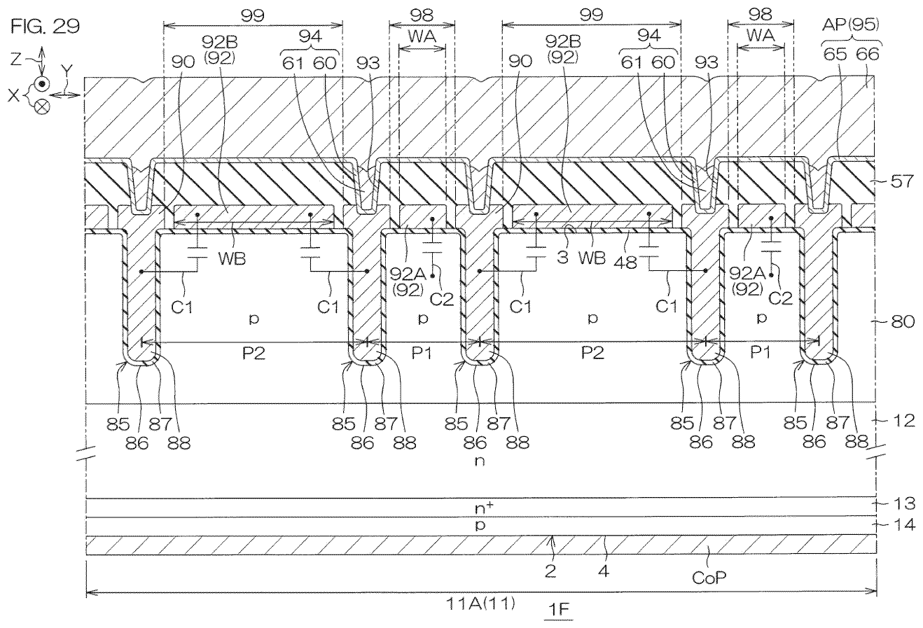

FIG. 29 is a cross-sectional view showing a main portion of a semiconductor device 1F according to a sixth embodiment. The semiconductor device 1F has a form in which the technical idea of the semiconductor device 1C is combined with the configuration of the semiconductor device 1D. The configuration of the semiconductor device 1F is also applicable to the semiconductor device 1E. Similar to the semiconductor device 1D, the semiconductor device 1F includes a plurality of pad well regions 80 and a plurality of pad capacitor structures 84 formed in a plurality of pad regions 11, respectively.

Similar to the semiconductor device 1D, the pad capacitor structure 84 includes a plurality of capacitor structures 85, a plurality of first capacitor electrode films 90, a main surface insulating film 48, a plurality of side wall dielectric films 91, a plurality of second capacitor electrode films 92, an interlayer film 57, a plurality of pad openings 93, a plurality of pad via electrodes 94, and a pad electrode 95. The semiconductor device 1F may include at least one of the plurality of capacitor structures 85 (see FIGS. 14 and 20A to 20M) according to the first to fourteenth layout examples.

In this embodiment, the pad capacitor structure 84 includes a plurality of capacitor structures 85 aligned at different pitches from one another in cross-sectional view. The pitch is a distance in the horizontal direction between central portions of the plurality of adjacent capacitor structures 85 in cross-sectional view.

In this embodiment, the pad capacitor structure 84 includes a plurality of capacitor structures 85 adjacent to each other at a first pitch P1 in cross-sectional view, and a plurality of capacitor structures 85 adjacent to each other at a second pitch P2 larger than the first pitch P1 in cross-sectional view. The plurality of capacitor structures 85 adjacent to each other at the second pitch P2 are adjacent to the plurality of capacitor structures 85 adjacent to each other at the first pitch P1 in the second direction Y.

In this embodiment, the plurality of capacitor structures 85 adjacent to each other at the second pitch P2 are alternately aligned in the second direction Y with the plurality of capacitor structures 85 adjacent to each other at the first pitch P1. As a matter of course, the pad capacitor structure 84 may include any one or both of a region in which three or more capacitor structures 85 are aligned at the first pitch P1 and a region in which three or more capacitor structures 85 are aligned at the second pitch P2.

The first pitch P1 may be 1 μm or more and 5 μm or less. The first pitch P1 may have a value belonging to at least one of the following ranges, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less. The first pitch P1 is preferably 1.5 μm or more and 3.5 μm or less.

A pitch ratio P2/P1 of the second pitch P2 to the first pitch P1 may be more than 1 and not more than 5. The pitch ratio P2/P1 may have a value belonging to at least one of the following ranges, more than 1 and not more than 1.5, 1.5 or more and 2 or less, 2 or more and 2.5 or less, 2.5 or more and 3 or less, 3 or more and 3.5 or less, 3.5 or more and 4 or less, 4 or more and 4.5 or less, and 4.5 or more and 5 or less.

Similar to the semiconductor device 1D, the semiconductor device 1F includes a plurality of first capacitor electrode films 90. The semiconductor device 1F includes a plurality of first capacitor electrode films 90 adjacent to each other at the first pitch P1 in cross-sectional view, and a plurality of first capacitor electrode films 90 adjacent to each other at the second pitch P2 in cross-sectional view according to the layout of the plurality of capacitor structures 85.

The plurality of first capacitor electrode films 90 adjacent to each other at the first pitch P1 define a first region 98 having a relatively narrow width. The plurality of first capacitor electrode films 90 adjacent to each other at the second pitch P2 define a second region 99 that is wider than the first region 98.

Similar to the semiconductor device 1A, the pad capacitor structure 84 includes a plurality of second capacitor electrode films 92. In this embodiment, the pad capacitor structure 84 includes one or a plurality of (in this embodiment, a plurality of) second capacitor electrode films 92A on one side and one or a plurality of (in this embodiment, a plurality of) second capacitor electrode films 92B on the other side.

Each of the plurality of second capacitor electrode films 92A on one side has a relatively small first width WA, and the plurality of second capacitor electrode films 92A are arranged in a plurality of the first regions 98, respectively. The plurality of second capacitor electrode films 92A face the plurality of first capacitor electrode films 90 through the plurality of side wall dielectric films 91, and form a capacitive coupling with the plurality of first capacitor electrode films 90 through the plurality of side wall dielectric films 91. The plurality of second capacitor electrode films 92A form a first capacitor C1 with the plurality of first capacitor electrode films 90.

Each of the plurality of second capacitor electrode films 92B on the other side has a second width WB larger than the first width WA, and the plurality of second capacitor electrode films 92B are arranged in a plurality of the second regions 99, respectively. The facing area of the second capacitor electrode film 92B with respect to the chip 2 (pad well region 80) is larger than the facing area of the second capacitor electrode film 92A with respect to the chip 2 (pad well region 80).

The plurality of second capacitor electrode films 92B face the plurality of first capacitor electrode films 90 through the plurality of side wall dielectric films 91, and form a capacitive coupling with the first capacitor electrode films 90 through the plurality of side wall dielectric films 91. The plurality of second capacitor electrode films 92A form a second capacitor C2 with the plurality of first capacitor electrode films 90.

The second width WB may be larger than the first pitch P1 and equal to or smaller than the second pitch P2. A width ratio WB/WA of the second width WB to the first width WA may be more than 1 and not more than 5. The width ratio WB/WA may have a value belonging to at least one of the following ranges, more than 1 and not more than 1.5, 1.5 or more and 2 or less, 2 or more and 2.5 or less, 2.5 or more and 3 or less, 3 or more and 3.5 or less, 3.5 or more and 4 or less, 4 or more and 4.5 or less, and 4.5 or more and 5 or less.

Similar to the semiconductor device 1D, the pad electrode 95 is arranged on the interlayer film 57, and is electrically connected to the plurality of second capacitor electrode films 92 through the plurality of pad via electrodes 94. In addition, the configuration of the semiconductor device 1F is similar to the configuration of the semiconductor device 1D. In the semiconductor device 1F, the capacitance value of the pad region 11 is appropriately adjusted by appropriately adjusting the first pitch P1, the second pitch P2, the first width WA, the second width WB, and the like.

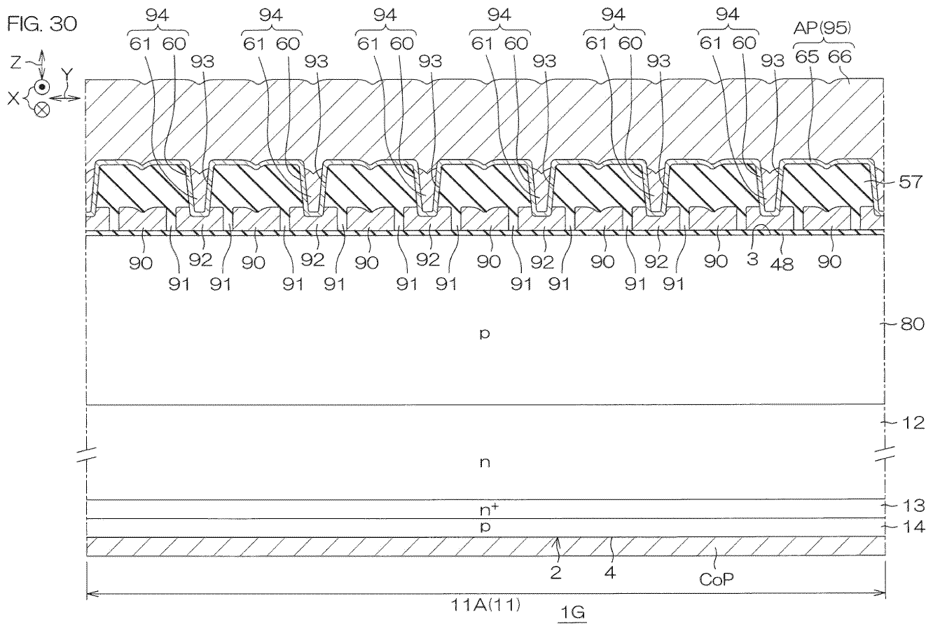

FIG. 30 is a cross-sectional view showing a main portion of a semiconductor device 1G according to a seventh embodiment. The semiconductor device 1G has a modified form of the above-described semiconductor device 1A. Similar to the semiconductor device 1A, the semiconductor device 1G includes pad well regions 80 and pad capacitor structures 84 formed in a plurality of pad regions 11, respectively. The semiconductor device 1G may include at least one of the pad capacitor structures 84 according to the first to fourteenth layout examples.

Similar to the semiconductor device 1A (first to fourteenth layout examples), the pad capacitor structure 84 includes a main surface insulating film 48, a plurality of first capacitor electrode films 90, a plurality of side wall dielectric films 91, a plurality of second capacitor electrode films 92, an interlayer film 57, a plurality of pad openings 93, a plurality of pad via electrodes 94, and a pad electrode 95. Unlike the semiconductor device 1A (first to fourteenth layout examples), the pad capacitor structure 84 has no capacitor structure 85.

In this embodiment, each of the plurality of first capacitor electrode films 90 has a lead-out portion led out from the pad region 11 to the active region 6, and is electrically connected to at least one of the emitter structure 30, the emitter connection structure 35, and the emitter wiring 55 in the active region 6.

For example, the plurality of first capacitor electrode films 90 may be led out to the active region 6 through an open portion of the gate connection structure 25 where the gate connection structure 25 does not exist. Therefore, an emitter potential is to be applied to the plurality of first capacitor electrode films 90 through the plurality of emitter structures 30. In addition, the configuration of the semiconductor device 1G is similar to that of the semiconductor device 1A.

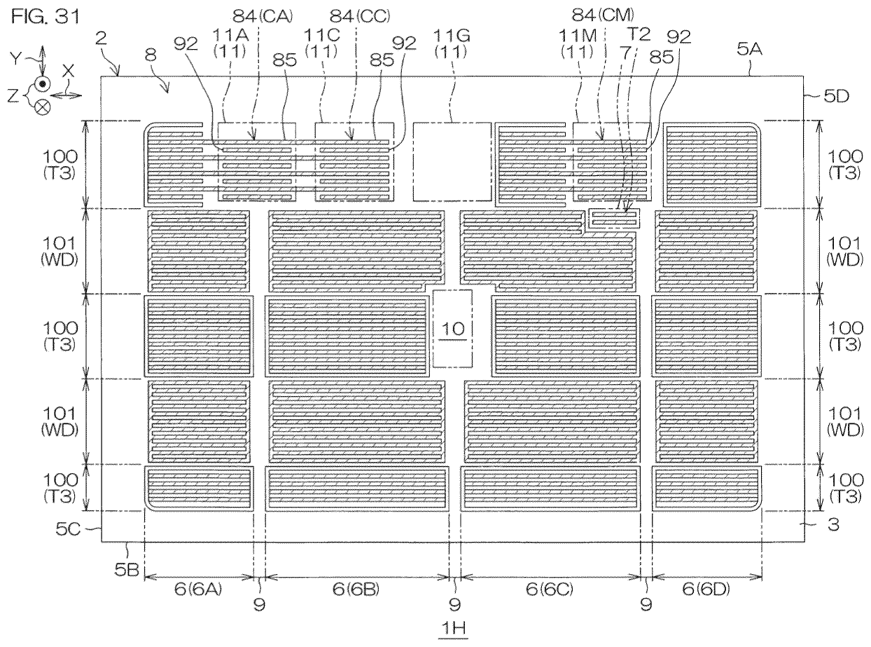

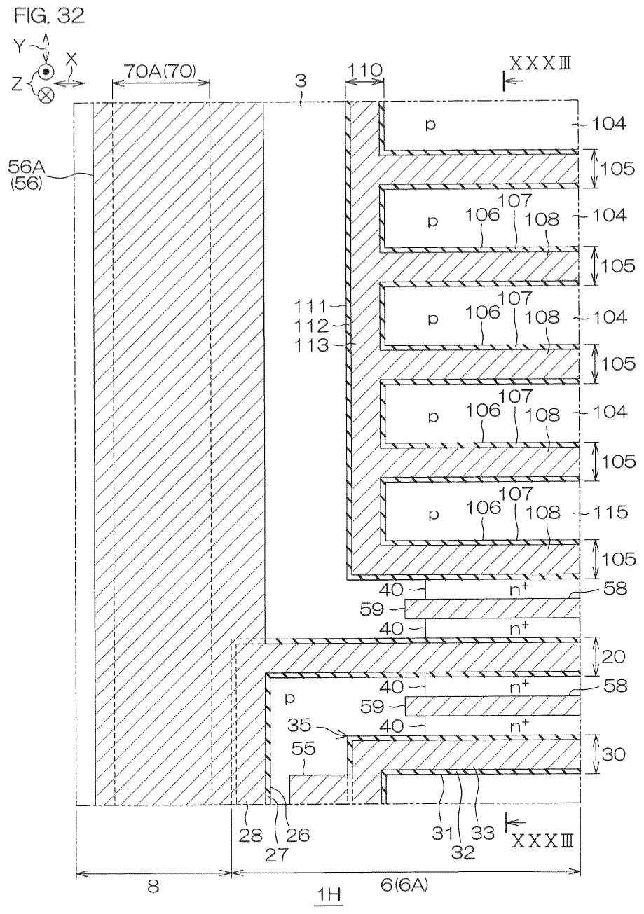

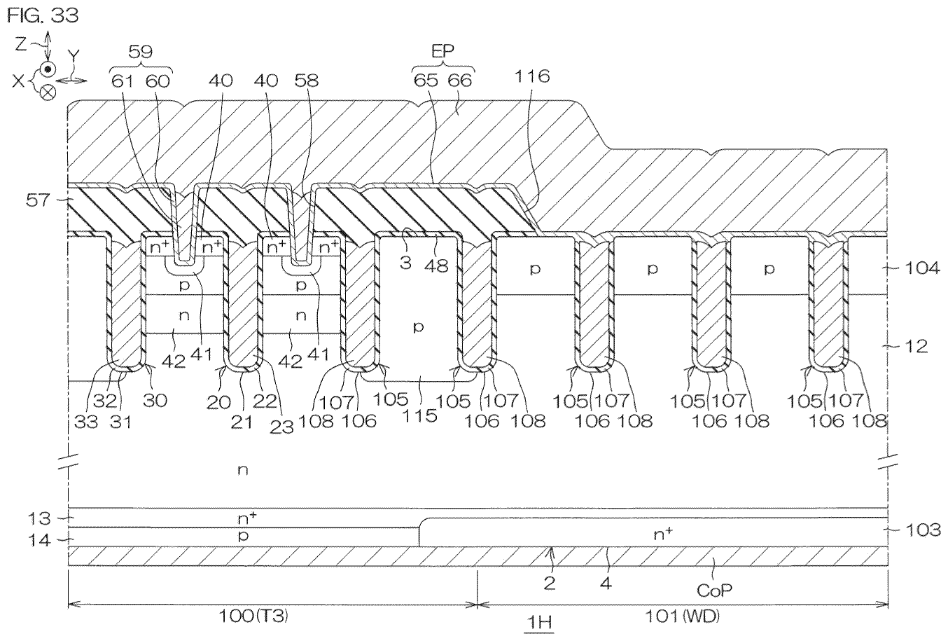

FIG. 31 is a plan view showing a layout example of the first main surface 3 of a semiconductor device 1H according to an eighth embodiment. FIG. 32 is an enlarged plan view showing a main portion of the active region 6 of the semiconductor device 1H shown in FIG. 31. FIG. 33 is a cross-sectional view taken along line XXXIII-XXXIII shown in FIG. 32. The semiconductor device 1H is a semiconductor switching device including the main transistor structure T1 as a reverse conducting-IGBT (RC-IGBT) structure having the transistor structure T3 and a freewheeling diode structure WD.

The semiconductor device 1H includes one or a plurality of (in this embodiment, a plurality of) transistor regions 100 respectively provided in the plurality of active regions 6, and one or a plurality of (in this embodiment, a plurality of) freewheeling diode regions 101 respectively provided in each of the plurality of active regions 6. The plurality of transistor regions 100 are regions including the above-described transistor structure T3. The plurality of transistor regions 100 are provided at an interval in the second direction Y in the corresponding active region 6.

With respect to the plurality of active regions 6 adjacent to each other, the plurality of transistor regions 100 arranged in one active region 6 each oppose the plurality of transistor regions 100 arranged in the other active region 6 in the first direction X in a one-to-one correspondence. That is, the plurality of transistor regions 100 are arranged in a matrix at an interval in the first direction X and the second direction Y in the first main surface 3.

The plurality of freewheeling diode regions 101 are regions including the freewheeling diode structure WD. The plurality of freewheeling diode regions 101 are respectively provided in regions adjacent to one or the plurality of transistor regions 100 in the second direction Y in the corresponding active region 6. Specifically, the plurality of freewheeling diode regions 101 and the plurality of transistor regions 100 are alternately arranged in the second direction Y.

With respect to the plurality of active regions 6 adjacent to each other, the plurality of freewheeling diode regions 101 arranged in one active region 6 each oppose the plurality of freewheeling diode regions 101 arranged in the other active region 6 in the first direction X in a one-to-one correspondence. That is, the plurality of freewheeling diode regions 101 are arranged in a matrix at an interval in the first direction X and the second direction Y in the first main surface 3. As a matter of course, the plurality of freewheeling diode regions 101 may oppose the plurality of transistor regions 100 in the first direction X.

In each transistor region 100, the semiconductor device 1H includes the base region 15, the plurality of gate structures 20, the plurality of gate connection structures 25, the plurality of emitter structures 30, the plurality of emitter connection structures 35, the plurality of emitter regions 40, the contact region 41, the plurality of storage regions 42, and the plurality of well regions 43.

The layout of these constituent elements in the transistor region 100 is similar to the layout of the corresponding constituent elements in the active region 6 according to the first embodiment. For the description of the layout of these constituent elements in the transistor region 100, the description of the layout of the corresponding constituent element in the active region 6 according to the first embodiment is applied.

The semiconductor device 1H includes an n-type freewheeling cathode region 103 formed in the surface layer portion of the second main surface 4 in the freewheeling diode region 101. The freewheeling cathode region 103 has an n-type impurity concentration higher than the n-type impurity concentration of the drift region 12.

The n-type impurity concentration of the freewheeling cathode region 103 may be higher than the n-type impurity concentration of the buffer region 13. In this embodiment, the freewheeling cathode region 103 has an n-type impurity concentration higher than the p-type impurity concentration of the collector region 14, and replaces the conductivity type of the collector region 14 from the p-type to the n-type.

The freewheeling cathode region 103 penetrates the collector region 14 and is electrically connected to the drift region 12. In this embodiment, the freewheeling cathode region 103 has an upper end portion located within the buffer region 13 and is electrically connected to the drift region 12 via the buffer region 13. The freewheeling cathode region 103 may have an upper end portion that penetrates the buffer region 13 and is located within the drift region 12.

The semiconductor device 1H includes the freewheeling diode structure WD formed in the first main surface 3 in the freewheeling diode region 101. Hereinafter, a configuration of one freewheeling diode structure WD as one constituent element of the semiconductor device 1H will be described.

The freewheeling diode structure WD includes a p-type freewheeling anode region 104 formed in the surface layer portion of the first main surface 3 in the freewheeling diode region 101. The freewheeling anode region 104 is formed in a surface layer portion of the drift region 12. In this embodiment, the freewheeling anode region 104 has a p-type impurity concentration higher than the n-type impurity concentration of the drift region 12, and the conductivity type of the drift region 12 is replaced from the n-type to the p-type.

The p-type impurity concentration of the freewheeling anode region 104 may be substantially equal to the p-type impurity concentration of the base region 15. As a matter of course, the p-type impurity concentration of the freewheeling anode region 104 may be higher than the p-type impurity concentration of the base region 15, or may be lower than the p-type impurity concentration of the base region 15.

The freewheeling anode regions 104 are respectively formed in a layer shape extending along the first main surface 3 in the freewheeling diode region 101, and oppose the freewheeling cathode region 103 with the drift region 12 interposed therebetween in the thickness direction. The freewheeling anode region 104 is formed at an interval on the first main surface 3 side from the depth position of the intermediate portion of the drift region 12.

The freewheeling anode region 104 may have a depth substantially equal to the depth of the base region 15. As a matter of course, the depth of the freewheeling anode region 104 may be larger than the depth of the base region 15, or may be smaller than the depth of the base region 15. The depth of the freewheeling anode region 104 is preferably smaller than the depth of the well region 43. As a matter of course, the depth of the freewheeling anode region 104 may be substantially equal to the depth of the well region 43, or may be larger than the depth of the well region 43.

The freewheeling diode structure WD includes a plurality of trench electrode type anode structures 105 formed in the first main surface 3 in the freewheeling diode region 101. An emitter potential is to be applied to the plurality of anode structures 105. The plurality of anode structures 105 each extend in a band shape in the first direction X in the anode pad region 11A, and are arranged at an interval in the second direction Y.

That is, the plurality of anode structures 105 are arranged in a stripe shape extending in the first direction X. The extension direction of the plurality of anode structures 105 coincides with the extension direction of the plurality of gate structures 20. The extension direction of the plurality of anode structures 105 coincides with the extension direction of the plurality of emitter structures 30.

The plurality of anode structures 105 may each have a width less than the widths of the plurality of street regions 9. The width of the anode structure 105 is a width in a direction (second direction Y) orthogonal to the extension direction (first direction X) of the anode structure 105.

The width of the anode structure 105 may be substantially equal to the width of the gate structure 20 (gate connection structure 25). As a matter of course, the width of the anode structure 105 may be larger than the width of the gate structure 20 (gate connection structure 25), or may be smaller than the width of the gate structure 20 (gate connection structure 25).

The width of the anode structure 105 may be substantially equal to the width of the emitter structure 30 (emitter connection structure 35). As a matter of course, the width of the anode structure 105 may be larger than the width of the emitter structure 30 (emitter connection structure 35), or may be smaller than the width of the emitter structure 30 (emitter connection structure 35).

The width of the anode structure 105 may be 0.5 μm or more and 5 μm or less. The width of the anode structure 105 may have a value belonging to at least one of the ranges of 0.5 μm or more and 1 μm or less, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less. The width of the anode structure 105 is preferably 1 μm or more and 2.5 μm or less.

The plurality of anode structures 105 penetrate the freewheeling anode region 104 to reach the drift region 12. The plurality of anode structures 105 are respectively formed at an interval on the first main surface 3 side from the depth position of the intermediate portion of the drift region 12. The plurality of anode structures 105 oppose the freewheeling cathode region 103 with a part of the drift region 12 interposed therebetween in the thickness direction.

The plurality of anode structures 105 may be formed in a tapered shape toward the bottom wall. As a matter of course, the plurality of anode structures 105 may be formed substantially perpendicular to the first main surface 3.

The bottom walls of the plurality of anode structures 105 may be formed in a curved shape toward the second main surface 4. As a matter of course, the bottom walls of the plurality of anode structures 105 may be formed substantially parallel to the first main surface 3. In this case, the bottom wall corner portions of the plurality of anode structures 105 may be formed in a curved shape.

The plurality of anode structures 105 may have a depth substantially equal to the depths of the plurality of gate structures 20 (gate connection structures 25). As a matter of course, the depth of the anode structure 105 may be larger than the depth of the gate structure 20 (gate connection structure 25), or may be smaller than the depth of the gate structure 20 (gate connection structure 25).

The depth of the anode structure 105 may be substantially equal to the depth of the emitter structure 30 (emitter connection structure 35). As a matter of course, the depth of the anode structure 105 may be larger than the depth of the emitter structure 30 (emitter connection structure 35), or may be smaller than the depth of the emitter structure 30 (emitter connection structure 35).

The depth of the anode structure 105 may be 0.5 μm or more and 10 μm or less. The depth of the anode structure 105 may have a value belonging to at least one of the ranges of 0.5 μm or more and 1 μm or less, 1 μm or more and 2 μm or less, 2 μm or more and 4 μm or less, 4 μm or more and 6 μm or less, 6 μm or more and 8 μm or less, and 8 μm or more and 10 μm or less. The depth of the anode structure 105 is preferably 4 μm or more and 8 μm or less.

A third trench pitch between the central portions of the plurality of anode structures 105 may be substantially equal to the first trench pitch between the central portion of the gate structure 20 and the central portion of the emitter structure 30. As a matter of course, the third trench pitch may be larger than the first trench pitch, or may be smaller than the first trench pitch.

The third trench pitch may be 1 μm or more and 5 μm or less. The third trench pitch may have a value belonging to at least one of the ranges of 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less. The third trench pitch is preferably 1.5 μm or more and 3.5 μm or less.

The plurality of anode structures 105 each include an anode trench 106, an anode insulating film 107, and an anode embedded electrode 108. The anode trench 106 is formed in the first main surface 3 and defines the wall surface (side wall and bottom wall) of the anode structure 105.

The anode insulating film 107 may include at least one of a silicon oxide film, a silicon nitride film, and a silicon oxynitride film. The anode insulating film 107 preferably includes the same type of insulator as the gate insulating film 22 (emitter insulating film 32). In this embodiment, the anode insulating film 107 has a single-layer structure formed of a silicon oxide film. The anode insulating film 107 particularly preferably includes a silicon oxide film that is constituted of the oxide of the chip 2.

The anode insulating film 107 covers the wall surface of the anode trench 106. The thickness of the anode insulating film 107 may be substantially equal to the thickness of the gate insulating film 22 (gate connection insulating film 27). As a matter of course, the thickness of the anode insulating film 107 may be larger than the thickness of the gate insulating film 22 (gate connection insulating film 27), or may be smaller than the thickness of the gate insulating film 22 (gate connection insulating film 27).

The thickness of the anode insulating film 107 may be substantially equal to the thickness of the emitter insulating film 32 (emitter connection insulating film 37). As a matter of course, the thickness of the anode insulating film 107 may be larger than the thickness of the emitter insulating film 32 (emitter connection insulating film 37), or may be smaller than the thickness of the emitter insulating film 32 (emitter connection insulating film 37).

The thickness of the anode insulating film 107 may be 10 nm or more and 200 nm or less. The thickness of the anode insulating film 107 may have a value belonging to at least one of the ranges of 10 nm or more and 25 nm or less, 25 nm or more and 50 nm or less, 50 nm or more and 75 nm or less, 75 nm or more and 100 nm or less, 100 nm or more and 125 nm or less, 125 nm or more and 150 nm or less, 150 nm or more and 175 nm or less, and 175 nm or more and 200 nm or less. The thickness of the anode insulating film 107 is preferably 100 nm or more and 150 nm or less.

The anode embedded electrode 108 is embedded in the anode trench 106 with the anode insulating film 107 interposed therebetween. The anode embedded electrode 108 opposes the drift region 12 and the freewheeling anode region 104 with the anode insulating film 107 interposed therebetween.

The electrode surface of the anode embedded electrode 108 may be located on the bottom wall side of the anode trench 106 with respect to the first main surface 3. The anode embedded electrode 108 may contain one or both of the p-type conductive polysilicon and the n-type conductive polysilicon. The anode embedded electrode 108 preferably contains the same type of conductor as the gate embedded electrode 23.

The freewheeling diode structure WD includes a plurality of trench electrode type anode connection structures 110 formed in the first main surface 3 to be connected to the plurality of anode structures 105. An emitter potential is to be applied to the plurality of anode connection structures 110. The anode connection structure 110 may be referred to as a “trench anode connection structure.”

The plurality of anode connection structures 110 are respectively arranged on both end portion sides of the plurality of anode structures 105 to be connected to one end portion and the other end portion of the plurality of anode structures 105 in the first direction X, and define the corresponding freewheeling diode region 101 together with the plurality of outermost anode structures 105.

The plurality of anode connection structures 110 includes an anode connection structure 110 on one end portion side of the plurality of anode structures 105 and an anode connection structure 110 on the other end portion side of the plurality of anode structures 105 in the first direction X. The anode connection structure 110 on one end portion side extends in a band shape in the second direction Y and is connected to one end portions of the plurality of anode structures 105. The anode connection structure 110 on the other end portion side extends in a band shape in the second direction Y and is connected to the other end portions of the plurality of anode structures 105.

The plurality of anode connection structures 110 may each have a width substantially equal to a width of the anode structure 105 (gate structure 20). As a matter of course, the width of the anode connection structure 110 may be larger than the width of the anode structure 105, or may be smaller than the width of the anode structure 105.

The width of the anode connection structure 110 may be 0.5 μm or more and 5 μm or less. The width of the anode connection structure 110 may have a value belonging to at least one of the ranges of 0.5 μm or more and 1 μm or less, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less. The width of the anode connection structure 110 is preferably 1 μm or more and 2.5 μm or less.

The plurality of anode connection structures 110 penetrate the freewheeling anode region 104 to reach the drift region 12. The plurality of anode connection structures 110 are respectively formed at an interval on the first main surface 3 side from the depth position of the intermediate portion of the drift region 12, and oppose the freewheeling cathode region 103 with a part of the drift region 12 interposed therebetween in the thickness direction.

The plurality of anode connection structures 110 may be formed in a tapered shape toward the bottom wall. As a matter of course, the plurality of anode connection structures 110 may be formed substantially perpendicular to the first main surface 3.

The plurality of anode connection structures 110 may have a bottom wall formed in a curved shape toward the second main surface 4. As a matter of course, the bottom walls of the plurality of anode connection structures 110 may be formed substantially parallel to the first main surface 3. In this case, the bottom wall corner portions of the plurality of anode connection structures 110 may be formed in a curved shape.

The plurality of anode connection structures 110 may each have a depth substantially equal to the depth of the anode structure 105 (gate structure 20). As a matter of course, the depth of the anode connection structure 110 may be larger than the depth of the anode structure 105, or may be smaller than the depth of the anode structure 105.

The depth of the anode connection structure 110 may be 0.5 μm or more and 10 μm or less. The depth of the anode connection structure 110 may have a value belonging to at least one of the ranges of 0.5 μm or more and 1 μm or less, 1 μm or more and 2 μm or less, 2 μm or more and 4 μm or less, 4 μm or more and 6 μm or less, 6 μm or more and 8 μm or less, and 8 μm or more and 10 μm or less. The depth of the anode connection structure 110 is preferably 4 μm or more and 8 μm or less.

The plurality of anode connection structures 110 each include an anode connection trench 111, an anode connection insulating film 112, and an anode connection embedded electrode 113. The anode connection trench 111 is formed in the first main surface 3 and defines the wall surface (side wall and bottom wall) of the anode connection structure 110. The anode connection trench 111 communicates with the plurality of anode trenches 106.

The anode connection insulating film 112 may include at least one of a silicon oxide film, a silicon nitride film, and a silicon oxynitride film. The anode connection insulating film 112 preferably includes the same type of insulator as the anode insulating film 107 (gate insulating film 22). In this embodiment, the anode connection insulating film 112 has a single-layer structure formed of a silicon oxide film. The anode connection insulating film 112 particularly preferably includes a silicon oxide film formed of the oxide of the chip 2.

The anode connection insulating film 112 covers the wall surface of the anode connection trench 111 in a film shape. The anode connection insulating film 112 is connected to the anode insulating film 107 at a communication portion between the anode trench 106 and the anode connection trench 111.

The anode connection insulating film 112 may have a thickness substantially equal to the thickness of the anode insulating film 107. As a matter of course, the thickness of the anode connection insulating film 112 may be larger than the thickness of the anode insulating film 107, or may be smaller than the thickness of the anode insulating film 107.

The anode connection insulating film 112 may have a thickness of 10 nm or more and 200 nm or less. The thickness of the anode connection insulating film 112 may have a value belonging to at least one of the ranges of 10 nm or more and 25 nm or less, 25 nm or more and 50 nm or less, 50 nm or more and 75 nm or less, 75 nm or more and 100 nm or less, 100 nm or more and 125 nm or less, 125 nm or more and 150 nm or less, 150 nm or more and 175 nm or less, and 175 nm or more and 200 nm or less. The thickness of the anode connection insulating film 112 is preferably 100 nm or more and 150 nm or less.

The anode connection embedded electrode 113 is embedded in the anode connection trench 111 with the anode connection insulating film 112 interposed therebetween. The anode connection embedded electrode 113 is connected to the anode embedded electrode 108 at a communication portion between the anode trench 106 and the anode connection trench 111.

The anode connection embedded electrode 113 opposes the drift region 12 and the freewheeling anode region 104 with the anode connection insulating film 112 interposed therebetween. The anode connection embedded electrode 113 is partially covered with the interlayer film 57.

The electrode surface of the anode connection embedded electrode 113 may be located on the bottom wall side of the anode connection trench 111 with respect to the first main surface 3. The anode connection embedded electrode 113 may contain one or both of the p-type conductive polysilicon and the n-type conductive polysilicon. The anode connection embedded electrode 113 preferably contains the same type of conductor as the anode embedded electrode 108.

The freewheeling diode structure WD includes a p-type boundary well region 115 formed in the surface layer portion of the first main surface 3 in the freewheeling diode region 101. The boundary well region 115 may have a p-type impurity concentration higher than the p-type impurity concentration of the base region 15.

As a matter of course, the p-type impurity concentration of the boundary well region 115 may be lower than the p-type impurity concentration of the base region 15. The p-type impurity concentration of the boundary well region 115 may be substantially equal to the p-type impurity concentration of the well region 43. In this embodiment, the boundary well region 115 is formed in an electrically floating state.

The boundary well region 115 is formed in a region between the pair of adjacent anode structures 105 in the transistor region 100 among the plurality of anode structures 105. Specifically, the boundary well region 115 is formed in a mesa region defined by the pair of anode structures 105 and the pair of anode connection structures 110.

The boundary well regions 115 each have a bottom portion located on the bottom wall side of the plurality of anode structures 105 with respect to the depth position of the bottom portion of the base region 15. The bottom portions of the plurality of anode regions 51 are located closer to the bottom wall side of the plurality of anode structures 105 than the depth position of the intermediate portions of the plurality of anode structures 105. In this embodiment, the bottom portion of the boundary well region 115 is located on the second main surface 4 side with respect to the bottom walls of the plurality of anode structures 105.

The boundary well regions 115 each extend in a band shape in the first direction X in conformance to the extension direction of the plurality of anode structures 105, and are connected to the plurality of anode structures 105 and the plurality of anode connection structures 110. The boundary well region 115 may have portions (bottom portions) covering the bottom walls of the plurality of anode structures 105 and the bottom walls of the plurality of anode connection structures 110.

The semiconductor device 1H includes the above-described main surface insulating film 48 that selectively covers the first main surface 3 in the freewheeling diode region 101. The main surface insulating film 48 covers the freewheeling anode region 104 and the boundary well region 115 in the freewheeling diode region 101. The main surface insulating film 48 is connected to the anode insulating film 107 and the anode connection insulating film 112 in the freewheeling diode region 101, and exposes the anode embedded electrode 108 and the anode connection embedded electrode 113.

The main surface insulating film 48 may have a thickness substantially equal to the thickness of the anode insulating film 107 (anode connection embedded electrode 113). As a matter of course, the thickness of the main surface insulating film 48 may be larger than the thickness of the anode insulating film 107 (anode connection embedded electrode 113), or may be smaller than the thickness of the anode insulating film 107 (anode connection embedded electrode 113).

The semiconductor device 1H includes the above-described interlayer film 57 that selectively covers the main surface insulating film 48 in the freewheeling diode region 101. The interlayer film 57 covers the freewheeling anode region 104 and the boundary well region 115 with the main surface insulating film 48 interposed therebetween in the freewheeling diode region 101. The interlayer film 57 selectively covers the plurality of anode structures 105 and the plurality of anode connection structures 110.

In this embodiment, the interlayer film 57 enters the plurality of anode trenches 106 and the plurality of anode connection trenches 111 from above the main surface insulating film 48. The interlayer film 57 has portions covering the electrode surfaces of the plurality of anode embedded electrodes 108 in the plurality of anode trenches 106. The interlayer film 57 has portions covering the electrode surfaces of the plurality of anode connection embedded electrodes 113 in the plurality of anode connection trenches 111.

The semiconductor device 1H includes a diode opening 116 formed in the interlayer film 57 in the freewheeling diode region 101. In this embodiment, the diode opening 116 exposes the inner portion of the anode region 51 and the inner portions of the plurality of anode structures 105.

The diode opening 116 may expose all of the anode structures 105. The above-described emitter pad EP enters the diode opening 116 from above the interlayer film 57 and is mechanically and electrically connected to the anode region 51 and the plurality of anode structures 105 in the diode opening 116.

In this embodiment, an example is shown in which a plurality of anode structures 105 and a plurality of anode connection structures 110 are formed, but the plurality of anode structures 105 and the plurality of anode connection structures 110 are not necessarily required and may be removed.

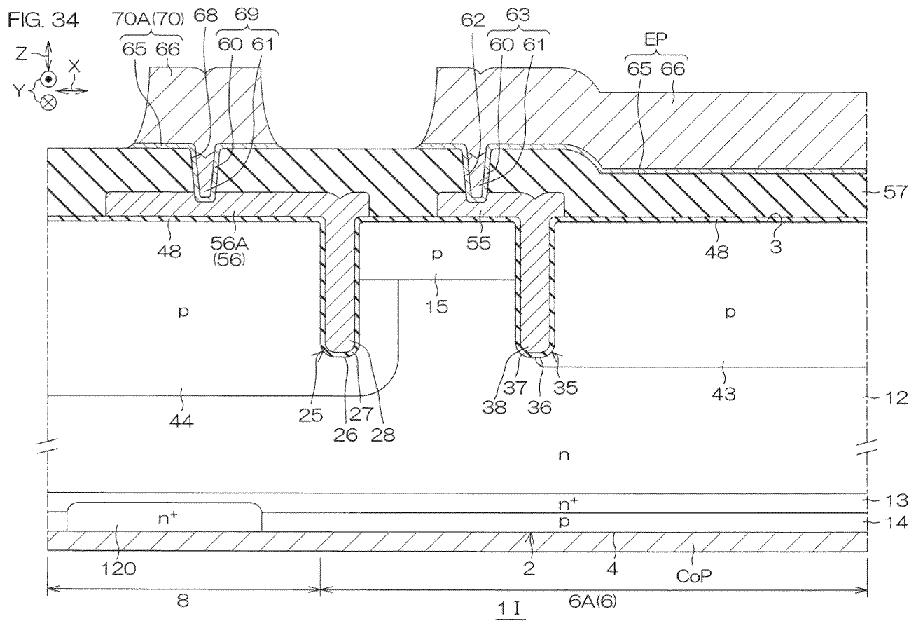

FIG. 34 is a cross-sectional view showing a main portion of a semiconductor device 1I according to an nineth embodiment. The semiconductor device 1I is a semiconductor switching device including the main transistor structure T1 as an RC-IGBT structure having the transistor structure T3 and the freewheeling diode structure WD. The configuration of the semiconductor device 1I may be combined with the semiconductor device 1H.

The semiconductor device 1I includes an n-type outer peripheral cathode region 120 formed in the surface layer portion of the second main surface 4 around the plurality of active regions 6. The outer peripheral cathode region 120 has an n-type impurity concentration higher than the n-type impurity concentration of the drift region 12.

The n-type impurity concentration of the outer peripheral cathode region 120 may be higher than the n-type impurity concentration of the buffer region 13. In this embodiment, the outer peripheral cathode region 120 has an n-type impurity concentration higher than the p-type impurity concentration of the collector region 14, and replaces the conductivity type of the collector region 14 from the p-type to the n-type.

The outer peripheral cathode region 120 is formed in a region opposing the outer peripheral well region 44 in the thickness direction of the chip 2 in the surface layer portion of the second main surface 4. The outer peripheral cathode region 120 is preferably formed to be narrower than the outer peripheral well region 44, and opposes the outer peripheral well region 44 at an interval inward from both ends of the outer peripheral well region 44. That is, the entire region of the outer peripheral cathode region 120 preferably opposes the outer peripheral well region 44 in the thickness direction in cross-sectional view.

The outer peripheral cathode region 120 penetrates the collector region 14 and is electrically connected to the drift region 12. In this embodiment, the outer peripheral cathode region 120 has an upper end portion located within the buffer region 13 and is electrically connected to the drift region 12 via the buffer region 13. The outer peripheral cathode region 120 may have an upper end portion that penetrates the buffer region 13 and is located within the drift region 12.

The outer peripheral cathode region 120 extends in a band shape along the peripheral edge of the first main surface 3 at an interval inward from the peripheral edge of the first main surface 3. In this embodiment, the outer peripheral cathode region 120 extends in a band shape in conformance to the extension direction of the outer peripheral well region 44 in plan view. The outer peripheral cathode region 120 may be formed in an annular shape surrounding the plurality of active regions 6.

As described above, the semiconductor device 1I may include the freewheeling diode structure WD including the outer peripheral well region 44 as an anode and the outer peripheral cathode region 120 as a cathode.

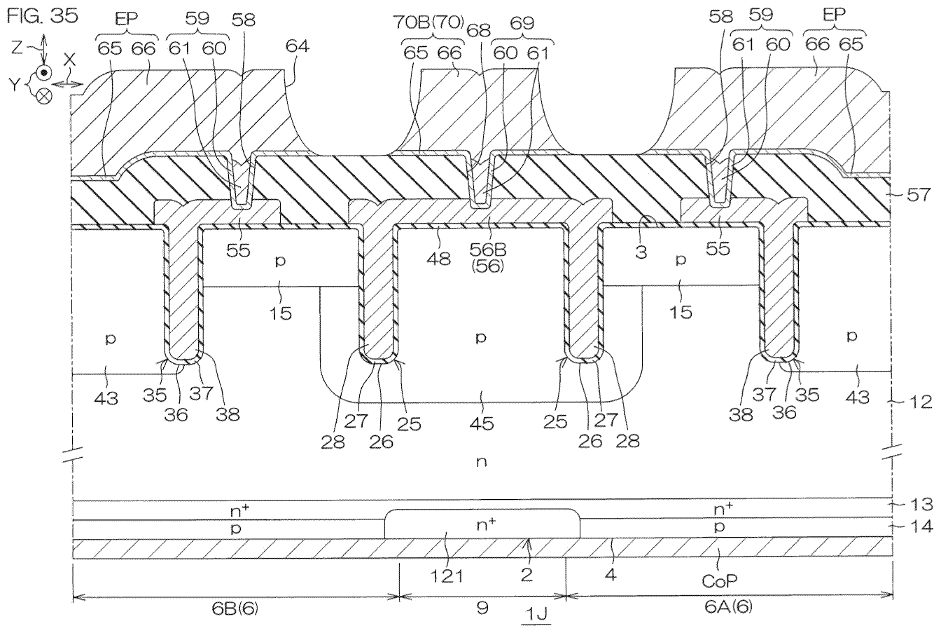

FIG. 35 is a cross-sectional view showing a main portion of a semiconductor device 1J according to a tenth embodiment. The semiconductor device 1J is a semiconductor switching device including the main transistor structure T1 as an RC-IGBT structure having the transistor structure T3 and the freewheeling diode structure WD. The configuration of the semiconductor device 1J may be combined with the semiconductor device 1H and the semiconductor device 1I.

The semiconductor device 1J includes an n-type street cathode region 121 formed in the surface layer portion of the second main surface 4 in the street region 9. The street cathode region 121 has an n-type impurity concentration higher than the n-type impurity concentration of the drift region 12.

The n-type impurity concentration of the street cathode region 121 may be higher than the n-type impurity concentration of the buffer region 13. In this embodiment, the street cathode region 121 has an n-type impurity concentration higher than the p-type impurity concentration of the collector region 14, and replaces the conductivity type of the collector region 14 from the p-type to the n-type.

The street cathode region 121 is formed in a region opposing the street well region 45 in the thickness direction of the chip 2 in the surface layer portion of the second main surface 4. The street cathode region 121 is preferably formed to be narrower than the street well region 45, and opposes the street well region 45 at an interval inward from both ends of the street well region 45.

The street cathode region 121 is preferably formed at an interval from the plurality of active regions 6. That is, the street cathode region 121 is preferably formed at an interval on the inner side of the street region 9 from the plurality of gate structures 20 and the plurality of gate connection structures 25. The entire region of the street cathode region 121 preferably opposes the street well region 45 in the thickness direction in cross-sectional view.

As a matter of course, the street cathode region 121 may have a width larger than the width of the street region 9, and have portions led out from the street region 9 into the plurality of active regions 6. In this case, the street cathode region 121 may oppose the plurality of gate structures 20 and the plurality of gate connection structures 25 in the thickness direction. The street cathode region 121 is formed in a band shape extending in the second direction Y in conformance to the extension direction of the street region 9.

The street cathode region 121 penetrates the collector region 14 and is electrically connected to the drift region 12. In this embodiment, the street cathode region 121 has an upper end portion located within the buffer region 13 and is electrically connected to the drift region 12 via the buffer region 13. The street cathode region 121 may have an upper end portion that penetrates the buffer region 13 and is located within the drift region 12.

As described above, the semiconductor device 1J may include the freewheeling diode structure WD including the street well region 45 as an anode and the street cathode region 121 as a cathode.

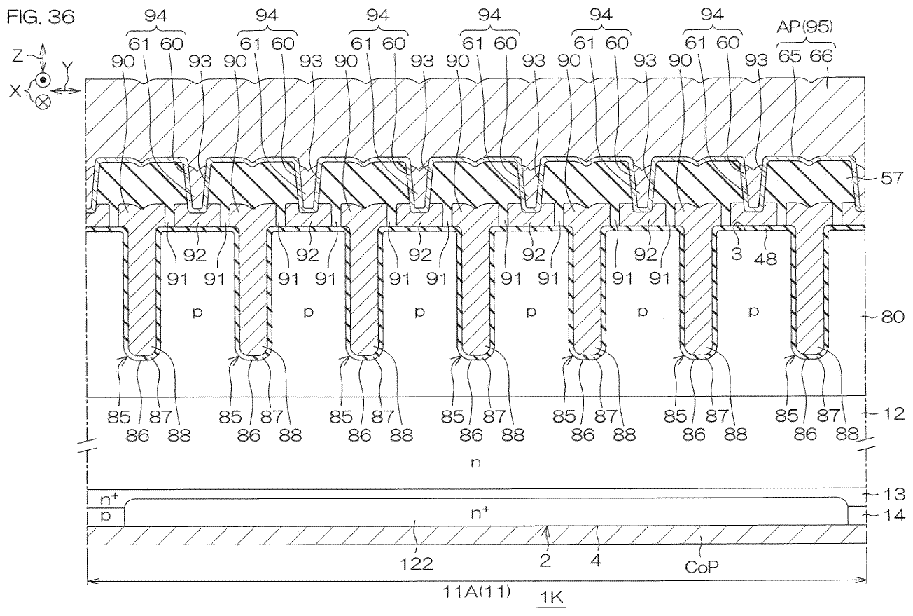

FIG. 36 is a cross-sectional view showing a main portion of a semiconductor device 1K according to a eleventh embodiment. The semiconductor device 1K is a semiconductor switching device including the main transistor structure T1 as an RC-IGBT structure having the transistor structure T3 and the freewheeling diode structure WD. The configuration of the semiconductor device 1K may be combined with the semiconductor device 1H, the semiconductor device 1I, and the semiconductor device 1J.

The semiconductor device 1K includes an n-type pad cathode region 122 formed in the surface layer portion of the second main surface 4 in one or the plurality of pad regions 11. FIG. 36 shows an example in which the pad cathode region 122 is formed in the anode pad region 11A. As a matter of course, the pad cathode region 122 may be formed in at least one of the gate pad region 11G, the monitor pad region 11M, and the cathode pad region 11C.

The pad cathode region 122 has an n-type impurity concentration higher than the n-type impurity concentration of the drift region 12. The n-type impurity concentration of the pad cathode region 122 may be higher than the n-type impurity concentration of the buffer region 13. In this embodiment, the pad cathode region 122 has an n-type impurity concentration higher than the p-type impurity concentration of the collector region 14, and replaces the conductivity type of the collector region 14 from the p-type to the n-type.

The pad cathode region 122 is formed in a region opposing the pad well region 80 in the thickness direction of the chip 2 in the surface layer portion of the second main surface 4. In this embodiment, the pad cathode region 122 opposes the pad well region 80 and the plurality of capacitor structures 85 in the thickness direction.

The pad cathode region 122 may be formed over the entire region of the corresponding pad region 11, or may be partially formed in a portion of the corresponding pad region 11. The pad cathode region 122 may oppose all of the first capacitor electrode films 90 (capacitor structures 85) and all of the second capacitor electrode films 92. The pad cathode region 122 may oppose some of the first capacitor electrode films 90 (capacitor structures 85), or may oppose some of the second capacitor electrode films 92.

The pad cathode region 122 penetrates the collector region 14 and is electrically connected to the drift region 12. In this embodiment, the pad cathode region 122 has an upper end portion located within the buffer region 13 and is electrically connected to the drift region 12 via the buffer region 13. The pad cathode region 122 may have an upper end portion that penetrates the buffer region 13 and is located within the drift region 12.

As described above, the semiconductor device 1K may include the freewheeling diode structure WD including the pad well region 80 as an anode and the pad cathode region 122 as a cathode.

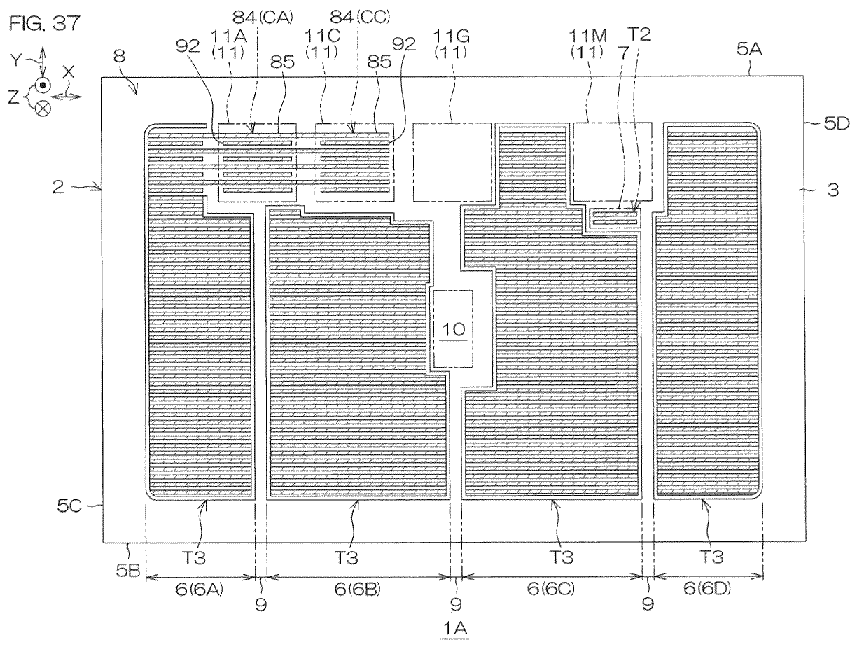

Hereinafter, modification examples applied to the semiconductor devices 1A to 1K according to the first to eleventh embodiments will be described. FIGS. 37 to 40 are plan views showing the first to fourth modification examples of the semiconductor devices 1A to 1K according to the first to eleventh embodiments. In FIGS. 37 to 40, the semiconductor device 1A is shown.

The semiconductor devices 1A to 1K according to the first to eleventh configuration examples may have at least one of the configurations according to the first to fourth modification examples. As a matter of course, the semiconductor devices 1A to 1K according to the first to eleventh configuration examples may have a configuration in which at least two of the configurations according to the first to fourth modification examples are combined.

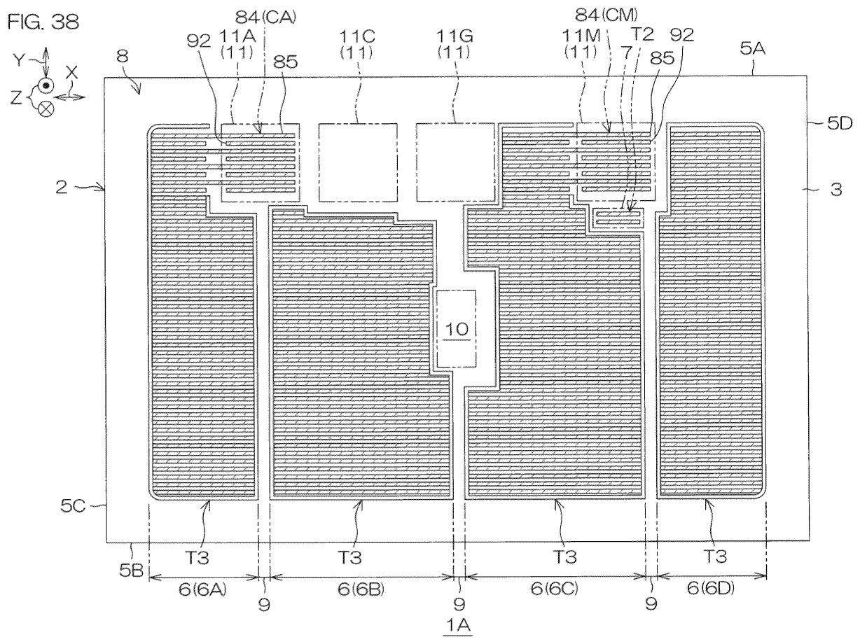

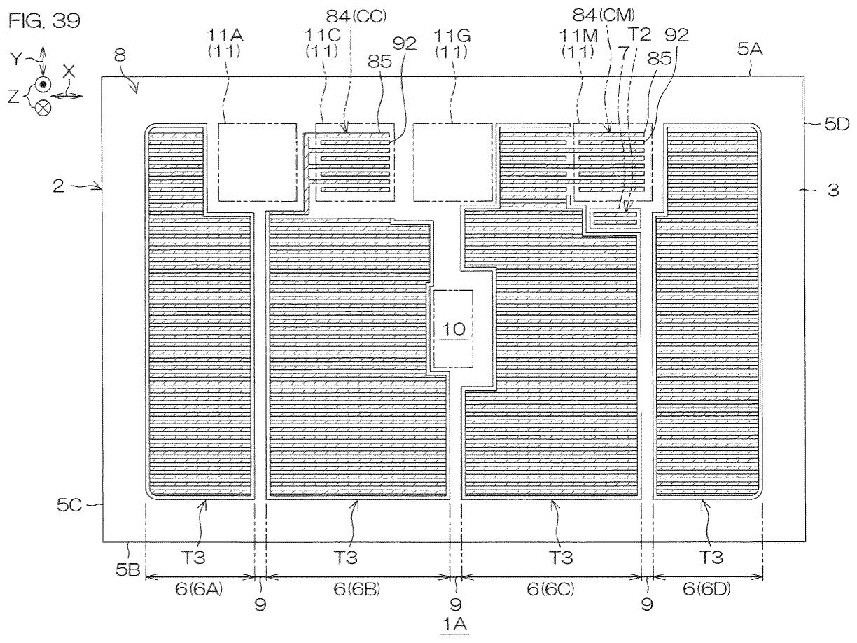

With reference to FIG. 37 (first modification example), the semiconductor devices 1A to 1K not having the monitor capacitor structure CM may be adopted. With reference to FIG. 38 (second modification example), the semiconductor devices 1A to 1K not having the anode capacitor structure CA may be adopted. With reference to FIG. 39 (third modification example), the semiconductor devices 1A to 1K not having the cathode capacitor structure CC may be adopted.

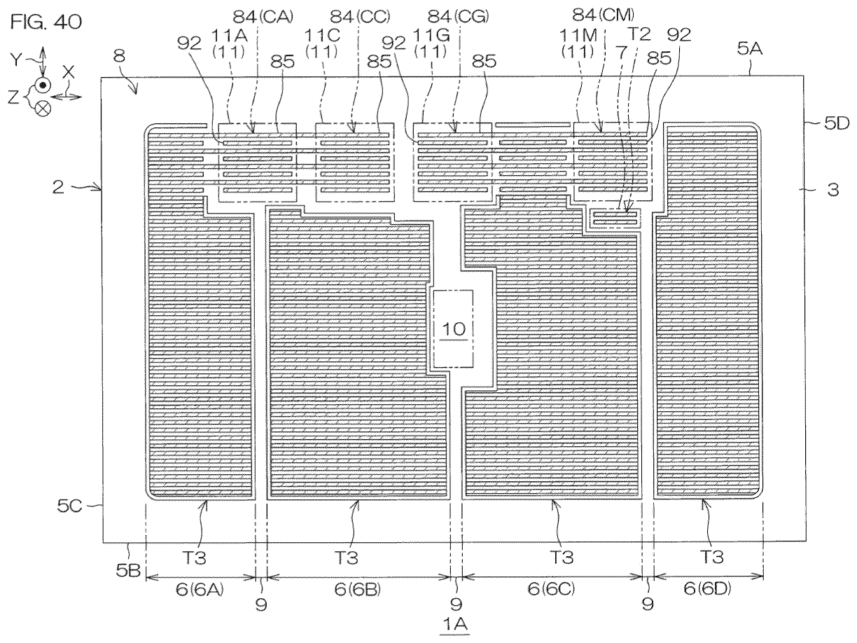

With reference to FIG. 40 (fourth modification example), the semiconductor devices 1A to 1K may include a gate capacitor structure CG as a pad capacitor structure 84 formed in the gate pad region 11G. The gate capacitor structure CG may have a configuration similar to any one of the pad capacitor structures 84 (anode capacitor structures CA) shown in the first to seventh embodiments.

The configuration of the gate capacitor structure CG is obtained by replacing “pad capacitor structure 84 (anode capacitor structure CA)” with “gate capacitor structure CG,” replacing “pad region 11 (anode pad region 11A)” with “gate pad region 11G,” and replacing “pad electrode 95 (anode pad AP)” with “gate pad GP” in the above-described description.

As a matter of course, the gate capacitor structure CG may have at least one feature of the capacitor structure 85 (refer to FIGS. 14 and 20A to 20M) according to the first to fourteenth layout examples.

Each of the above-described embodiments (including the modification examples) can be implemented in still other embodiments. For example, in each of the above-described embodiments (including the modification examples), the monitor capacitor structure CM, the anode capacitor structure CA, the cathode capacitor structure CC, and the gate capacitor structure CG do not necessarily have the same configuration, and may have different configurations.

That is, the monitor capacitor structure CM may have any one of the pad capacitor structures 84 according to the first to seventh embodiments in the first to eleventh embodiments. In addition, the anode capacitor structure CA may have any one of the pad capacitor structures 84 according to the first to seventh embodiments in the first to eleventh embodiments.

In addition, the cathode capacitor structure CC may have any one of the pad capacitor structures 84 according to the first to seventh embodiments in the first to eleventh embodiments. In addition, the gate capacitor structure CG may have any one of the pad capacitor structures 84 according to the first to seventh embodiments in the first to eleventh embodiments.

In each of the above-described embodiments (including modification examples), in a case in which the emitter potential is applied to the plurality of capacitor structures 85 (plurality of first capacitor electrode film 90), the plurality of capacitor structures 85 (plurality of first capacitor electrode film 90) are not necessarily mechanically connected to one or both of the emitter structure 30 and the emitter connection structure 35.

For example, each of the above-described embodiments (including modification examples) may have the emitter wiring 55, the second emitter opening 62, and the second emitter via electrode 63 for the capacitor structures 85 (first capacitor electrode film 90) in the active region 6.

In this case, the emitter wiring 55 is connected to the plurality of capacitor structures 85 (plurality of first capacitor electrode film 90) on the first main surface 3 (main surface insulating film 48). The second emitter opening 62 exposes the emitter wiring 55 for the plurality of capacitor structures 85 (plurality of first capacitor electrode film 90).

The second emitter via electrode 63 is mechanically and electrically connected to the emitter wiring 55 in the second emitter opening 62, and is electrically connected to the plurality of capacitor structures 85 (plurality of first capacitor electrode film 90) via the emitter wiring 55.

The emitter pad EP is electrically connected to the plurality of capacitor structures 85 (plurality of first capacitor electrode film 90) via the emitter wiring 55 and the second emitter via electrode 63 in the active region 6. As a result, the emitter potential is transmitted to the plurality of capacitor structures 85 (plurality of first capacitor electrode film 90) via the emitter wiring 55 and the second emitter via electrode 63.

In each of the above-described embodiments (including modification examples), in a case in which the emitter potential is applied to the plurality of second capacitor electrode film 92, the plurality of second capacitor electrode film 92 are not necessarily mechanically connected to one or both of the emitter structure 30 and the emitter connection structure 35.

For example, each of the above-described embodiments (including modification examples) may have the emitter wiring 55, the second emitter opening 62, and the second emitter via electrode 63 for the plurality of second capacitor electrode film 92 in the active region 6. In this case, the emitter wiring 55 is connected to the plurality of second capacitor electrode film 92 on the first main surface 3 (main surface insulating film 48). The second emitter opening 62 exposes the emitter wiring 55 for the plurality of second capacitor electrode film 92.

The second emitter via electrode 63 is mechanically and electrically connected to the emitter wiring 55 in the second emitter opening 62, and is electrically connected to the second capacitor electrode film 92 via the emitter wiring 55.

The emitter pad EP is electrically connected to the second capacitor electrode film 92 via the emitter wiring 55 and the second emitter via electrode 63 in the active region 6. As a result, the emitter potential is transmitted to the second capacitor electrode film 92 via the emitter wiring 55 and the second emitter via electrode 63.

In each of the above-described embodiments (including the modification examples), a configuration may be adopted in which the monitor region 7 (monitor transistor structure T2) is not provided but the active region 6 (transistor structure T3) and the temperature detection region 10 (temperature-sensitive diode structure D) are provided.

In each of the above-described embodiments, a configuration may be adopted in which the temperature detection region 10 (temperature-sensitive diode structure D) is not provided, but the active region 6 (transistor structure T3) and the monitor region 7 (monitor transistor structure T2) are provided.

In each of the above-described embodiments (including the modification examples), a configuration may be adopted in which the active region 6 (transistor structure T3) is not provided, but one or both of the monitor region 7 (monitor transistor structure T2) and the temperature detection region 10 (temperature-sensitive diode structure D) are provided.

In each of the above-described embodiments (including the modification examples), a structure may be adopted in which the conductivity type of a semiconductor region of the “n-type” is inverted to the “p-type” and the conductivity type of a semiconductor region of the “p-type” is inverted to the “n-type.” The specific arrangement in this case is obtained by replacing the “n-type” with the “p-type” and replacing the “p-type” with the “n-type” at the same time in the above description and attached drawings.

In each of the above-described embodiments (including modification examples), the collector region 14 may be removed. In this case, the main transistor structure T1 (transistor structure T3) includes a MISFET structure instead of the IGBT structure.

The specific configuration in this case is obtained by replacing the “emitter” of the IGBT structure with the “source” of the MISFET structure and replacing the “collector” of the IGBT structure with the “drain” of the MISFET structure in the above-described description. In this case, the chip 2 may have a laminated structure including an n-type semiconductor substrate on the second main surface 4 side and an n-type epitaxial layer on the first main surface 3 side.

Hereinafter, examples of features extracted from this specification and the drawings will be indicated below. Hereinafter, the alphanumeric characters and the like in parentheses represent the corresponding constituent elements and the like, but in the above-described embodiment, are not intended to limit the scope of each clause to the above-described embodiment. The “semiconductor device” according to the following items may be replaced with a “SiC semiconductor device,” a “wide bandgap semiconductor device,” a “semiconductor switching device,” an “IGBT device,” an “RC-IGBT device,” a “MISFET device,” a “semiconductor rectifier,” or the like, as necessary.
[A1] A semiconductor device (1A to 1K) comprising: a chip (2) that has a main surface (3); a pad region (11, 11A, 11C, 11G, 11M) that is provided in the main surface (3); a first electrode (90, 90a, 90b, 90A, 90B) that is arranged on the main surface (3) in the pad region (11, 11A, 11C, 11G, 11M), and to which a first potential is to be applied; a side wall dielectric film (91) that covers a side wall of the first electrode (90, 90a, 90b, 90A, 90B) in the pad region (11, 11A, 11C, 11G, 11M); and a second electrode (92, 92A, 92B) that is arranged on the main surface (3) so as to form a capacitive coupling with the first electrode (90, 90a, 90b, 90A, 90B) via the side wall dielectric film (91) in the pad region (11, 11A, 11C, 11G, 11M), and to which a second potential different from the first potential is to be applied.
[A2] The semiconductor device (1A to 1K) according to A1, wherein the first potential is a potential other than a gate potential.
[A3] The semiconductor device (1A to 1K) according to A1 or A2, wherein the first potential is a reference potential serving as a reference of circuit operation.
[A4] The semiconductor device (1A to 1K) according to any one of A1 to A3, wherein the first potential is an emitter potential.
[A5] The semiconductor device (1A to 1K) according to any one of A1 to A4, wherein the second potential is a potential other than a gate potential.
[A6] The semiconductor device (1A to 1K) according to any one of A1 to A5, wherein the second potential is a potential other than a reference potential serving as a reference of circuit operation.
[A7] The semiconductor device (1A to 1K) according to any one of A1 to A6, wherein the second potential is a potential other than an emitter potential.
[A8] The semiconductor device (1A to 1K) according to any one of A1 to A7, further comprising: a pad electrode (95, GP, MP, AP, CaP) that is arranged on the first electrode (90, 90a, 90b, 90A, 90B) and the second electrode (92, 92A, 92B) in the pad region (11, 11A, 11C, 11G, 11M) so as to be electrically separated from the first electrode (90, 90a, 90b, 90A, 90B) and electrically connected to the second electrode (92, 92A, 92B), and to which the second potential is to be applied.
[A9] The semiconductor device (1A to 1K) according to any one of A1 to A8, further comprising: a capacitor structure (85, 85A, 85B) of a trench electrode type that is formed in the main surface (3); wherein the first electrode (90, 90a, 90b, 90A, 90B) is connected to the capacitor structure (85, 85A, 85B), and the second electrode (92, 92A, 92B) is formed at an interval from the capacitor structure (85, 85A, 85B).
[A10] The semiconductor device (1A to 1K) according to A9, wherein the capacitor structure (85, 85A, 85B) includes a trench (86) formed in the main surface (3), an insulating film (87) covering a wall surface of the trench (86), and an embedded electrode (88) embedded in the trench (86) with the insulating film (87) interposed therebetween, and the first electrode (90, 90a, 90b, 90A, 90B) is integrally formed with the embedded electrode (88) as a projecting portion that projects upward from the embedded electrode (88) with respect to a height position of the main surface (3).
[A11] The semiconductor device (1A to 1K) according to any one of A1 to A10, further comprising: a main surface dielectric film (48) that covers the main surface (3); wherein the second electrode (92, 92A, 92B) is arranged on the main surface dielectric film (48), and forms a capacitive coupling with the chip (2) via the main surface dielectric film (48).
[A12] The semiconductor device (1A to 1K) according to A11, further comprising: a semiconductor region (12) of a first conductivity type (n-type) that is formed in the chip (2); and a well region (80) of a second conductivity type (p-type) that is formed in a surface layer portion of the main surface (3), and is electrically connected to the semiconductor region (12); wherein the main surface dielectric film (48) covers the well region (80) on the main surface (3), and the second electrode (92, 92A, 92B) forms the capacitive coupling with the well region (80) via the main surface dielectric film (48).
[A13] The semiconductor device (1A to 1K) according to any one of A1 to A12, further comprising: an active region (6) that is provided in the main surface (3); and a transistor (T1, T3) that is formed in the active region (6); wherein the pad region (11, 11A, 11C, 11G, 11M) is provided outside the active region (6) in the main surface (3).
[A14] The semiconductor device (1A to 1K) according to any one of A1 to A13, further comprising: a diode region (10) that is provided in the main surface (3); and a diode (D) that is formed in the diode region (10); wherein the pad region (11, 11A, 11C, 11G, 11M) is provided outside the diode region (10) in the main surface (3).
[A15] The semiconductor device (1A to 1K) according to any one of A1 to A14, further comprising: a monitor region (7) that is provided in the main surface (3); and a current monitor (T2) that is formed in the monitor region (7); wherein the pad region (11, 11A, 11C, 11G, 11M) is provided outside the monitor region (7) in the main surface (3).
[A16] A semiconductor device (1A to 1K) comprising: a chip (2) that has a main surface (3); a first electrode (90, 90a, 90b, 90A, 90B) that is arranged on the main surface (3), and to which a first potential is to be applied; a first dielectric film (48) that covers the main surface (3); a second dielectric film (91) that covers a wall surface of the first electrode (90, 90a, 90b, 90A, 90B); and a second electrode (92, 92A, 92B) that is arranged on the first dielectric film (48) so as to form a capacitive coupling with the chip (2) via the first dielectric film (48) and form a capacitive coupling with the first electrode (90, 90a, 90b, 90A, 90B) via the second dielectric film (91), and to which a second potential different from the first potential is to be applied.
[A17] The semiconductor device (1A to 1K) according to A16, wherein the second dielectric film (91) has a thickness greater than a thickness of the first dielectric film (48).
[A18] The semiconductor device (1A to 1K) according to A16 or A17, further comprising:
a pad electrode (95, GP, MP, AP, CaP) that is arranged on the first electrode (90, 90a, 90b, 90A, 90B) and the second electrode (92, 92A, 92B) so as to be electrically separated from the first electrode (90, 90a, 90b, 90A, 90B) and electrically connected to the second electrode (92, 92A, 92B), and to which the second potential is to be applied.
[A19] The semiconductor device (1A to 1K) according to any one of A16 to A18, further comprising: a well region (80) of a p-type that is formed in a surface layer portion of the main surface (3); wherein the first dielectric film (48) covers the well region (80) on the main surface (3), and the second electrode (92, 92A, 92B) forms the capacitive coupling with the well region (80) via the first dielectric film (48).
[A20] The semiconductor device (1A to 1K) according to any one of A16 to A19, further comprising: a capacitor structure (85, 85A, 85B) of a trench electrode type that is formed in the main surface (3); wherein the first electrode (90, 90a, 90b, 90A, 90B) is connected to the capacitor structure (85, 85A, 85B), and the second electrode (92, 92A, 92B) is formed at an interval from the capacitor structure (85, 85A, 85B).

While the specific embodiments have been described in detail above, this is merely a specific example used to clarify the technical contents. The various technical ideas extracted from this Description can be combined as appropriate with each other without being limited by the order of description, the order of configuration examples, the order of modification examples, etc., in this Description.

What is claimed is:

1. A semiconductor device comprising:
a chip that has a main surface;
a pad region that is provided in the main surface;
a first electrode that is arranged on the main surface in the pad region, and to which a first potential is to be applied;
a side wall dielectric film that covers a side wall of the first electrode in the pad region; and
a second electrode that is arranged on the main surface so as to form a capacitive coupling with the first electrode via the side wall dielectric film in the pad region, and to which a second potential different from the first potential is to be applied.

2. The semiconductor device according to claim 1,
wherein the first potential is a potential other than a gate potential.

3. The semiconductor device according to claim 1,
wherein the first potential is a reference potential serving as a reference of circuit operation.

4. The semiconductor device according to claim 1,
wherein the first potential is an emitter potential.

5. The semiconductor device according to claim 1,
wherein the second potential is a potential other than a gate potential.

6. The semiconductor device according to claim 1,
wherein the second potential is a potential other than a reference potential serving as a reference of circuit operation.

7. The semiconductor device according to claim 1,
wherein the second potential is a potential other than an emitter potential.

8. The semiconductor device according to claim 1, further comprising:
a pad electrode that is arranged on the first electrode and the second electrode in the pad region so as to be electrically separated from the first electrode and electrically connected to the second electrode, and to which the second potential is to be applied.

9. The semiconductor device according to claim 1, further comprising:
a capacitor structure of a trench electrode type that is formed in the main surface;
wherein the first electrode is connected to the capacitor structure, and
the second electrode is formed at an interval from the capacitor structure.

10. The semiconductor device according to claim 9,
wherein the capacitor structure includes a trench formed in the main surface, an insulating film covering a wall surface of the trench, and an embedded electrode embedded in the trench with the insulating film interposed therebetween, and
the first electrode is integrally formed with the embedded electrode as a projecting portion that projects upward from the embedded electrode with respect to a height position of the main surface.

11. The semiconductor device according to claim 1, further comprising:
a main surface dielectric film that covers the main surface;
wherein the second electrode is arranged on the main surface dielectric film, and forms a capacitive coupling with the chip via the main surface dielectric film.

12. The semiconductor device according to claim 11, further comprising:
a semiconductor region of a first conductivity type that is formed in the chip; and
a well region of a second conductivity type that is formed in a surface layer portion of the main surface, and is electrically connected to the semiconductor region;
wherein the main surface dielectric film covers the well region on the main surface, and
the second electrode forms the capacitive coupling with the well region via the main surface dielectric film.

13. The semiconductor device according to claim 1, further comprising:
an active region that is provided in the main surface; and
a transistor that is formed in the active region;
wherein the pad region is provided outside the active region in the main surface.

14. The semiconductor device according to claim 1, further comprising:
a diode region that is provided in the main surface; and
a diode that is formed in the diode region;
wherein the pad region is provided outside the diode region in the main surface.

15. The semiconductor device according to claim 1, further comprising:
a monitor region that is provided in the main surface; and
a current monitor that is formed in the monitor region;
wherein the pad region is provided outside the monitor region in the main surface.

16. A semiconductor device comprising:
a chip that has a main surface;
a first electrode that is arranged on the main surface, and to which a first potential is to be applied;
a first dielectric film that covers the main surface;
a second dielectric film that covers a wall surface of the first electrode; and
a second electrode that is arranged on the first dielectric film so as to form a capacitive coupling with the chip via the first dielectric film and form a capacitive coupling with the first electrode via the second dielectric film, and to which a second potential different from the first potential is to be applied.

17. The semiconductor device according to claim 16,
wherein the second dielectric film has a thickness greater than a thickness of the first dielectric film.

18. The semiconductor device according to claim 16, further comprising:
a pad electrode that is arranged on the first electrode and the second electrode so as to be electrically separated from the first electrode and electrically connected to the second electrode, and to which the second potential is to be applied.

19. The semiconductor device according to claim 16, further comprising:
a well region of a p-type that is formed in a surface layer portion of the main surface;
wherein the first dielectric film covers the well region on the main surface, and
the second electrode forms the capacitive coupling with the well region via the first dielectric film.

20. The semiconductor device according to claim 16, further comprising:
a capacitor structure of a trench electrode type that is formed in the main surface;
wherein the first electrode is connected to the capacitor structure, and
the second electrode is formed at an interval from the capacitor structure.
